(19) United States
(12) Patent Application Publication
(10) Pub. No.: US 2025/0241118 A1
(43) Pub. Date: Jul. 24, 2025

(54) ORGANIC LIGHT EMITTING DIODE AND ORGANIC LIGHT EMITTING DEVICE INCLUDING THE SAME

(71) Applicant: LG Display Co., Ltd, Seoul (KR)

(72) Inventors: Chi-Ho LEE, Paju-si (KR); Gyeong-Woo KIM, Paju-si (KR); Suk-Young BAE, Paju-si (KR); Han-Jin AHN, Paju-si (KR); Jun-Yun KIM, Paju-si (KR)

(73) Assignee: LG Display Co., Ltd, Seoul (KR)

(21) Appl. No.: 18/999,285

(22) Filed: Dec. 23, 2024

(30) Foreign Application Priority Data
Jan. 24, 2024 (KR) 10-2024-0010925

(51) Int. Cl. H10K 50/12; H10K 50/13; H10K 50/19; H10K 59/38; H10K 77/10; H10K 85/30; H10K 85/40; H10K 85/60; H10K 101/00; H10K 101/25; H10K 101/30; H10K 101/40; H10K 102/00

(52) U.S. Cl. CPC H10K 50/121; H10K 85/342; H10K 85/346; H10K 85/40; H10K 85/615; H10K 85/633; H10K 85/654; H10K 85/6572; H10K 85/658; H10K 50/13; H10K 50/19; H10K 59/38; H10K 77/111; H10K 2101/25; H10K 2101/27; H10K 2101/30; H10K 2101/40; H10K 2101/90; H10K 2102/3026; H10K 2102/311; H10K 2102/351

(57) ABSTRACT

An organic light emitting diode, and an organic light emitting device including the same are described. An organic light emitting diode includes a first electrode; a second electrode facing the first electrode; and a first emitting part including a first blue emitting material layer and positioned between the first and second electrodes, the first blue emitting material layer including a first blue emitting layer and a second blue emitting layer, wherein one of the first and second blue emitting layers includes a first p-type host represented by Formula 1 and a first n-type host represented by Formula 3 to provide an exciplex property, and the other one of the first and second blue emitting layers includes a second p-type host represented by Formula 1 and a second n-type host represented by Formula 5 to provide a delayed fluorescent property.

### CROSS-REFERENCE TO RELATED APPLICATIONS

The present application claims priority under 35 U.S.C. § 119 to Korean Patent Application No. 10-2024-0010925 filed in the Republic of Korea on Jan. 24, 2024, which is hereby incorporated by reference in its entirety into the present application for all purposes.

### BACKGROUND

### Technical Field

The present disclosure relates to an organic light emitting diode (OLED), and more particularly, to an organic light emitting diode having improved lifespan and an organic light emitting device including the organic light emitting diode.

### Discussion of the Related Art

As demand increases for display devices in various fields, especially those that occupy a small space, an organic light emitting display device including an OLED (e.g., an organic electroluminescent device) has been a focus of recent research and development.

An OLED provides can provide certain advantages over conventional display technologies. For instance, the organic light emitting display device can be operated at a low voltage, consume relatively less power, have excellent colors, be applied to a flexible substrate, and can be provided in a variety of sizes, for a variety of applications. OLED devices can have a wide viewing angle and a high contrast ratio compared to liquid crystal display (LCD) devices and do not require a backlight, making them lightweight and ultra-thin.

The OLED is formed by arranging a plurality of intermediate layers, such as a hole injection layer, a hole transport layer, a hole transport auxiliary layer, an electron blocking layer, an electron transport layer, an electron injection layer, etc., between a cathode (electron injection electrode) and an anode (hole injection electrode). An OLED emits light when a voltage is applied by injecting electrons from a cathode as an electron injection electrode, and holes from an anode as a hole injection electrode, into an emitting material layer (EML), where the electrons are combined with the holes, generating an exciton, and which emits light as it transitions from an excited state to a ground state.

Since fluorescent materials use only singlet excitons in the luminous process, there is an issue with low luminous efficiency. For instance, in the case of fluorescent materials, while only a singlet of about 25% of the excitons formed in the emission layer is used to generate light, and a triplet of 75% is mostly lost as heat. Meanwhile, phosphorescent materials can show high luminous efficiency since they use both triplet excitons and singlet excitons in the luminous process. However, examples of phosphorescent material include metal complexes, which have a short luminous lifespan, which can be too short for commercial use.

There is still a technical need to improve the performance of the organic light emitting diode by deriving high-efficiency phosphorescent dopant materials and applying hosts with optimal photophysical characteristics to improve the efficiency and lifetime of the element compared to conventional organic light emitting diodes.

### SUMMARY OF THE DISCLOSURE

Accordingly, one or more embodiments of the present disclosure are directed to an OLED and an organic light emitting device that substantially obviate one or more of the problems associated with the limitations and disadvantages of the related art.

An object of the present disclosure is to provide an OLED and an organic light emitting device having and improved lifespan.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

To achieve these and other advantages in accordance with the purpose of one or more embodiments of the present disclosure, as described herein, an aspect of the present disclosure is an organic light emitting diode comprising a first electrode; a second electrode facing the first electrode; and a first emitting part including a first blue emitting material layer and positioned between the first and second electrodes, the first blue emitting material layer including a first blue emitting layer and a second blue emitting layer, wherein the first blue emitting layer includes a first p-type host, a first n-type host and a first phosphorescent dopant, and the second blue emitting layer includes a second p-type host, a second n-type host and a second phosphorescent dopant, wherein each of the first and second p-type host is independently represented by Formula 1:

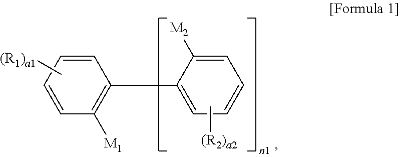

in the Formula 1, each of a1 and a2 is independently an integer of 0 to 4, n1 is 0 or 1, when a1 is 2 or more, two or more R₁ can be same or different, when a2 is 2 or more, two or more R₂ can be same or different, each of R₁ and R₂ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany alkylgermanyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
each of M₁ and M₂ is independently selected from Formula 1a-1 and Formula 1-2:

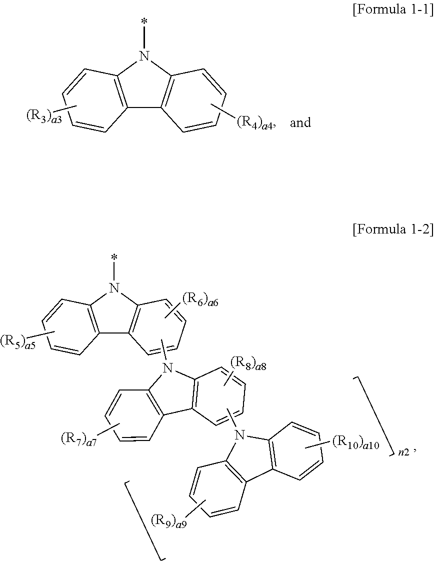

in the Formula 1-1, each of a3 and a4 is independently an integer of 0 to 4, when a3 is 2 or more, two or more R₃ can be same or different, when a4 is 2 or more, two or more R₄ can be same or different, each of R₃ and R₄ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
in the Formula 1-2, each of a5, a7, a8, a9 and a10 is independently an integer of 0 to 4, a6 is an integer of 0 to 3, n2 is 0 or 1, when a5 is 2 or more, two or more R₈ can be same or different, when a6 is 2 or more, two or more R₆ can be same or different, when a7 is 2 or more, two or more R₇ can be same or different, when a8 is 2 or more, two or more R₈ can be same or different, when a9 is 2 or more, two or more R₉ can be same or different, when a10 is 2 or more, two or more R₁₀ can be same or different, and each of R₅, R₆, R₇, R₈, R₉ and R₁₀ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group, wherein the first n-type host is represented by Formula 3:

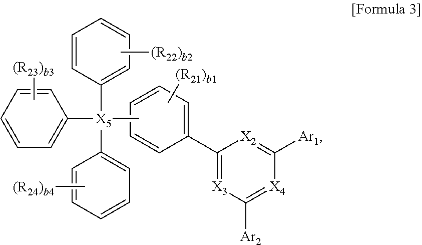

in the Formula 3, b1 is an integer of 0 to 4, each of b2, b3 and b4 is independently an integer of 0 to 5, when b1 is 2 or more, two or more R₂₁ can be same or different, when b2 is 2 or more, two or more R₂₂ can be same or different, when b3 is 2 or more, two or more R₂₃ can be same or different, when b4 is 2 or more, two or more R₂₄ can be same or different, each of X₂, X₃ and X₄ is independently selected from N and CR₂₉, at least one of X₂, X₃ and X₄ is N, R₂₁, R₂₂, R₂₃ and R₂₄ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, R₂₉ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C30 heteroaryl group, and X₅ is one of C, Si and Ge, wherein the second n-type host is represented by Formula 5:

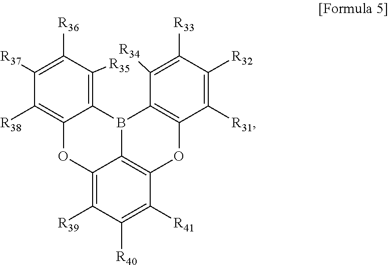

in the Formula 5, one of R₃₁ to R₄₁ is represented by Formula 5-1, at least one of R₃₁ to R₄₁ is represented by Formula 5-2, each of the rest of R₃₁ to R₄₁ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or optionally, adjacent two of the rest of R₃₁ to R₄₁ are combined to form a ring,

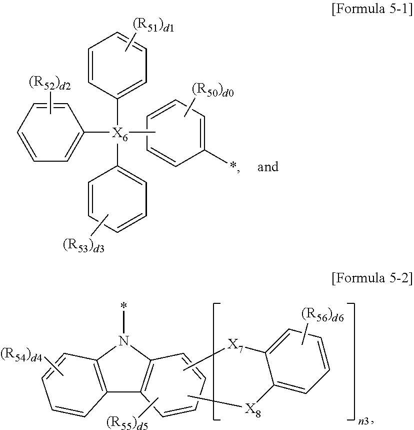

in the Formula 5-1, d0 is an integer of 0 to 4, each of d1, d2 and d3 is independently an integer of 0 to 5, when d0 is 2 or more, two or more R₅₀ can be same or different, when d1 is 2 or more, two or more R₅₁ can be same or different, when d2 is 2 or more, two or more R₅₂ can be same or different, when d3 is 2 or more, two or more R₅₃ can be same or different, each of R₅₀, R₅₁, R₅₂ and R₅₃ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and X₆ is one of C, Si and Ge,
in the Formula 5-2, n3 is 0 or 1, each of d4 and d6 is independently an integer of 0 to 4, d5 is an integer of 0 to 2, when d4 is 2 or more, two or more R₅₄ can be same or different, when d5 is 2 or more, two or more R₅₅ can be same or different, when d6 is 2, two R₅₆ can be same or different, each of R₅₄, R₅₅ and R₅₆ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, one of X₇ and X₈ is a single bond, the other one of X₇ and X₈ is selected from NR₅₇, CR₅₈R₅₉, O and S, and each of R₅₇, R₅₈ and R₅₉ is independently selected from the group consisting of hydrogen, deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

In some embodiments, one of the first and second blue emitting layers includes a first p-type host represented by Formula 1 and a first n-type host represented by Formula 3 to provide an exciplex property, and the other one of the first and second blue emitting layers includes a second p-type host represented by Formula 1 and a second n-type host represented by Formula 5 to provide a delayed fluorescent property. For instance, one of the first and second blue emitting layers includes a first p-type host represented by Formula 2 and a first n-type host represented by Formula 3a to provide an exciplex property, and the other one of the first and second blue emitting layers includes a second p-type host represented by Formula 2 and a second n-type host represented by Formula 6 to provide a delayed fluorescent property.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate some embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to one or more embodiments of the present disclosure.

FIG. 3 is a schematic cross-sectional view of an OLED according to one or more embodiments of the present disclosure.

FIGS. 4A and 4B are graphs showing an exciplex property.

FIG. 4C is a graph explaining a property by a second p-type host and a second n-type host.

FIG. 5 is a schematic cross-sectional view of an OLED according to one or more embodiments of the present disclosure.

FIG. 6 is a schematic cross-sectional view of an OLED according to one or more embodiments of the present disclosure.

FIG. 7 is a schematic cross-sectional view of an OLED according to one or more embodiments of the present disclosure.

FIG. 8 is a schematic cross-sectional view of an organic light emitting display device according to one or more embodiments of the present disclosure.

FIG. 9 is a schematic cross-sectional view of an organic light emitting display device according to one or more embodiments of the present disclosure.

FIG. 10 is a schematic cross-sectional view of an OLED according to one or more embodiments of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products. All the components of each organic light emitting display device according to all embodiments of the present disclosure are operatively coupled and configured.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts can be added unless ‘only’ is used. When a component is expressed in the singular, cases including the plural are included unless specific statement is described. Further, the term “can” encompasses all the meanings and coverages of the term “may”.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Reference will now be made in detail to some of the examples and some embodiments, which are illustrated in the accompanying drawings.

The present disclosure relates to an OLED, in which each of adjacent blue emitting layers has different combination in their compounds (materials), and an organic light emitting device including the OLED. For example, an organic light emitting device can be an organic light emitting display device or an organic lightening device. As an example, an organic light emitting display device, which is a display device including the OLED of the present disclosure, will be mainly described.

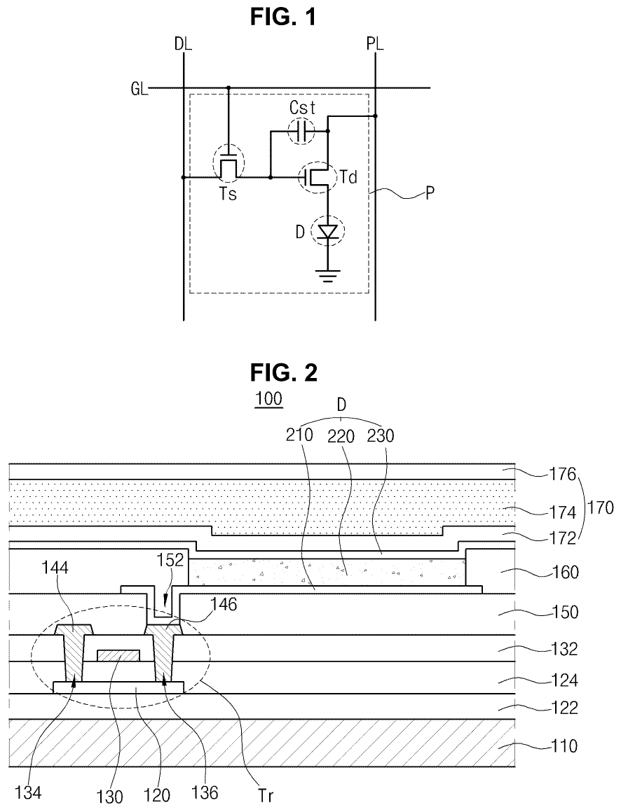

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region can include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to one or more embodiments of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region can be defined on the substrate 110.

The substrate 110 can be a glass substrate or a flexible substrate. For example, the flexible substrate can be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate, and the TFT Tr is formed on the buffer layer 122. The buffer layer 122 can be omitted. For example, the buffer layer 122 can be formed of an inorganic insulating material, e.g., silicon oxide or silicon nitride.

A semiconductor layer 120 is formed on the buffer layer 122. The semiconductor layer 120 can include an oxide semiconductor material or polycrystalline silicon.

When the semiconductor layer 120 includes the oxide semiconductor material, a light-shielding pattern can be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities can be doped into both sides of the semiconductor layer 120.

A gate insulating layer 124 is formed on the semiconductor layer 120. The gate insulating layer 124 can be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. For example, the gate electrode 130 can be formed of a metal, e.g., copper (Cu), molybdenum (Mo), titanium (Ti), aluminum (Al), gold (Au) or silver (Ag). The gate electrode 130 can have a single-layered structure or a multi-layered structure.

In FIG. 2, the gate insulating layer 124 is formed on an entire surface of the substrate 110. Alternatively, the gate insulating layer 124 can be patterned to have the same shape as the gate electrode 130.

An interlayer insulating layer 132 is formed on the gate electrode 130 and over an entire surface of the substrate 110. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124 and the interlayer insulating layer 132. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132. The source electrode 144 and the drain electrode 146 are spaced apart from each other with respect to the gate electrode 130 and respectively contact both sides of the semiconductor layer 120 through the first and second contact holes 134 and 136.

For example, each of the source electrode 144 and the drain electrode 146 can be formed of a metal, e.g., Cu, Mo, Ti, Al, Au or Ag. Each of the source electrode 144 and the drain electrode 146 can have a single-layered structure or a multi-layered structure.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

In some embodiments, the gate line and the data line cross each other to define the pixel region, and the switching TFT is formed to be connected to the gate and data lines. The switching TFT is connected to the TFT Tr as the driving element. In addition, the power line, which can be formed to be parallel to and spaced apart from one of the gate and data lines, and the storage capacitor for maintaining the voltage of the gate electrode of the TFT Tr in one frame can be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr. The planarization layer 150 can be formed of an inorganic insulating material, e.g., silicon oxide or silicon nitride, or an organic insulating material, e.g., benzocyclobutene or photo-acryl.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 can be an anode and can include a transparent conductive oxide material layer, which can be formed of a conductive material, e.g., a transparent conductive oxide (TCO), having a relatively high work function. For example, the transparent conductive oxide material layer can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 210 can have a single-layered structure of the transparent conductive oxide material layer. Namely, the first electrode 210 can be a transparent electrode.

Alternatively, the first electrode 210 can further include a reflective layer to have a double-layered structure or a triple-layered structure. Namely, the first electrode 210 can be a reflective electrode.

For example, the reflective layer can be formed of one of silver (Ag), an alloy of Ag and one of palladium (Pd), copper (Cu), indium (In) and neodymium (Nd), and aluminum-palladium-copper (APC) alloy. For example, the first electrode 210 can have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 including an emitting material layer (EML) is formed on the first electrode 210. The organic light emitting layer 220 can further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

In an aspect of the present disclosure, in the OLED D in the blue pixel region, the EML of the organic light emitting layer 220 includes a first blue emitting layer and a second blue emitting layer.

In an aspect of the present disclosure, the organic light emitting layer 220 of the OLED D in the blue pixel region can include a first blue emitting part including a first blue EML and a second blue emitting part including a second blue EML to have a tandem structure, and at least one of the first and second blue EMLs can include a first blue emitting layer and a second blue emitting layer. In this case, the organic light emitting layer 220 can further include a charge generation layer (CGL) between the first and second blue emitting parts.

As described below, in the OLED D of the blue pixel region, one of the first blue emitting layer and the second blue emitting layer includes first and second hosts, which is capable of providing a delayed fluorescent property, and a first phosphorescent dopant, and the other one of the first blue emitting layer and the second blue emitting layer includes third and fourth hosts, which is capable of providing an exciplex property, and a second phosphorescent dopant. As a result, the OLED and the organic light emitting device including the same have the improved lifespan.

For example, the first blue emitting layer, which is closer to the first electrode being an anode, includes the first and second hosts, which is capable of providing a delayed fluorescent property, and the first phosphorescent dopant, and the second blue emitting layer, which is closer to the second electrode being a cathode, includes the third and fourth hosts, which is capable of providing an exciplex property, and the second phosphorescent dopant.

The second electrode 230 is formed over the substrate 110 where the organic light emitting layer 220 is formed. The second electrode 230 covers an entire surface of the display area and can be formed of a conductive material having a relatively low work function to serve as a cathode. For example, the second electrode 230 can be formed of aluminum (Al), magnesium (Mg), calcium (Ca), silver (Ag) or their alloy, e.g., Mg—Ag alloy (Mg:Ag).

In a top-emission type OLED D, the first electrode 210 serves as a reflective electrode, and the second electrode 230 has a thin profile to have a light transparent (or semi-transparent) property. Namely, the visible light transmittance of the second electrode 230 can be greater than that of the first electrode 210.

Alternatively, in a bottom-emission type OLED, the first electrode 210 serves as a transparent electrode, and the second electrode serves as a reflective electrode. Namely, the visible light transmittance of the second electrode 230 can be smaller than that of the first electrode 210.

In the bottom-emission type OLED D, the second electrode 220 can be formed of Al. In the top-emission type OLED D, the second electrode 220 can be formed of Mg:Ag. In this case, a weight % ratio of Mg to Ag can be in a range of 1:9 to 9:1, preferably 1:9 to 3:7.

A top-emission type OLED D can further include a capping layer on the second electrode 230. The emitting efficiency of the OLED D and the organic light emitting display device 100 can be further improved by the capping layer.

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

In some embodiments, the organic light emitting display device 100 can include a color filter layer corresponding to the red, green and blue pixel regions.

In the bottom-emission type organic light emitting display device 100, the color filter layer can be positioned between the substrate 110 and the OLED D. In the top-emission type organic light emitting display device 100, the color filter layer can be positioned over the OLED D. For example, in the top-emission type organic light emitting display device 100, the color filter layer can be positioned on the encapsulation layer 170.

In the bottom-emission type organic light emitting display device 100, the organic light emitting display device 100 can further include a metal plate on or over the encapsulation layer 170.

The organic light emitting display device 100 can further include a polarization plate for reducing an ambient light reflection. For example, the polarization plate can be a circular polarization plate. In the bottom-emission type organic light emitting display device 100, the polarization plate can be disposed under the substrate 110. In the top-emission type organic light emitting display device 100, the polarization plate can be disposed on or over the encapsulation layer 170.

In addition, the organic light emitting display device 100 can further include a cover window on or over the encapsulation layer 170 or the polarization plate. In this instance, the substrate 110 and the cover window have a flexible property such that a flexible organic light emitting display device can be provided.

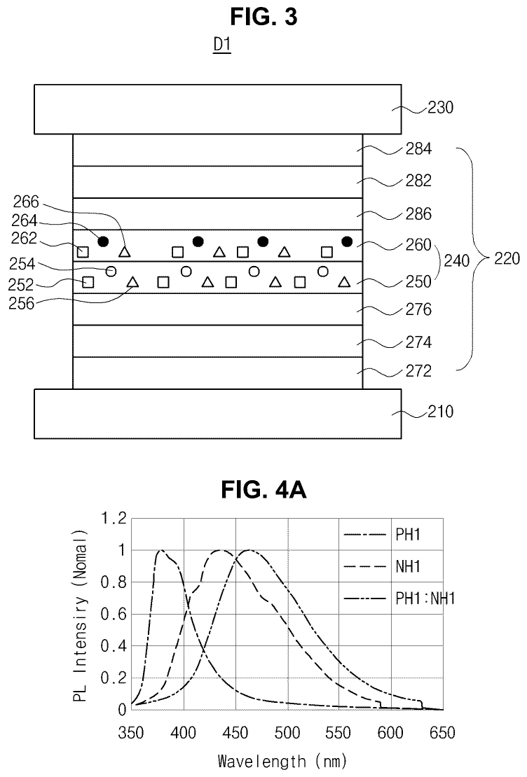

FIG. 3 is a schematic cross-sectional view of an OLED according to one or more embodiments of the present disclosure.

As shown in FIG. 3, the OLED D1 includes first and second electrodes 210 and 230, which face each other, and an organic light emitting layer 220 therebetween. The organic light emitting layer 220 includes a blue emitting material layer (EML) 240, and the blue EML 240 includes a first blue emitting layer 250 and a second blue emitting layer 260. The OLED D1, which is a top-emission type, can further include a capping layer on the second electrode 230 to enhance a light extraction efficiency.

The organic light emitting display device 100 (of FIG. 2) can include a red pixel region, a green pixel region and a blue pixel region, and the OLED D1 can be positioned in the blue pixel region.

One of the first and second electrodes 210 and 230 is an anode, and the other one of the first and second electrodes 210 and 230 is a cathode. One of the first and second electrodes 210 and 230 can be a reflective electrode, and the other one of the first and second electrodes 210 and 230 can be a transparent (or a semi-transparent) electrode.

In a top-emission type OLED D1, the first electrode 210 can be a reflective electrode and can have a structure of ITO/Ag/ITO, and the second electrode 230 can be a transparent electrode and can be formed of Mg:Ag with a weight % ratio of 1:9.

In a bottom-emission type OLED D1, the first electrode 210 can be a transparent electrode and can be formed of ITO, and the second electrode 230 can be a reflective electrode and can be formed of Al.

In the blue EML 240, the second blue emitting layer 260 contacts and is disposed on the first blue emitting layer 250 so that the blue EML 240 has a double-layered structure. The first blue emitting layer 250 is disposed to be closer to the first electrode 210 as an anode than the second blue emitting 260, and the second blue emitting layer 260 is disposed to be closer to the second electrode 230 as a cathode than the first blue emitting layer 250.

The first blue emitting layer 250 includes a first p-type host 252, a first n-type host 254 and a first phosphorescent dopant 256, and the second blue emitting layer 260 includes a second p-type host 262, a second n-type host 264 and a second phosphorescent dopant 266. For example, the first phosphorescent dopant 256 can be referred to as a first emitter, and the second phosphorescent dopant 266 can be referred to as a second emitter.

Each of the first and second p-type hosts 252 and 262 is independently represented by Formula 1.

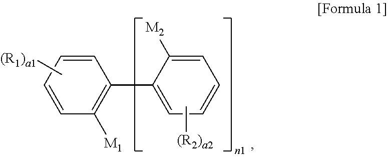

In Formula 1, each of a1 and a2 is independently an integer of 0 to 4, n1 is 0 or 1,
when a1 is 2 or more, two or more R₁ can be same or different, when a2 is 2 or more, two or more R₂ can be same or different,
each of R₁ and R₂ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
each of M₁ and M₂ is independently selected from Formula 1a-1 and Formula 1-2:

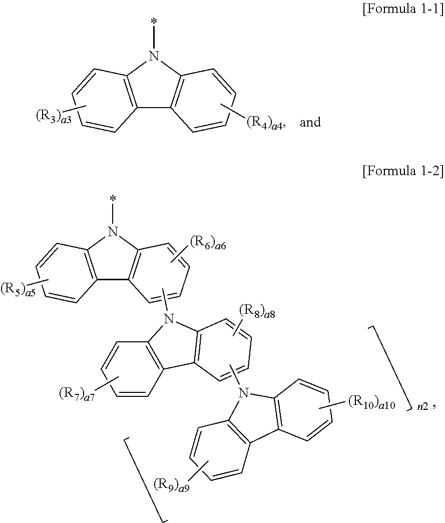

in Formula 1-1, each of a3 and a4 is independently an integer of 0 to 4,
when a3 is 2 or more, two or more R₃ can be same or different, when a4 is 2 or more, two or more R₄ can be same or different,
each of R₃ and R₄ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
in Formula 1-2, each of a5, a7, a8, a9 and a10 is independently an integer of 0 to 4, a6 is an integer of 0 to 3, n2 is 0 or 1,
when a5 is 2 or more, two or more R₅ can be same or different, when a6 is 2 or more, two or more R₆ can be same or different, when a7 is 2 or more, two or more R₇ can be same or different, when a8 is 2 or more, two or more R₈ can be same or different, when a9 is 2 or more, two or more R₉ can be same or different, when a10 is 2 or more, two or more R₁₀ can be same or different, and
each of R₅, R₆, R₇, R₈, R₉ and R₁₀ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group.

In each of Formulas 1-1 and 1-2, the “*” mark represents a bonding site.

In the present disclosure, without specific definition, a substituent of an alkyl group, an alkoxy group, a cycloalkyl group, an alkylamino group, an alkylsilyl group, an alkylgermanyl group, an alkenyl group, an alkynyl group, an arylamino group, an arylsilyl group, an aryloxy group, an arylgermanyl group, an aryl group and a heteroaryl group can be selected from deuterium, halogen, cyano, an alkyl group unsubstituted or substituted with at least one of deuterium and halogen, an alkoxy group unsubstituted or substituted with at least one of deuterium and halogen, an alkylsilyl group unsubstituted or substituted with at least one of deuterium and halogen, an alkoxysilyl group unsubstituted or substituted with at least one of deuterium and halogen, a cycloalkyl group unsubstituted or substituted with at least one of deuterium, halogen and a C1 to C20 alkyl group, an arylsilyl group unsubstituted or substituted with at least one of deuterium, halogen and a C1 to C20 alkyl group, an aryl group unsubstituted or substituted with at least one of deuterium, halogen and a C1 to C20 alkyl group and a heteroaryl group unsubstituted or substituted with at least one of deuterium, halogen and a C1 to C20 alkyl group.

In the present disclosure, without specific definition, a C1 to C20 alkyl group or an alkyl group can include a linear alkyl group and a branched alkyl group. For example, a C1 to C20 alkyl group or an alkyl group can be selected from the group consisting of methyl, ethyl, propyl and butyl, e.g., n-butyl or tert-butyl.

In the present disclosure, without specific definition, a C3 to C30 cycloalkyl group can be selected from the group consisting of cyclopropyl, cyclobutyl, cyclohexyl and adamantanyl.

In the present disclosure, without specific definition, a C6 to C30 arylsilyl group can be triphenylsilyl. In the present disclosure, without specific definition, a C6 to C60 arylamino group can include a C6 to C30 arylamino group, e.g., diphenylamino.

In the present disclosure, without specific definition, a ring formed by adjacent two substituents (or groups) can be one of a substituted or unsubstituted C3 to C30 alicyclic ring, a substituted or unsubstituted C6 to C30 aromatic ring and a substituted or unsubstituted C3 to C30 heteroaromatic ring.

In the present disclosure, without specific definition, a C6 to C30 aryl group can be selected from the group consisting of phenyl, biphenyl, terphenyl, naphthyl, anthracenyl, pentalenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C60 heteroaryl group can include a C3 to C30 heteroaryl group or a C3 to C20 heteroaryl group, and can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In an aspect of the present disclosure, each of R₁ to R₁₀ can be independently deuterium or a structure of Formula 1-3:

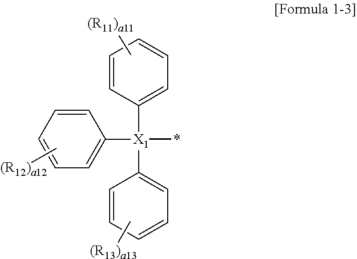

In Formula 1-3,
each of a11, a12 and a13 is independently an integer of 0 to 5,
when a11 is 2 or more, two or more R₁₁ can be same or different, when a12 is 2 or more, two or more R₁₂ can be same or different, when a13 is 2 or more, two or more R₁₃ can be same or different,
each of R₁₁, R₁₂ and R₁₃ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
X₁ is one of C, Si and Ge.

In Formula 1-3, the “*” mark represents a bonding site.

In an aspect of the present disclosure, X₁ can be Si.

In an aspect of the present disclosure, each of a1 and a2 can be 0.

In an aspect of the present disclosure, a1 can be 1, and R₁ can be selected from the group consisting of a C1 to C20 alkyl group substituted with a substituted or unsubstituted C6 to C30 aryl group, a substituted or unsubstituted C6 to C30 arylsilyl group and a substituted or unsubstituted C6 to C30 arylgermanyl group. For example, R₁ can be selected from the group consisting of triphenylmethyl, triphenylsilyl and triphenylgermanyl ((C₆H₅)₃Ge).

In an aspect of the present disclosure, a1 can be 4, and R₁ can be deuterium.

In an aspect of the present disclosure, a2 can be 4, and R₂ can be deuterium.

In an aspect of the present disclosure, each of a3 and a4 can be 0.

In an aspect of the present disclosure, a3 can be 1, and R₃ can be selected from the group consisting of a C1 to C20 alkyl group substituted with a substituted or unsubstituted C6 to C30 aryl group, a substituted or unsubstituted C6 to C30 arylsilyl group and a substituted or unsubstituted C6 to C30 arylgermanyl group. For example, R₃ can be selected from the group consisting of triphenylmethyl, triphenylsilyl and triphenylgermanyl ((C₆H₅)₃Ge).

In an aspect of the present disclosure, each of a3 and a4 can be 4, and each of R₃ and R₄ can be deuterium.

In an aspect of the present disclosure, each of a5 and a6 can be 0.

In an aspect of the present disclosure, a5 can be 1, and R₅ can be selected from the group consisting of a C1 to C20 alkyl group substituted with a substituted or unsubstituted C6 to C30 aryl group, a substituted or unsubstituted C6 to C30 arylsilyl group and a substituted or unsubstituted C6 to C30 arylgermanyl group. For example, R₅ can be selected from the group consisting of triphenylmethyl, triphenylsilyl and triphenylgermanyl ((C₆H₅)₃Ge).

In an aspect of the present disclosure, a5 can be 4, a6 can be 3, and each of R₅ and R₆ can be deuterium.

In an aspect of the present disclosure, each of a7 and a8 can be 0.

In an aspect of the present disclosure, a7 can be 1, and R₇ can be selected from the group consisting of a C1 to C20 alkyl group substituted with a substituted or unsubstituted C6 to C30 aryl group, a substituted or unsubstituted C6 to C30 arylsilyl group and a substituted or unsubstituted C6 to C30 arylgermanyl group. For example, R₇ can be selected from the group consisting of triphenylmethyl, triphenylsilyl and triphenylgermanyl ((C₆H₅)₃Ge).

In an aspect of the present disclosure, a7 can be 4, a8 can be 3, and each of R₇ and R₈ can be deuterium.

In an aspect of the present disclosure, each of a9 and a10 can be 0.

In an aspect of the present disclosure, a9 can be 1, and R₉ can be selected from the group consisting of a C1 to C20 alkyl group substituted with a substituted or unsubstituted C6 to C30 aryl group, a substituted or unsubstituted C6 to C30 arylsilyl group and a substituted or unsubstituted C6 to C30 arylgermanyl group. For example, R₉ can be selected from the group consisting of triphenylmethyl, triphenylsilyl and triphenylgermanyl ((C₆H₅)₃Ge).

In an aspect of the present disclosure, a9 can be 4, and R₉ can be deuterium.

In an aspect of the present disclosure, a10 can be 4, and R₁₀ can be deuterium.

In Formula 1-2, a bonding position of the carbazole moiety can be specified. For example, Formula 1-2 can be represented by one of Formulas 1-2a, 1-2b, 1-2c and 1-2d.

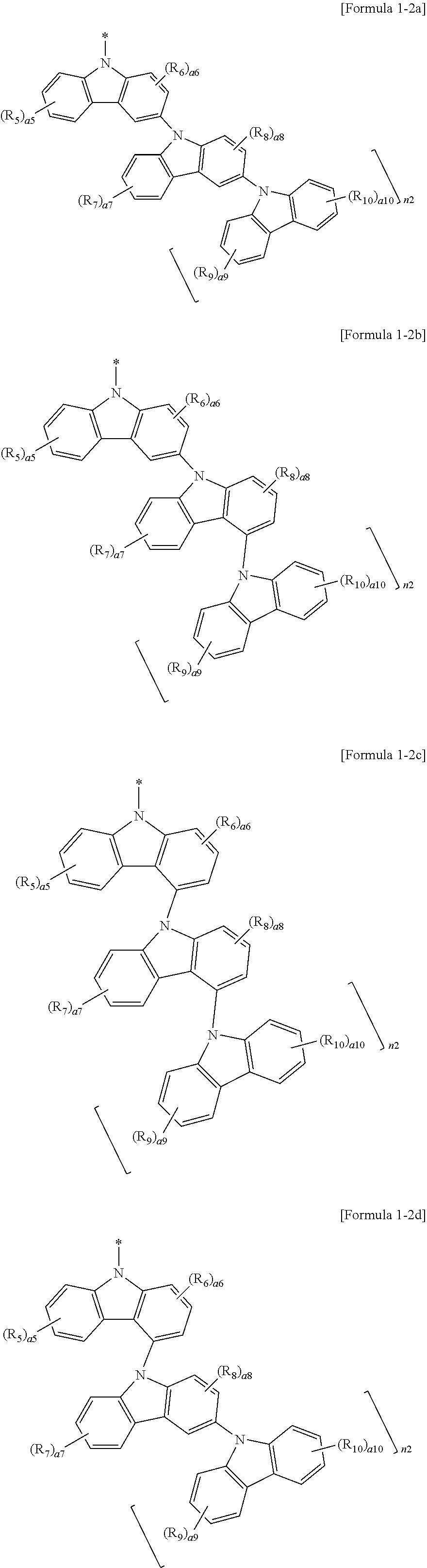

In each of Formulas 1-2a to 1-2d, the definitions of a5 to a10, R₅ to R₁₀ and n1 are same those in Formula 1-2.

For example, each of the first p-type host 252 and the second p-type host 262 can be independently one of the compounds in Formula 2. The first p-type host 252 and the second p-type host 262 can be same or different.

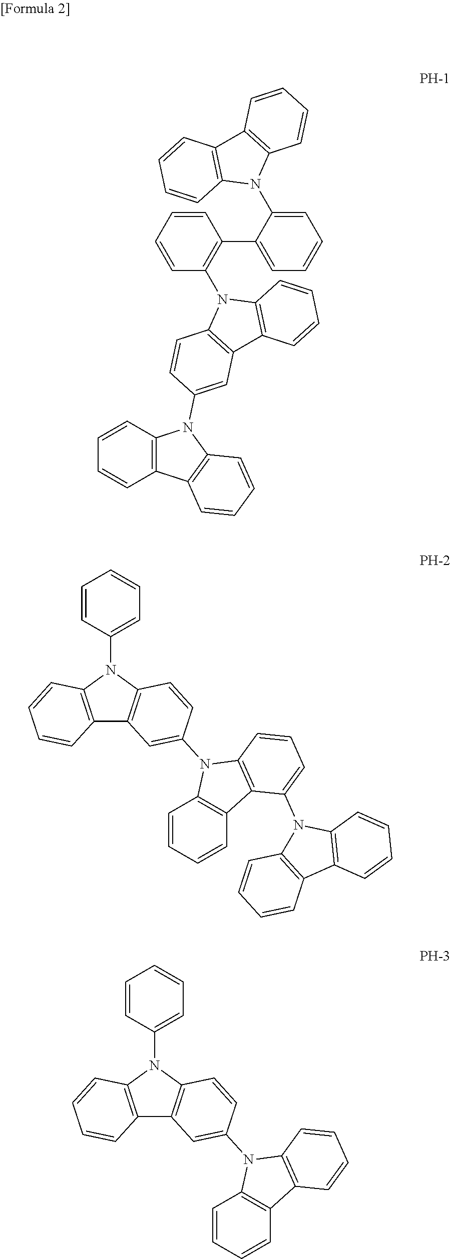 [SMILES: c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3cc(-n4c5ccccc5c5c(-n6c7ccccc7c7ccccc76)cccc54)ccc32)cc1 ; c1ccc(-n2c3ccccc3c3cc(-n4c5ccccc5c5ccccc54)ccc32)cc1]

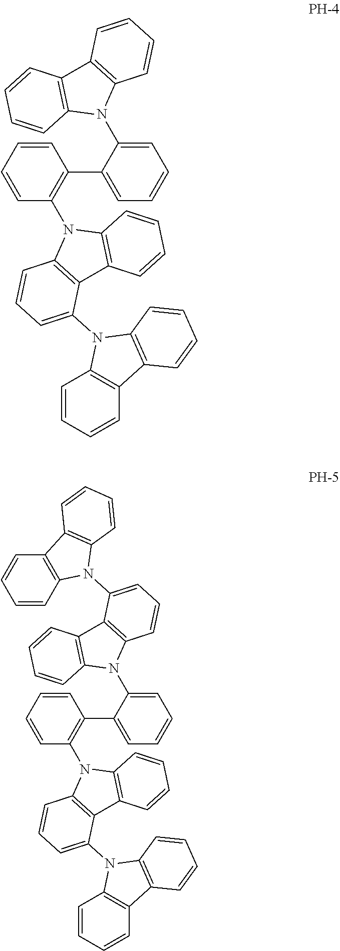 [SMILES: c1ccc(-n2c3ccccc3c3ccccc32)c(-c2ccccc2-n2c3ccccc3c3c(-n4c5ccccc5c5ccccc54)cccc32)c1 ; c1ccc(-n2c3ccccc3c3c(-n4c5ccccc5c5ccccc54)cccc32)c(-c2ccccc2-n2c3ccccc3c3c(-n4c5ccccc5c5ccccc54)cccc32)c1]

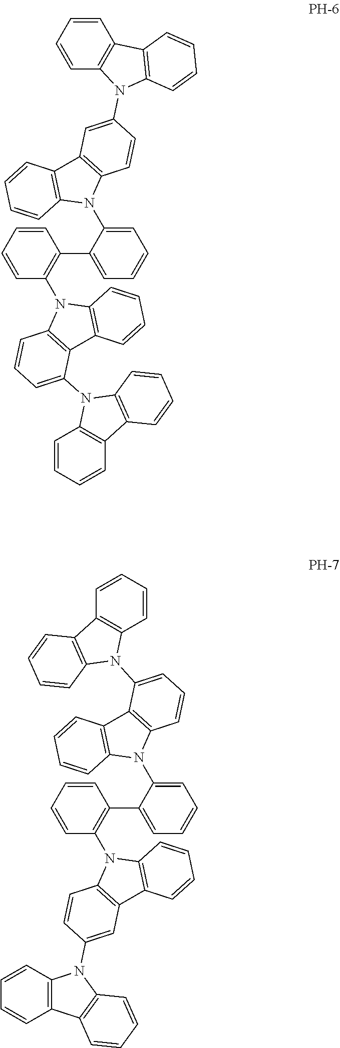 [SMILES: c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1]

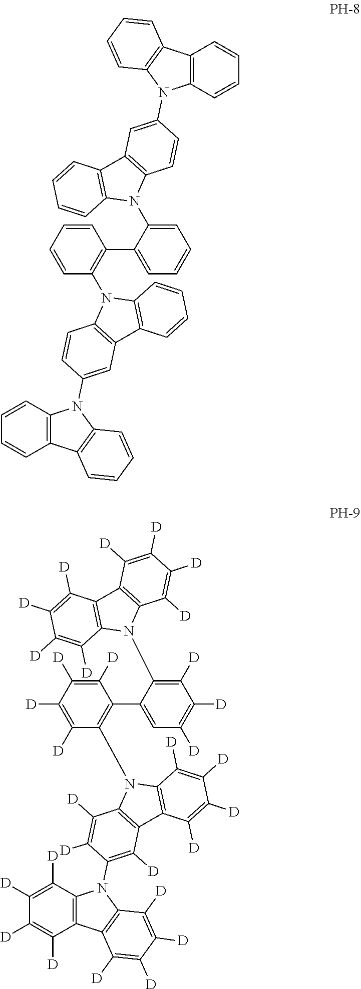 [SMILES: c1ccc(-n2c3ccccc3c3cc(-n4c5ccccc5c5ccccc54)ccc32)c(-c2ccccc2-n2c3ccccc3c3cc(-n4c5ccccc5c5ccccc54)ccc32)c1 ; [2H]c1cc(-c2c([2H])c([2H])c([2H])c([2H])c2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c(-n2c3c([2H])c([2H])c([2H])c([2H])c3c3c([2H])c([2H])c([2H])c([2H])c32)c([2H])c1[2H]]

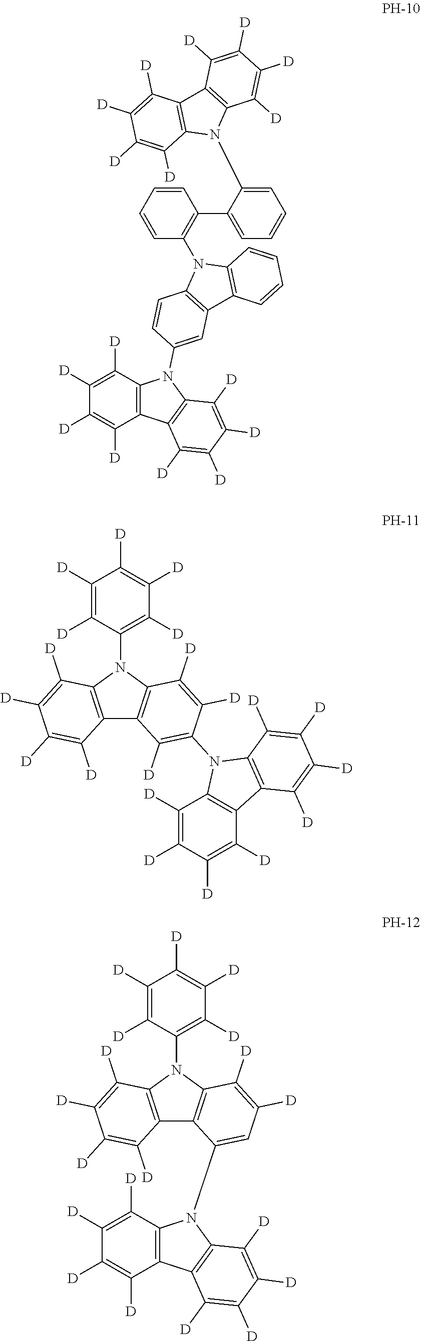

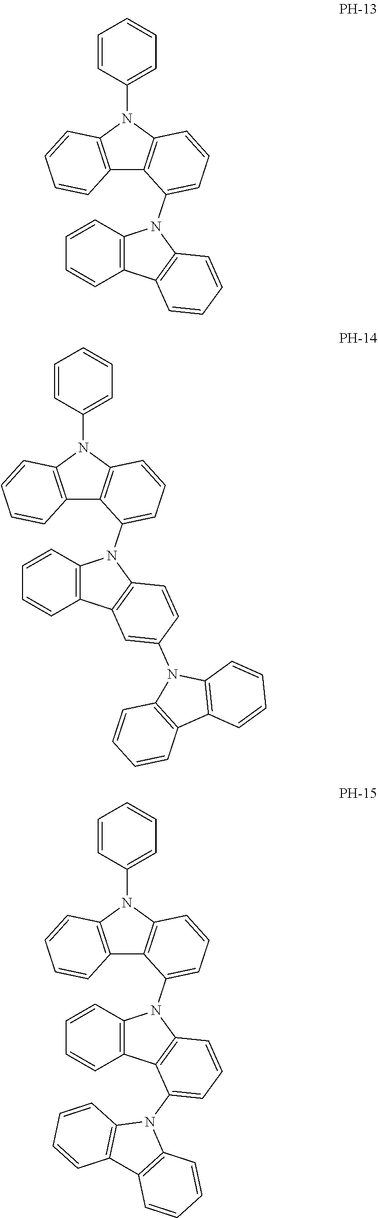

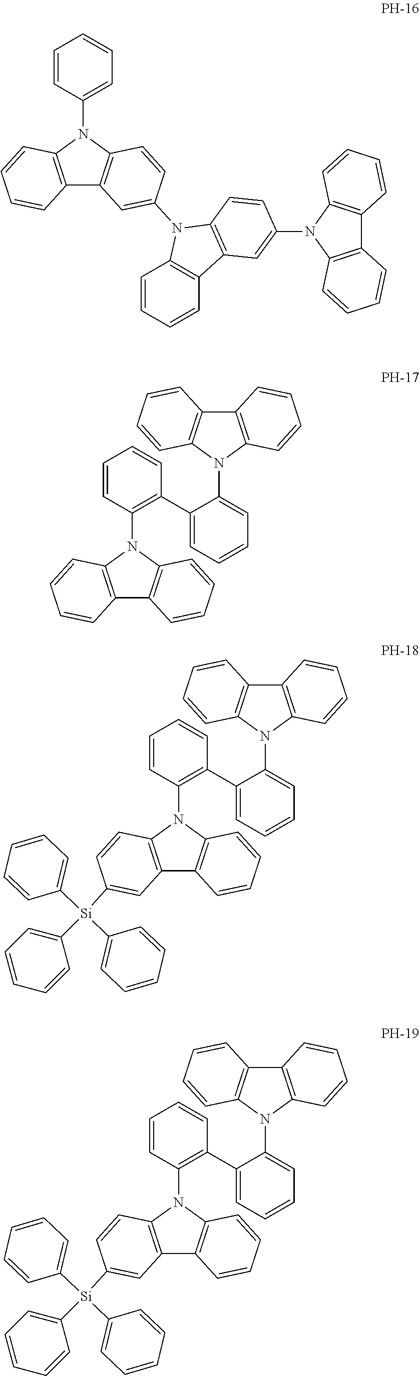 [SMILES: c1ccc(-n2c3ccccc3c3cc(-n4c5ccccc5c5cc(-n6c7ccccc7c7ccccc76)ccc54)ccc32)cc1 ; c1ccc(-n2c3ccccc3c3ccccc32)c(-c2ccccc2-n2c3ccccc3c3ccccc32)c1 ; c1ccc([Si](c2ccccc2)(c2ccccc2)c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3ccccc32)cc1]

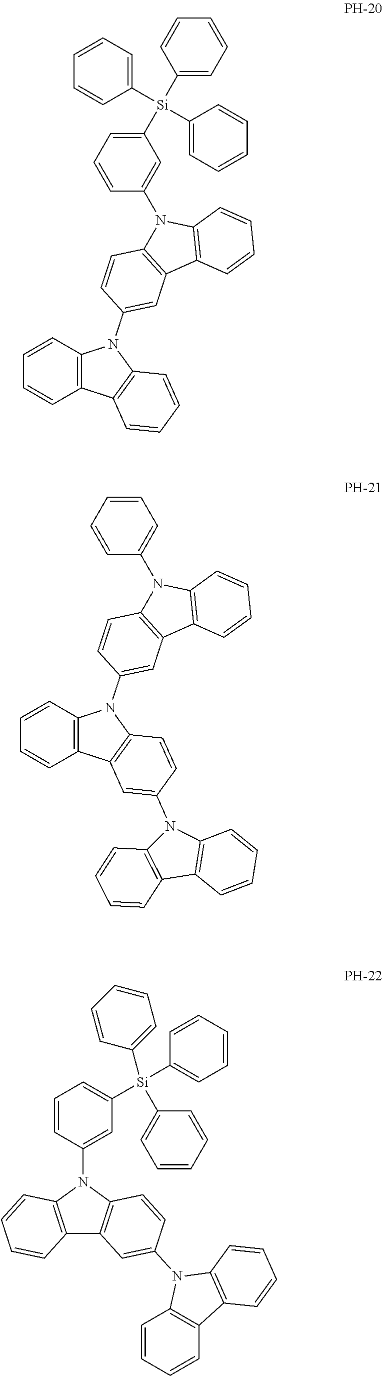 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc(-n2c3ccccc3c3cc(-n4c5ccccc5c5cc(-n6c7ccccc7c7ccccc76)ccc54)ccc32)cc1 ; c1ccc([Si](c2ccccc2)(c2ccccc2)c2cccc(-n3c4ccccc4c4cc(-n5c6ccccc6c6ccccc65)ccc43)c2)cc1]

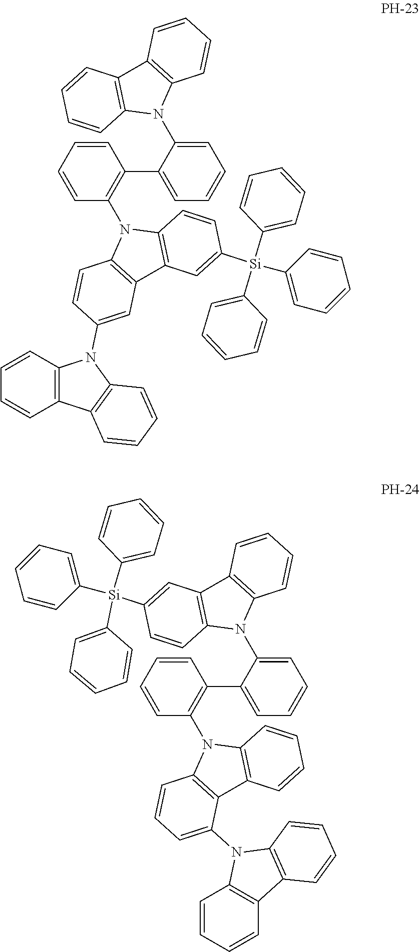 [SMILES: c1ccc([Si](c2ccccc2)(c2ccccc2)c2ccc3c(c2)c2cc(-n4c5ccccc5c5ccccc54)ccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3c(-n4c5ccccc5c5ccccc54)cccc32)cc1]

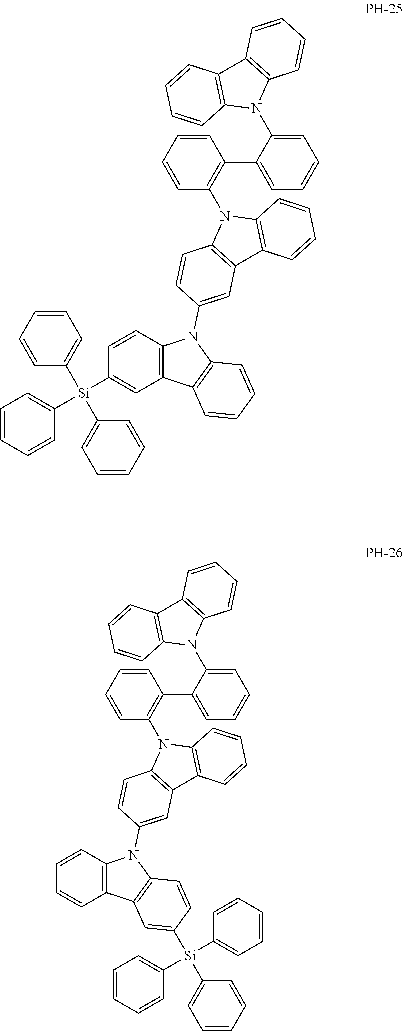 [SMILES: c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1]

One of the first n-type host 254 and the second n-type host 264 is represented by Formula 3.

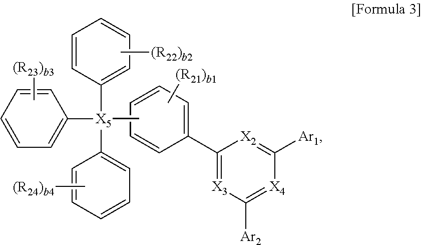

In Formula 3, b1 is an integer of 0 to 4, each of b2, b3 and b4 is independently an integer of 0 to 5,
when b1 is 2 or more, two or more R₂₁ can be same or different, when b2 is 2 or more, two or more R₂₂ can be same or different, when b3 is 2 or more, two or more R₂₃ can be same or different, when b4 is 2 or more, two or more R₂₄ can be same or different,
each of X₂, X₃ and X₄ is independently selected from N and CR₂₉, at least one of X₂, X₃ and X₄ is N,
R₂₁, R₂₂, R₂₃ and R₂₄ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
R₂₉ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C30 heteroaryl group, and
X₅ is one of C, Si and Ge.

In an aspect of the present disclosure, each of b1 to b4 can be 0.

In an aspect of the present disclosure, b1 can be 4, each of b2 to b4 can be 5, and each of R₂₁ to R₂₄ can be deuterium.

In an aspect of the present disclosure, each of X₂, X₃ and X₄ can be N.

In an aspect of the present disclosure, X₅ can be Si.

In an aspect of the present disclosure, each of Ar₁ and Ar₂ can be independently selected from the group consisting of a substituted or unsubstituted C6 to C30 aryl group, e.g., phenyl, and a substituted or unsubstituted C3 to C30 heteroaryl group, e.g., carbazolyl.

For example, Formula 3 can be represented by Formula 3a.

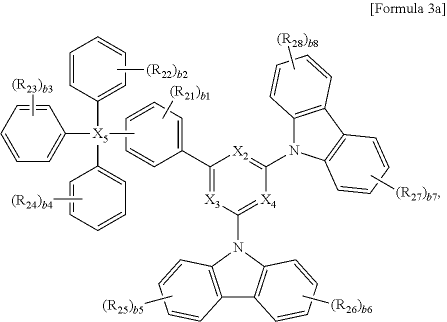

In Formula 3a, the definitions of b1 to b4 and R₂₁ to R₂₄ are same as those in Formula 3,
each of b5, b6, b7 and b8 is independently an integer of 0 to 4,
when b5 is 2 or more, two or more R₂₅ can be same or different, when b6 is 2 or more, two or more R₂₆ can be same or different, when b7 is 2 or more, two or more R₂₇ can be same or different, when b8 is 2 or more, two or more R₂₈ can be same or different, and
R₂₅, R₂₆, R₂₇ and R₂₈ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or, optionally, adjacent two of R₂₅, R₂₆, R₂₇ and R₂₈ are combined to form a ring.

In an aspect of the present disclosure, each of b5 to b8 can be 0.

In an aspect of the present disclosure, each of b5 to b8 can be 4, and each of R₂₅ to R₂₈ can be deuterium.

In an aspect of the present disclosure, b5 can be 1, R₂₅ can be a substituted or unsubstituted C3 to C30 heteroaryl group, e.g., carbazolyl.

For example, the compound represented by Formula 3 can be one of the compounds in Formula 4.

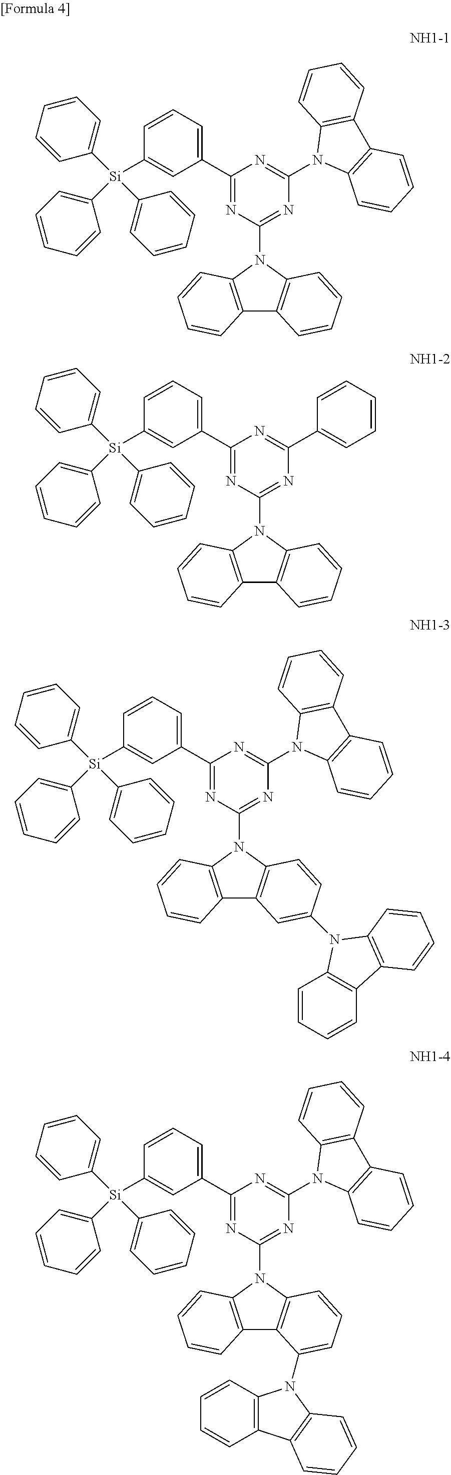

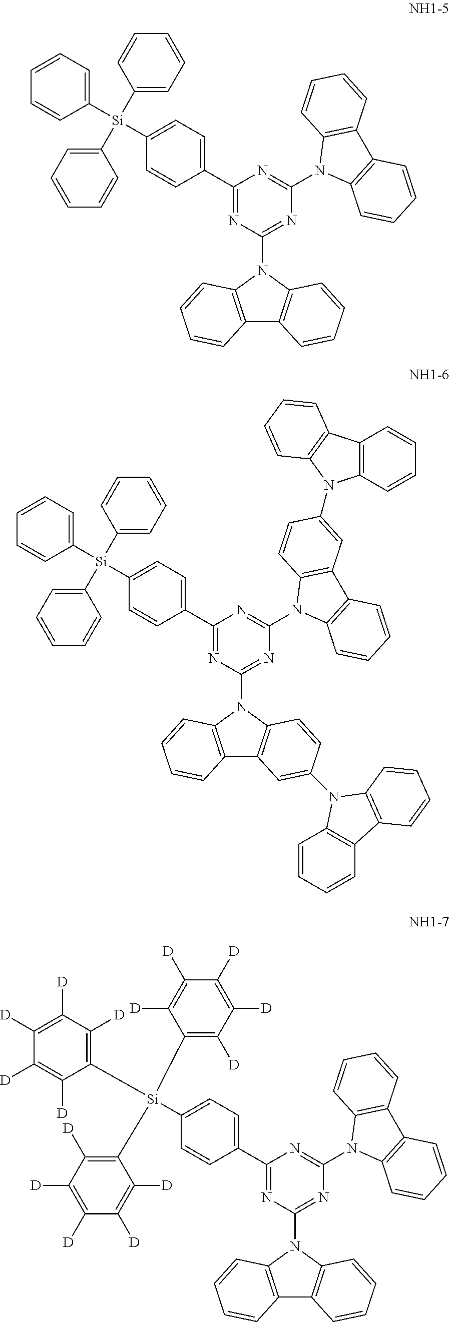 [SMILES: c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1 ; [2H]c1c([2H])c([2H])c([Si](c2ccc(-c3nc(-n4c5ccccc5c5ccccc54)nc(-n4c5ccccc5c5ccccc54)n3)cc2)(c2c([2H])c([2H])c([2H])c([2H])c2[2H])c2c([2H])c([2H])c([2H])c([2H])c2[2H])c([2H])c1[2H]]

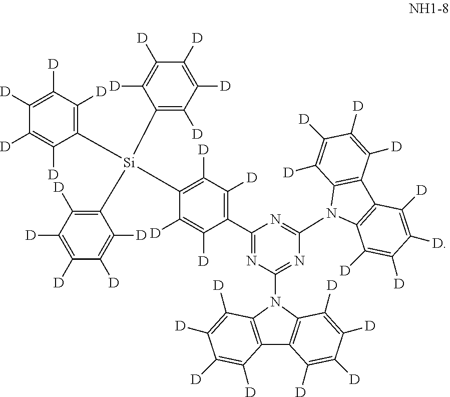

The other one of the first and second n-type hosts 254 and 264 is represented by Formula 5.

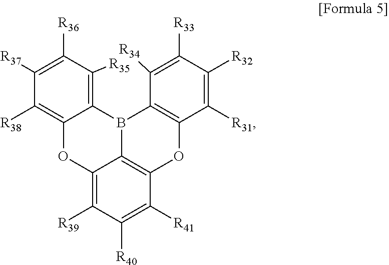

In Formula 5,
one of R₃₁ to R₄₁ is represented by Formula 5-1, at least one of R₃₁ to R₄₁ is represented by Formula 5-2,
each of the rest of R₃₁ to R₄₁ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or optionally, adjacent two of the rest of R₃₁ to R₄₁ are combined to form a ring,

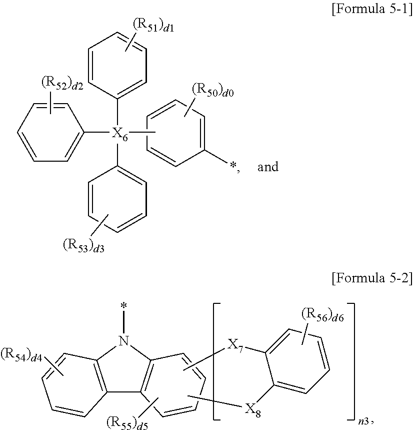

In Formula 5-1, d0 is an integer of 0 to 4, each of d1, d2 and d3 is independently an integer of 0 to 5,
when d0 is 2 or more, two or more R₅₀ can be same or different, when d1 is 2 or more, two or more R₅₁ can be same or different, when d2 is 2 or more, two or more R₅₂ can be same or different, when d3 is 2 or more, two or more R₅₃ can be same or different,
each of R₅₀, R₅₁, R₅₂ and R₅₃ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
X₆ is one of C, Si and Ge,
in Formula 5-2, n3 is 0 or 1, each of d4 and d6 is independently an integer of 0 to 4, d5 is an integer of 0 to 2,
when d4 is 2 or more, two or more R₅₄ can be same or different, when d5 is 2 or more, two or more R₅₅ can be same or different, when d6 is 2, two R₅₆ can be same or different,
each of R₅₄, R₅₅ and R₅₆ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
one of X₇ and X₈ is a single bond, the other one of X₇ and X₈ is selected from NR₅₇, CR₅₈R₅₉, O and S, and
each of R₅₇, R₅₈ and R₅₉ is independently selected from the group consisting of hydrogen, deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

In each of Formulas 5-1 and 5-2, the “*” mark represents a bonding site.

In an aspect of the present disclosure, one or two of R₃₁ to R₄₁ can be represented by Formula 5-2.

In an aspect of the present disclosure, adjacent two of R₃₁ to R₄₁ can have a structure of Formula 5-1 and a structure of Formula 5-2, respectively.

In an aspect of the present disclosure, one of R₃₁ to R₃₄ can have a structure of Formula 5-1, and another one of R₃₁ to R₃₄ can have a structure of Formula 5-2.

In an aspect of the present disclosure, R₃₂ can have a structure of Formula 5-2, and R₃₁ or R₃₃ can have a structure of Formula 5-1. Namely, a carbazole moiety or a fused-carbazole moiety of Formula 5-2 can be bonded at a para-position with respect to a boron atom, and the structure of Formula 5-1 can be boned at an ortho-position with respect to a carbazole moiety or a fused-carbazole moiety of Formula 5-2. The lifespan of the OLED D1 and the organic light emitting display device 100 each including the compound having the above structure can be significantly increased.

In an aspect of the present disclosure, one of R₃₁ to R₃₄ can have a structure of Formula 5-1, and two of R₃₁ to R₃₄ can have a structure of Formula 5-2.

In an aspect of the present disclosure, one of R₃₉ to R₄₁ can have a structure of Formula 5-1, and another one of R₃₁ to R₃₄ can have a structure of Formula 5-2.

In an aspect of the present disclosure, one of R₃₁ to R₃₄ can have a structure of Formula 5-1, and another one of R₃₁ to R₃₄ and one of R₃₉ to R₄₁ can have a structure of Formula 5-2.

In an aspect of the present disclosure, one of R₃₁ to R₃₄ can have a structure of Formula 5-1, and another one of R₃₁ to R₃₄ and one of R₃₅ to R₃₈ can have a structure of Formula 5-2.

In an aspect of the present disclosure, one of R₃₁ to R₃₄ can have one of a structure of Formula 5-1 and a structure of Formula 5-2, and one of R₃₅ to R₃₈ can have the other one of a structure of Formula 5-1 and a structure of Formula 5-2.

In an aspect of the present disclosure, one of R₃₁ to R₃₄ can have one of a structure of Formula 5-1 and a structure of Formula 5-2, and one of R₃₉ to R₄₁ can have the other one of a structure of Formula 5-1 and a structure of Formula 5-2.

In an aspect of the present disclosure, one of X₇ and X₈ can be a single bond, the other one of X₇ and X₈ can be NR₅₇.

In an aspect of the present disclosure, each of d1 to d3 can be 0.

In an aspect of the present disclosure, each of d4 to d6 can be 0.

In an aspect of the present disclosure, d4 can be 1, R₅₄ can be a substituted or unsubstituted C3 to C30 heteroaryl group, e.g., carbazolyl.

For example, the compound represented by Formula 5 can be one of the compounds in Formula 6.

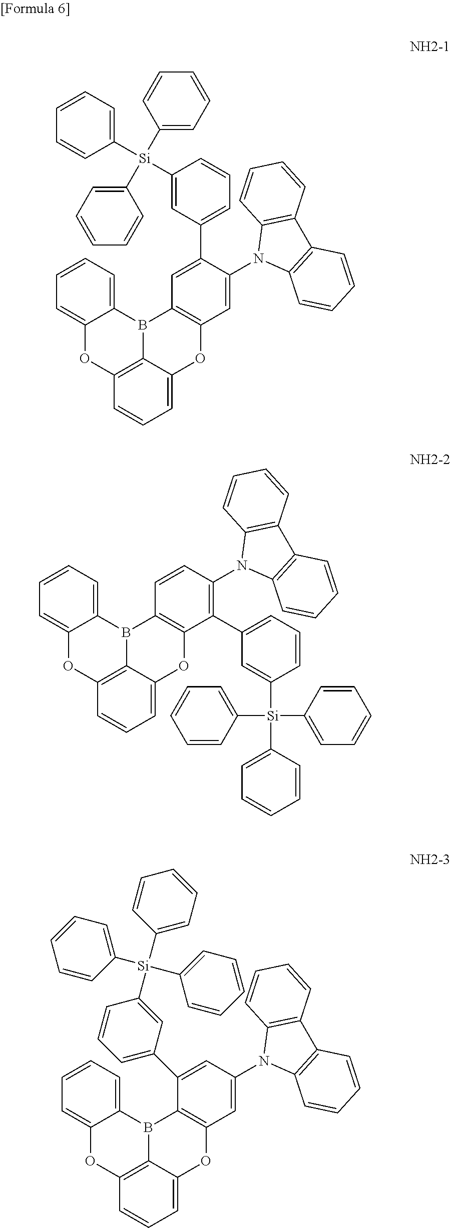 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

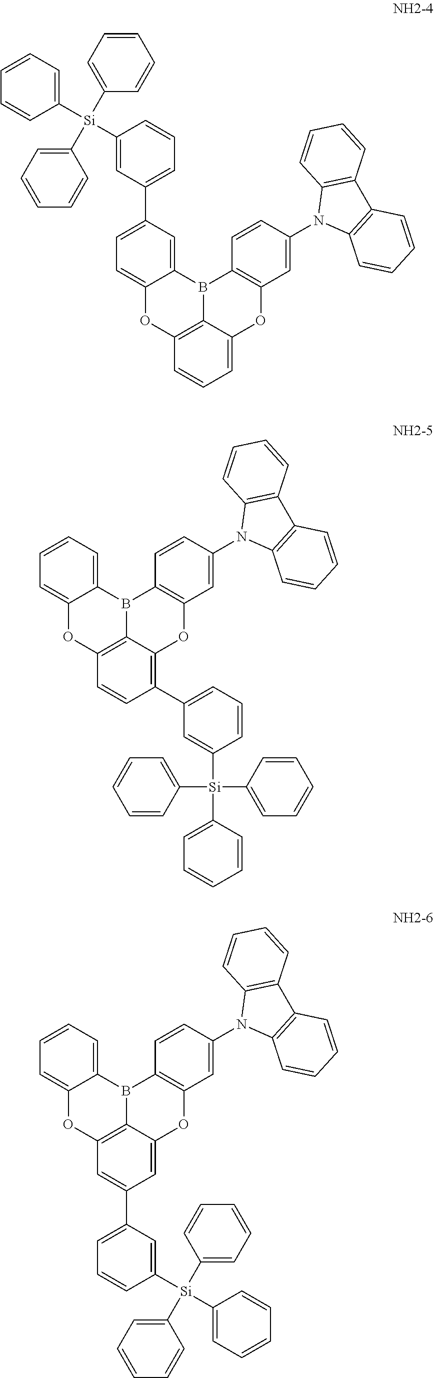 [SMILES: c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1]

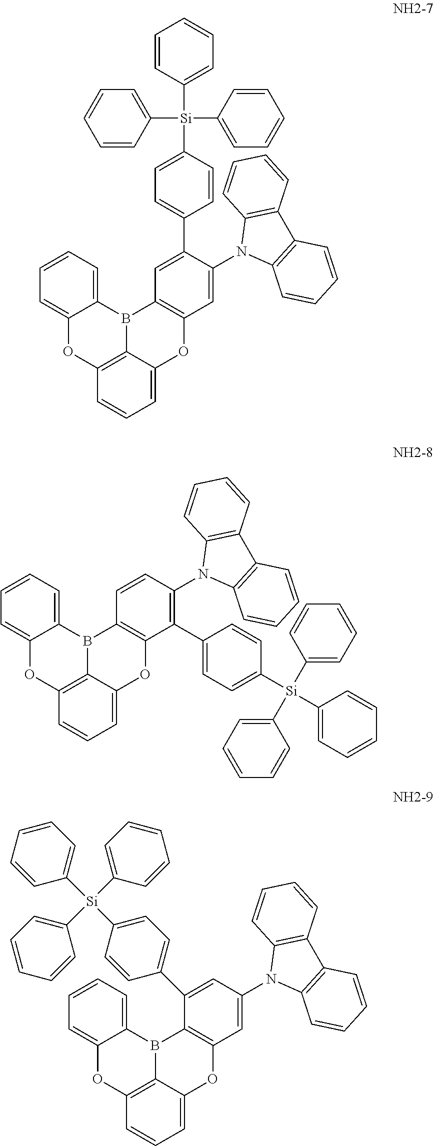 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

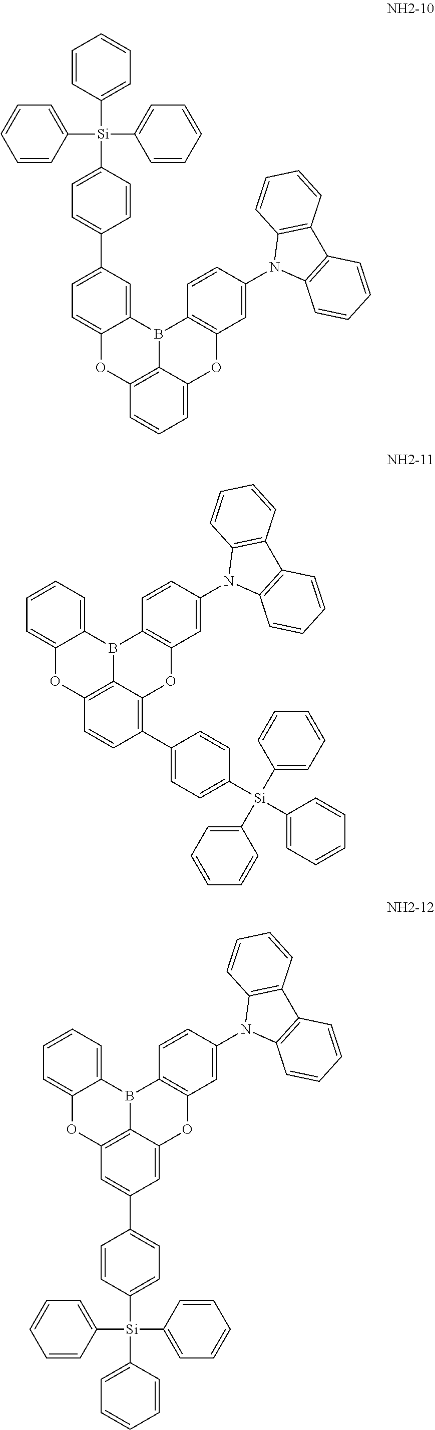 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

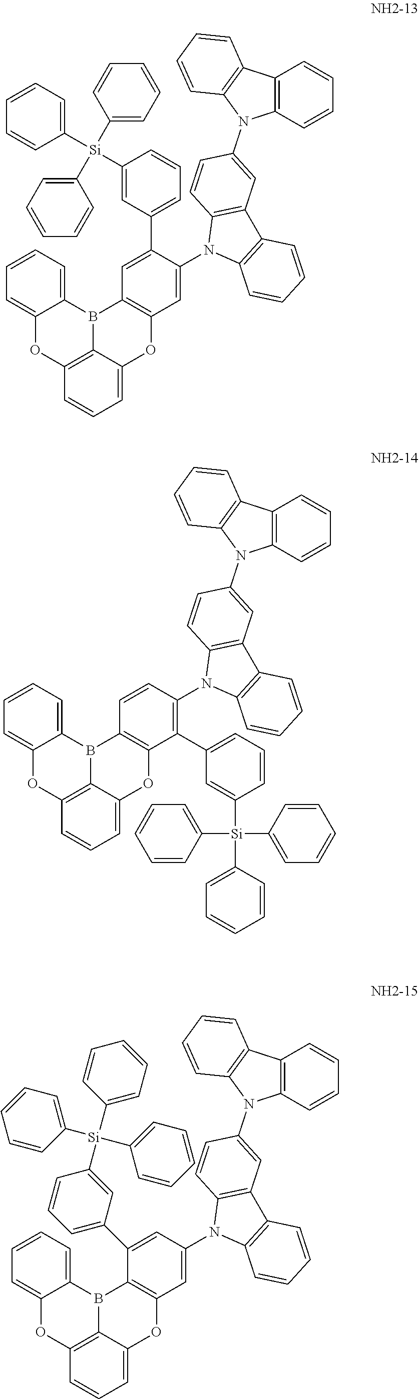 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

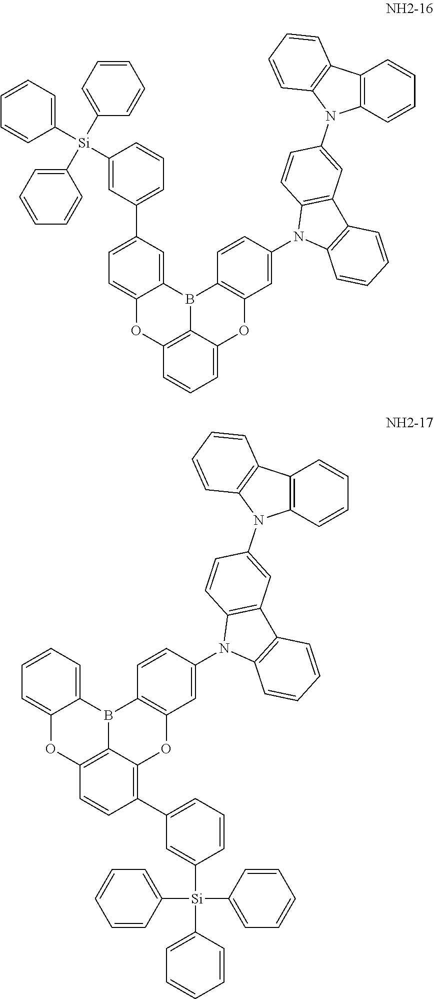

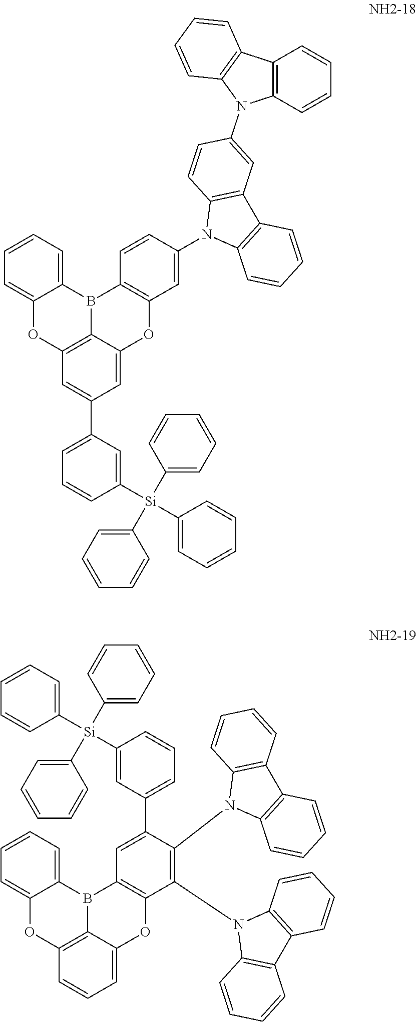 [SMILES: c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1]

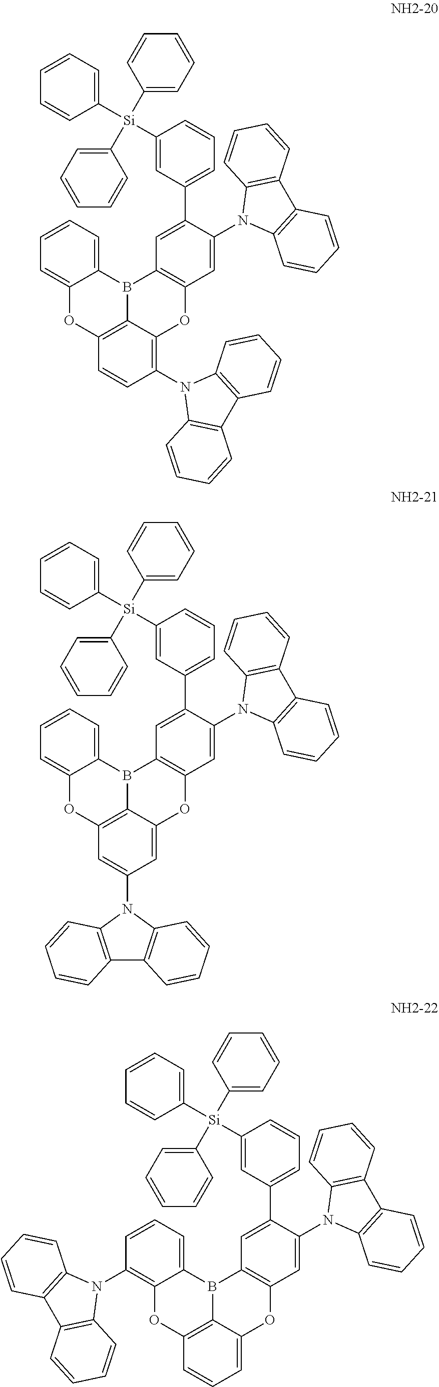

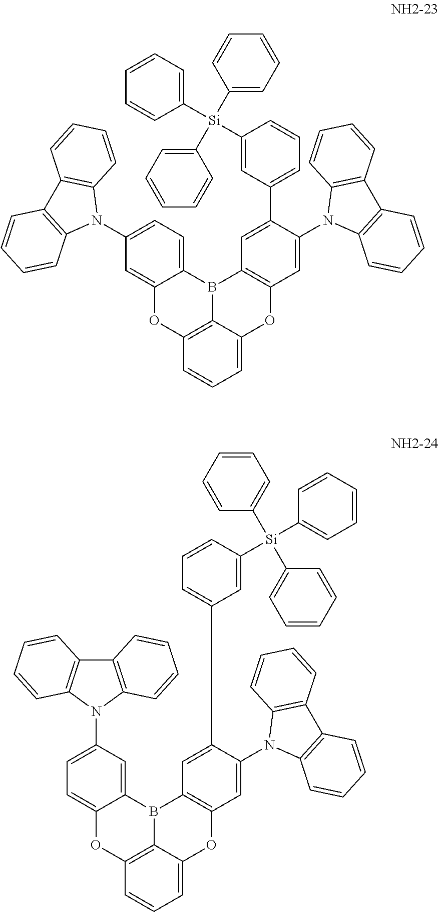 [SMILES: c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

Each of the first and second phosphorescent dopants 246 and 266 is independently represented by Formula 7.

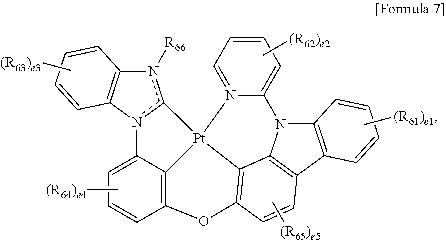

In Formula 7, each of e1, e2 and e3 is independently an integer of 0 to 4, e4 is an integer of 0 to 3, e5 is an integer of 0 to 2,
when e1 is 2 or more, two or more R₆₁ can be same or different, when e2 is 2 or more, two or more R₆₂ can be same or different, when e3 is 2 or more, two or more R₆₃ can be same or different, when e4 is 2 or more, two or more R₆₄ can be same or different, when e5 is 2, two R₆₅ can be same or different,
each of R₆₁ to R₆₅ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
R₆₆ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

In an aspect of the present disclosure, each of R₆₁ to R₆₆ can be independently selected from the group consisting of a substituted or unsubstituted C1 to C20 alkyl group, e.g., methyl or tert-butyl, a substituted or unsubstituted C3 to C20 cycloalkyl group, e.g., adamantanyl, a substituted or unsubstituted C6 to C30 aryl group, e.g., phenyl or terphenyl, and a substituted or unsubstituted C3 to C30 heteroaryl group, e.g., carbazolyl.

In an aspect of the present disclosure, at least one of e1 to e5 can be a positive integer.

The compound represented by Formula 7 can have a maximum emission wavelength in a range of 450 to 470 nm. A ratio of a second emission peak intensity to a first emission intensity can be 0.7 or less. For example, the compound represented by Formula 7 can have a maximum emission wavelength of 460 nm, and a ratio of a second emission peak intensity to a first emission intensity can be 0.56. In this case, the first emission peak intensity can be an emission intensity at a maximum emission wavelength, and the second emission peak intensity can be an emission intensity at a peak having a second highest emission wavelength.

For example, each of the first and second phosphorescent dopants 256 and 266 can be independently one of the compounds in Formula 8. The first and second phosphorescent dopants 256 and 266 can be same or different.

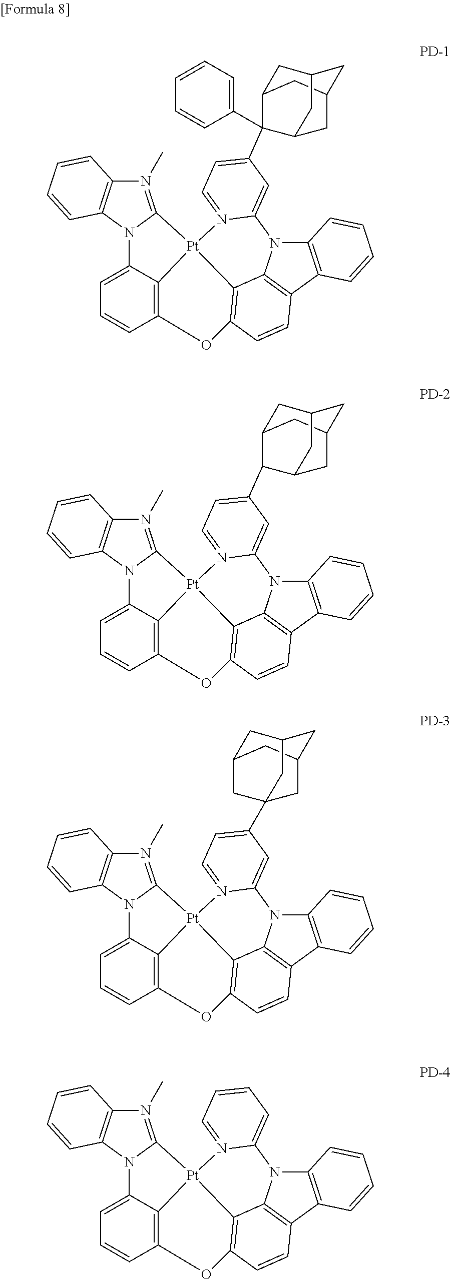

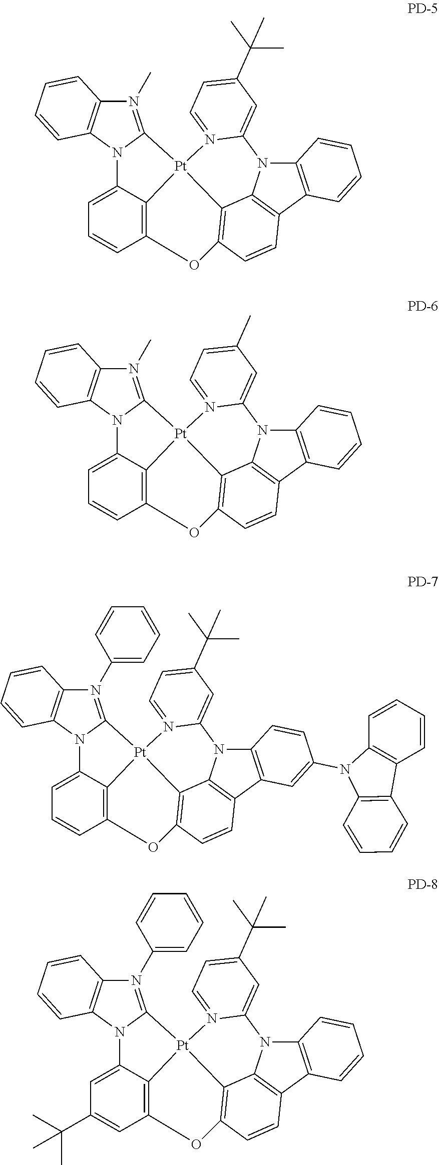

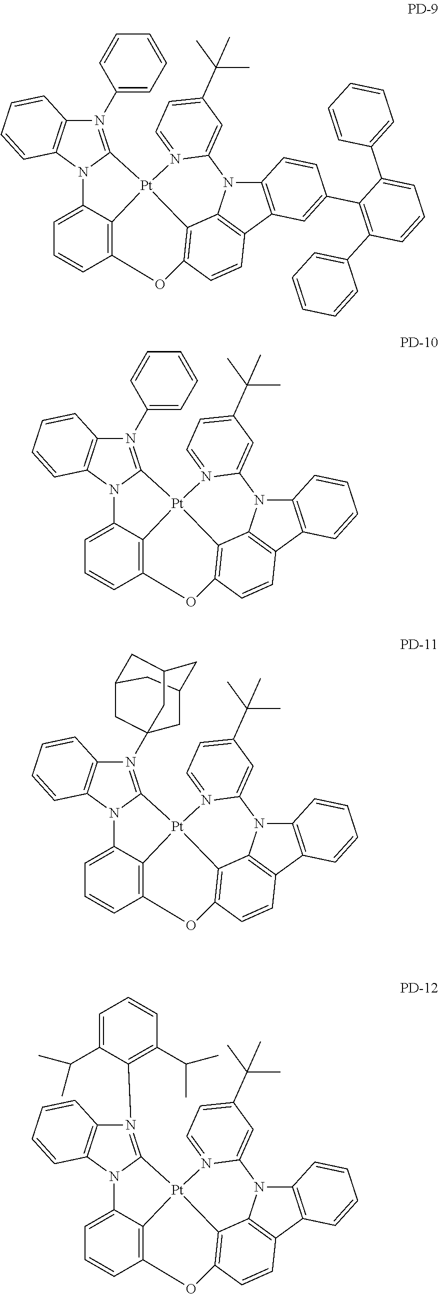

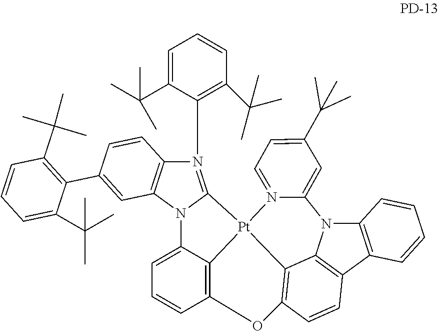

In an aspect of the present disclosure, the first n-type host 254 in the first blue emitting layer 250 can be the compound represented by Formula 3, and the second n-type host 264 in the second blue emitting layer 260 can be the compound represented by Formula 5.

In the first blue emitting layer 250, a maximum emission wavelength (Δmax__{(PH1:NH1)}) of a mixture of the first p-type host 252 and the first n-type host 254 can be 480 nm or less, a maximum emission wavelength (λmax__{NH1}) of the first n-type host 254 can be shorter (e.g., smaller) than the maximum emission wavelength (λmax__{(PH1:NH1)}) of the mixture of the first p-type host 252 and the first n-type host 254 and longer (e.g., greater) than a maximum emission wavelength (λmax__{PH1}) of the first p-type host 252. (480 nm>λmax__{(PH1:NH1)}>λmax__{NH1}>λmax__{PH1})

In addition, in the first blue emitting layer 250, a difference between a lowest unoccupied molecular orbital (LUMO) energy level (LUMO_{PH1}) of the first p-type host 252 and a LUMO energy level (LUMO_{NH1}) of the first n-type host 254 can be greater than 0.3 eV, a difference between a highest occupied molecular orbital (HOMO) energy level (HOMO_{PH1}) of the first p-type host 252 and a HOMO energy level (HOMO_{NH1}) of the first n-type host 254 can be greater than 0.3 eV. (LUMO_{PH1}−LUMO_{NH1}>0.3 eV, HOMO_{PH1}−HOMO_{NH1}>0.3 eV)

In the second blue emitting layer 260, a difference (ΔE_{ST}) between a singlet energy level of the second n-type host 264 and a triplet energy level of the second n-type host 264 can be smaller than 0.3 eV. In addition, a LUMO energy level (LUMO_{NH2}) of the second n-type host 264 can be smaller than a LUMO energy level (LUMO_{PH2}) of the second p-type host 262 and can be equal to or greater than a LUMO energy level (LUMO_{PD2}) of the second phosphorescent dopant 266. (LUMO_{PH2}>LUMO_{NH2}>LUMO_{PD2}) For example, a LUMO energy level (LUMO_{PD2}) of the second phosphorescent dopant 266 can be −2.6 eV.

Moreover, in the second blue emitting layer 260, a maximum emission wavelength (λmax_{(PH2:NH2)}) of a mixture of the second p-type host 262 and the second n-type host 264 can be smaller than a maximum emission wavelength (λmax_{NH2}) of the second n-type host 264 and greater than a maximum emission wavelength (λmax_{PH2}) of the second p-type host 262. (λmax_{NH2}>λmax_{(PH2:NH2)}>λmax_{PH2}) Furthermore, a triplet energy level of each of the second p-type host 262, the second n-type host 264 and the second phosphorescent dopant 266 can be greater than 2.7 eV.

In this case, an exciplex property can be provided by the first p-type host 252 and the first n-type host 254 in the first blue emitting layer 250, and a delayed fluorescent property can be provided by the second p-type host 262 and the second n-type host 264 in the second blue emitting layer 260.

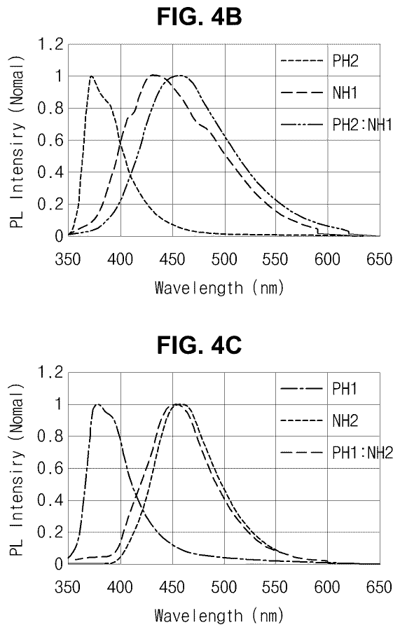

A PL spectrum of each of the compound PH-1 in Formula 2 and the compound NH1-1 in Formula 4, a PL spectrum of a mixture of the compound PH-1 in Formula 2 and the compound NH1-1 in Formula 4 were measured and shown in FIG. 4A, a PL spectrum of each of the compound PH-2 in Formula 2 and the compound NH1-1 in Formula 4, a PL spectrum of a mixture of the compound PH-2 in Formula 2 and the compound NH1-1 in Formula 4 were measured and shown in FIG. 4B.

As shown in FIG. 4A, a maximum emission wavelength in the PL spectrum of the mixture of the compound PH-1 in Formula 2 and the compound NH1-1 in Formula 4 is longer than each of a maximum emission wavelength in the PL spectrum of the compound PH-1 in Formula 2 and a maximum emission wavelength in the PL spectrum of the compound NH1-1 in Formula 4.

As shown in FIG. 4B, a maximum emission wavelength in the PL spectrum of the mixture of the compound PH-2 in Formula 2 and the compound NH1-1 in Formula 4 is longer than each of a maximum emission wavelength in the PL spectrum of the compound PH-2 in Formula 2 and a maximum emission wavelength in the PL spectrum of the compound NH1-1 in Formula 4.

Namely, an exciplex property is provided by a combination of a p-type host, which is represented by Formula 1 and selected from the compounds in Formula 2, and an n-type host, which is represented by Formula 3 and selected from the compounds in Formula 4.

A PL spectrum of each of the compound PH-1 in Formula 2 and the compound NH2-1 in Formula 6, a PL spectrum of a mixture of the compound PH-1 in Formula 2 and the compound NH2-1 in Formula 6 were measured and shown in FIG. 4C.

As shown in FIG. 4C, a maximum emission wavelength in the PL spectrum of the mixture of the compound PH-2 in Formula 2 and the compound NH2-1 in Formula 6 is longer than a maximum emission wavelength in the PL spectrum of the compound PH-2 in Formula 2 and is shorter than a maximum emission wavelength in the PL spectrum of the compound NH2-1 in Formula 6. Namely, an exciplex property is not provided by a combination of a p-type host, which is represented by Formula 1 and selected from the compounds in Formula 2, and an n-type host, which is represented by Formula 5 and selected from the compounds in Formula 6, and a delayed fluorescent property is provided by the combination of a p-type host, which is represented by Formula 1 and selected from the compounds in Formula 2, and an n-type host (e.g., the compound NH2-1), which is represented by Formula 5 and selected from the compounds in Formula 6.

In an aspect of the present disclosure, the first n-type host 254 in the first blue emitting layer 250, which is disposed to be closer to the first electrode 210 being an anode, can be the compound represented by Formula 5, the second n-type host 264 in the second blue emitting layer 260, which is disposed to be closer to the second electrode 230 being a cathode, can be the compound represented by Formula 3.

In the first blue emitting layer 250, a difference (ΔE_{ST}) between a single energy level of the first n-type host 254 and a triplet energy level of the first n-type host 254 can be smaller than 0.3 eV. In addition, a LUMO energy level (LUMO_{NH1}) of the first n-type host 254 can be smaller than a LUMO level (LUMO_{PH1}) of the first p-type host 252 and can be greater than a LUMO energy level (LUMO_{PD1}) of the first phosphorescent dopant 256. (LUMO_{PH1}>LUMO_{NH1}≥LUMO_{PD1}) For example, a LUMO energy level (LUMO_{PD1}) of the first phosphorescent dopant 256 can be −2.6 eV.

In addition, in the first blue emitting layer 250, a maximum emission wavelength (A max__{(PH1:NH1)}) of a mixture of the first p-type host 252 and the first n-type host 254 can be shorter than a maximum emission wavelength (λmax__{NH1}) of the first n-type host 254 and can be longer than a maximum emission wavelength (λmax__{PH1}) of the first p-type host 252. (λmax_{NH1}>λmax_{(PH1:NH1)}>λmax_{PH1}) A triplet energy level of each of the first p-type host 252, the first n-type host 254 and the first phosphorescent dopant 256 can be greater than 2.7 eV.

In the second blue emitting layer 260, a maximum emission wavelength (A max__{(PH2:NH2)}) of a mixture of the second p-type host 262 and the second n-type host 264 can be 480 nm or less, a maximum emission wavelength (λmax__{NH2}) of the second n-type host 264 can be shorter than the maximum emission wavelength (λmax__{(PH2:NH2)}) of the mixture of the second p-type host 262 and the second n-type host 264 and longer than a maximum emission wavelength (λmax__{PH2}) of the second p-type host 262. (480 nm>λmax__{(PH2:NH2)}>λmax_{NH2}>λmax__{PH2})

In addition, in the second blue emitting layer 260, a difference between a LUMO energy level (LUMO_{PH2}) of the second p-type host 262 and a LUMO energy level (LUMO_{NH2}) of the second n-type host 264 can be greater than 0.3 eV, a difference between a HOMO energy level (HOMO_{PH2}) of the second p-type host 262 and a HOMO energy level (HOMO_{NH2}) of the second n-type host 264 can be greater than 0.3 eV. (LUMO_{PH2}−LUMO_{NH2}>0.3 eV, HOMO_{PH2}−HOMO_{NH2}>0.3 eV)

In this case, a delayed fluorescent property can be provided by the first p-type host 252 and the first n-type host 254 in the first blue emitting layer 250, and an exciplex property can be provided by the second p-type host 262 and the second n-type host 264 in the second blue emitting layer 260.

A PL spectrum can be measured using an organic solvent, e.g., toluene, at room temperature, i.e., 25° C. For example, after a thin film having a thickness of 30 nm is formed using a solution, in which a compound dissolved in an organic solvent, e.g., toluene, with about 1*10⁻⁵M, a PL spectrum can be measured using a photoluminescence (PL) detection and a fluorescent spectrometer, e.g., FS-5 fluorescent spectrometer (Edinburgh Instruments).

Various methods of determining the HOMO energy level are known to the skilled person. For example, the HOMO energy level can be determined using a conventional surface analyzer such as an AC3 surface analyzer made by RKI instruments. The surface analyzer can be used to interrogate a single film (neat film) of a compound with a thickness of 50 nm. The LUMO energy level can be calculated as follows:

LUMO energy level (ev)=HOMO energy level (eV)−bandgap energy level (ev).

The bandgap can be measured using a SCINCO S-3100 spectrophotometer. The HOMO and LUMO values of the compounds of the examples and embodiments disclosed herein can be determined in this way. Namely, the HOMO and LUMO values can be experimentally or empirically determined values of thin films, such as 50 nm films.

Each of the first and second blue emitting layers 250 and 260 can have a thickness of 5 to 30 nm, e.g., 10 to 20 nm. For example, a thickness of each of the first and second blue emitting layers 250 and 260 can be 10 nm, 15 nm or 20 nm.

A thickness of the first emitting layer 250 and a thickness of the second blue emitting layer 260 can be same or different. In an aspect of the present disclosure, a thickness of the first emitting layer 250 and a thickness of the second blue emitting layer 260 can be same.

In the first blue emitting layer 250, a weight % of each of the first p-type host 252 and the first n-type host 254 can be greater than that of the first phosphorescent dopant 256, and a weight % of the first p-type host 252 and a weight % of the first n-type host 254 can be same or different. For example, a weight % of the first p-type host 252 and a weight % of the first n-type host 254 can be same.

In an aspect of the present disclosure, the first p-type host 252 can have a weight % of 25 to 50, the first n-type host 254 can have a weight % of 25 to 50, and the first phosphorescent dopant 256 can have a weight % of 4 to 25. In an aspect of the present disclosure, the first p-type host 252 can have a weight % of 44, the first n-type host 254 can have a weight % of 44, and the first phosphorescent dopant 256 can have a weight % of 12.

In the second blue emitting layer 260, a weight % of each of the second p-type host 262 and the second n-type host 264 can be greater than that of the second phosphorescent dopant 266, and a weight % of the second p-type host 262 and a weight % of the second n-type host 264 can be same or different. For example, a weight % of the second p-type host 262 and a weight % of the second n-type host 264 can be same.

In an aspect of the present disclosure, the second p-type host 262 can have a weight % of 25 to 50, the second n-type host 264 can have a weight % of 25 to 50, and the second phosphorescent dopant 266 can have a weight % of 4 to 25. In an aspect of the present disclosure, the second p-type host 262 can have a weight % of 44, the second n-type host 264 can have a weight % of 44, and the second phosphorescent dopant 266 can have a weight % of 12.

A weight % of the first p-type host 252 in the first blue emitting layer 250 and a weight % of the second p-type host 262 in the second blue emitting layer 260 can be same or different. A weight % of the first n-type host 254 in the first blue emitting layer 250 and a weight % of the second n-type host 264 in the second blue emitting layer 260 can be same or different. A weight % of the first phosphorescent dopant 256 in the first blue emitting layer 250 and a weight % of the second phosphorescent dopant 266 in the second blue emitting layer 260 can be same or different.

The light emitting layer 220 further include at least one of a hole transporting layer (HTL) 274 between the first electrode 210 and the EML 240 and an electron transporting layer (ETL) 282 between the second electrode 230 and the EML 240.

In addition, the light emitting layer 220 can further include at least one of a hole injection layer (HIL) 272 between the first electrode 210 and the HTL 274 and an electron injection layer (EIL) 284 between the second electrode 230 and the ETL 282.

Moreover, the light emitting layer 220 can further include at least one of an electron blocking layer (EBL) 276 between the HTL 274 and the EML 240 and a hole blocking layer (HBL) 286 between the EML 240 and the ETL 282.

For example, the OLED D1 can have a structure of the first electrode 210 as an anode, the HIL 272, the HTL 274, the EBL 276, the first blue emitting layer 250, the second blue emitting layer 260, the HBL 286, the ETL 282, the EIL 284 and the second electrode 230 as a cathode sequentially stacked. In this configuration, a first surface of the first blue emitting layer 250 contacts the second blue emitting layer 260, and a second surface of the first blue emitting layer 250 contacts the EBL 276. A first surface of the second blue emitting layer 260 contacts the first blue emitting layer 250, and a second surface of the second blue emitting layer 260 contacts the HBL 286.

For example, the HIL 272 can include a hole injection material selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine(CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′3′-h]quinoxaline-2,3,6,7,10,11-hexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), and N-(biphenyl-4-yl)-9,9-dimethyl-N-(4-(9-phenyl-9H-carbazol-3-yl)phenyl)-9H-fluoren-2-amine. Alternatively, the hole injection material of the HIL 272 can include a compound in Formula 9 as a host and a compound in Formula 10 as a dopant. In this case, the compound in Formula 10 can have a weight % of 1 to 10. For example, the HIL 272 can have a thickness of 1 to 30 nm.

The HTL 274 can include a hole transporting material selected from the group consisting of N,N′-diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), poly[N,N′-bis(4-butylpnehyl)-N,N′-bis(phenyl)-benzidine](poly-TPD), (poly[(9,9-dioctylfluorenyl-2,7-diyl)-co-(4,4′-(N-(4-sec-butylphenyl)diphenylamine))](TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl-4-amine. Alternatively, the hole transporting material of the HTL 274 can include the compound in Formula 9. The HTL 274 can have a thickness of 20 to 60 nm, preferably 30 to 40 nm.

The ETL 282 can include an electron transporting material selected from the group consisting of tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,08)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)](PFNBr), tris(phenylquinoxaline (TPQ), and diphenyl-4-triphenylsilyl-phenylphosphine oxide (TSPO1). Alternatively, the electron transporting material of the ETL 282 can include a compound in Formula 11. For example, the ETL 282 can have a thickness of 10 to 50 nm, preferably 20 to 40 nm.

The EIL 284 can include an electron injection material selected from an alkali halide compound, such as LiF, CsF, NaF, or BaF₂, and an organo-metallic compound, such as Liq, lithium benzoate, or sodium stearate. For example, the EIL 284 can have a thickness of 0.1 to 10 nm, preferably 0.5 to 2 nm.

The EBL 276 can include an electron blocking material selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene. Alternatively, the electron blocking material of the EBL 276 can be the same as the first p-type host 252 in the first blue emitting layer 250 or the second p-type host 262 in the second blue emitting layer 260. In an aspect of the present disclosure, the electron blocking material of the EBL 276 can be the same as the first p-type host 252 in the first blue emitting layer 250. For example, the EBL 276 can have a thickness of 5 to 40 nm, preferably 10 to 20 nm.

The HBL 286 can include a hole blocking material selected from the group consisting of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1. Alternatively, the hole blocking material of the HBL 286 can be the same as the first n-type host 254 in the first blue emitting layer 250 or the second n-type host 264 in the second blue emitting layer 260. In an aspect of the present disclosure, the hole blocking material of the HBL 286 can be the same as the second n-type host 264 in the second blue emitting layer 260. For example, the HBL 286 can have a thickness of 1 to 20 nm, preferably 1 to 10 nm.

The capping layer can include the above-mentioned hole transporting material and can have a thickness of 50 to 100 nm, preferably 70 to 80 nm.

In the OLED D1 of the present disclosure, the blue EML 240 includes the first blue emitting layer 250 and the second blue emitting layer 260. The first blue emitting layer 250 includes the first p-type host 252 represented by Formula 1, the first n-type host 254 represented by one of Formulas 3 and 5 and the first phosphorescent dopant 256 represented by Formula 7, and the second blue emitting layer 260 includes the second p-type host 262 represented by Formula 1, the second n-type host 264 represented by the other one of Formulas 3 and 5 and the second phosphorescent dopant 266 represented by Formula 7. As a result, the lifespan of the OLED D1 and the organic light emitting display device 100 are improved.

For example, when a blue EML having a single-layered structure includes a p-type host represented by Formula 1, an n-type host represented by one of Formulas 3 and 5 and a phosphorescent dopant represented by Formula 7, a recombination zone in the blue EML is shifted toward the first electrode or the second electrode so that the triplet-polaron quenching problem can be generated at an interface between the blue EML and adjacent layer (e.g., an EBL or an HBL). As a result, the lifespan of the OLED and the organic light emitting display device can be decreased.

However, in the OLED D1 of the present disclosure, since the blue EML 240 has a double-layered structure including a phosphorescent emitting layer with a delayed fluorescent property and a phosphorescent emitting layer with an exciplex property, a recombination zone is shifted toward a center of the blue EML 240 so that the triplet-polaron quenching problem can be prevented. As a result, the lifespan of the OLED D1 and the organic light emitting display 100 device can be improved.

In addition, when a phosphorescent emitting layer with an exciplex property is disposed to be closer to the cathode, the lifespan of the OLED D1 and the organic light emitting display 100 device can be further improved.

Moreover, a phosphorescent emitting layer with a delayed fluorescent property and a phosphorescent emitting layer with an exciplex property have the same thickness, the lifespan of the OLED D1 and the organic light emitting display 100 device can be further improved.

### EXAMPLES

The following examples are exemplary and not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### [OLED1]

An anode (ITO, 50 nm), an HIL (a compound in Formula 9 and a compound in Formula 10 (5 wt % doping), 10 nm), an HTL (the compound in Formula 9, 40 nm), an EBL (15 nm), a blue EML, an HBL (5 nm), an ETL (a compound in Formula 11, 30 nm), an EIL (LiF, 1 nm) and a cathode (Al, 100 nm) are sequentially deposited to form a bottom-emission type blue OLED.

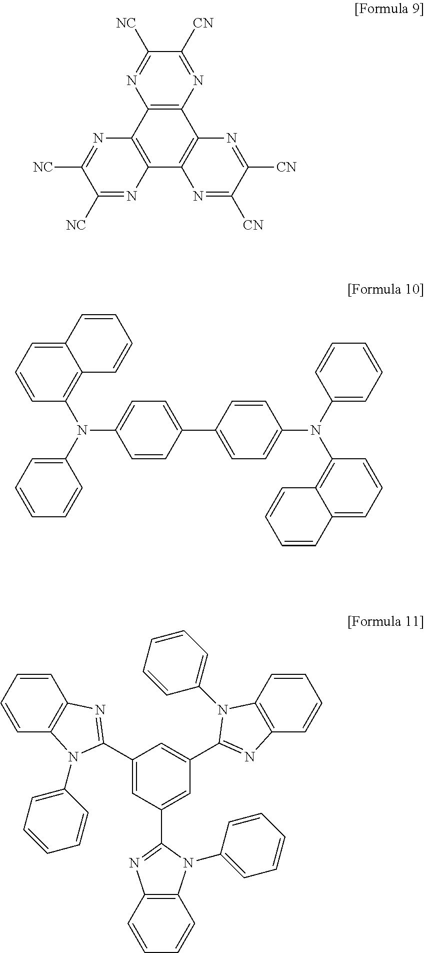 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc(-n2c(-c3cc(-c4nc5ccccc5n4-c4ccccc4)cc(-c4nc5ccccc5n4-c4ccccc4)c3)nc3ccccc32)cc1]

### 1. Comparative Examples

### (1) Comparative Example 1 (Ref1)

The compound PH-1 in Formula 2 (44 wt %), the compound NH1-1 in Formula 4 (44 wt %) and the compound PD-1 in Formula 8 (12 wt %) were used to form the blue EML (30 nm). The compound PH-1 in Formula 2 was used to form the EBL, and the compound NH1-1 in Formula 4 was used to form the HBL.

### (2) Comparative Example 2 (Ref2)

The compound PH-1 in Formula 2 (44 wt %), the compound NH2-1 in Formula 6 (44 wt %) and the compound PD-1 in Formula 8 (12 wt %) were used to form the blue EML (30 nm). The compound PH-1 in Formula 2 was used to form the EBL, and the compound NH2-1 in Formula 6 was used to form the HBL.

### (3) Comparative Example 3 (Ref3)

The compound PH-1 in Formula 2 (44 wt %), the compound NH1-1 in Formula 4 (44 wt %) and the compound PD-1 in Formula 8 (12 wt %) were used to form a first blue emitting layer (10 nm) on the EBL, and the compound PH-1 in Formula 2 (44 wt %), the compound NH2-1 in Formula 6 (44 wt %) and the compound PD-1 in Formula 8 (12 wt %) were used to form a second blue emitting layer (20 nm) on the first blue emitting layer. The compound PH-1 in Formula 2 was used to form the EBL, and the compound NH2-1 in Formula 6 was used to form the HBL.

### (4) Comparative Example 4 (Ref4)

The compound PH-1 in Formula 2 (44 wt %), the compound NH1-1 in Formula 4 (44 wt %) and the compound PD-1 in Formula 8 (12 wt %) were used to form a first blue emitting layer (15 nm) on the EBL, and the compound PH-1 in Formula 2 (44 wt %), the compound NH2-1 in Formula 6 (44 wt %) and the compound PD-1 in Formula 8 (12 wt %) were used to form a second blue emitting layer (15 nm) on the first blue emitting layer. The compound PH-1 in Formula 2 was used to form the EBL, and the compound NH2-1 in Formula 6 was used to form the HBL.

### (5) Comparative Example 5 (Ref5)

The compound PH-1 in Formula 2 (44 wt %), the compound NH1-1 in Formula 4 (44 wt %) and the compound PD-1 in Formula 8 (12 wt %) were used to form a first blue emitting layer (20 nm) on the EBL, and the compound PH-1 in Formula 2 (44 wt %), the compound NH2-1 in Formula 6 (44 wt %) and the compound PD-1 in Formula 8 (12 wt %) were used to form a second blue emitting layer (10 nm) on the first blue emitting layer. The compound PH-1 in Formula 2 was used to form the EBL, and the compound NH2-1 in Formula 6 was used to form the HBL.

### 2. Examples

### (1) Example 1 (Ex1)

The compound PH-1 in Formula 2 (44 wt %), the compound NH2-1 in Formula 6 (44 wt %) and the compound PD-1 in Formula 8 (12 wt %) were used to form a first blue emitting layer (7.5 nm) on the EBL, and the compound PH-1 in Formula 2 (44 wt %), the compound NH1-1 in Formula 4 (44 wt %) and the compound PD-1 in Formula 8 (12 wt %) were used to form a second blue emitting layer (22.5 nm) on the first blue emitting layer. The compound PH-1 in Formula 2 was used to form the EBL, and the compound NH1-1 in Formula 6 was used to form the HBL.

### (2) Example 2 (Ex2)

The compound PH-1 in Formula 2 (44 wt %), the compound NH2-1 in Formula 6 (44 wt %) and the compound PD-1 in Formula 8 (12 wt %) were used to form a first blue emitting layer (10 nm) on the EBL, and the compound PH-1 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-1 in Formula 2 was used to form the EBL, and the compound NH1-1 in Formula 6 was used to form the HBL.

### (3) Example 3 (Ex3)

The compound PH-1 in Formula 2 (44 wt %), the compound NH2-1 in Formula 6 (44 wt %) and the compound PD-1 in Formula 8 (12 wt %) were used to form a first blue emitting layer (15 nm) on the EBL, and the compound PH-1 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-1 in Formula 2 was used to form the EBL, and the compound NH1-1 in Formula 6 was used to form the HBL.

### (4) Example 4 (Ex4)

The compound PH-1 in Formula 2 (44 wt %), the compound NH2-1 in Formula 6 (44 wt %) and the compound PD-1 in Formula 8 (12 wt %) were used to form a first blue emitting layer (20 nm) on the EBL, and the compound PH-1 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-1 in Formula 2 was used to form the EBL, and the compound NH1-1 in Formula 6 was used to form the HBL.

### (5) Example 5 (Ex5)

The compound PH-1 in Formula 2 (44 wt %), the compound NH2-1 in Formula 6 (44 wt %) and the compound PD-1 in Formula 8 (12 wt %) were used to form a first blue emitting layer (22.5 nm) on the EBL, and the compound PH-1 in Formula 2 (44 wt %), the compound NH1-1 in Formula 4 (44 wt %) and the compound PD-1 in Formula 8 (12 wt %) were used to form a second blue emitting layer (7.5 nm) on the first blue emitting layer. The compound PH-1 in Formula 2 was used to form the EBL, and the compound NH1-1 in Formula 6 was used to form the HBL.

A part of the structure of the OLED in Comparative Examples 1 to 5 and Examples 1 to 5 is listed in Table 1, and the emitting properties, i.e., a driving voltage (V, %), an external quantum efficiency (EQE, %), a color coordinate index (CIEx, CIEy), a maximum emission wavelength (A_{MAX}, nm) and the lifespan (LT95), of the OLED in Comparative Examples 1 to 5 and Examples 1 to 5 was measured and listed in Table 2. The property of the OLED was measured under a condition of 8.6 mA/Wm. The driving voltage and the lifespan are a relative value to Comparative Example 1.

TABLE 1

| | EBL | EML | | HBL |
|---|---|---|---|---|
| Ref1 | PH-1 | PH-1:NH1-1:PD-1 [44:44:12] (30 nm) | | NH1-1 |
| Ref2 | PH-1 | PH-1:NH2-1:PD-1 [44:44:12] (30 nm) | | |
| Ref3 | PH-1 | PH-1:NH1-1:PD-1 | PH-1:NH2-1:PD-1 | NH2-1 |
| | | [44:44:12] (10 nm) | [44:44:12] (20 nm) | |
| Ref4 | PH-1 | PH-1:NH1-1:PD-1 | PH-1:NH2-1:PD-1 | NH2-1 |
| | | [44:44:12] (15 nm) | [44:44:12] (15 nm) | |
| Ref5 | PH-1 | PH-1:NH1-1:PD-1 | PH-1:NH2-1:PD-1 | NH2-1 |
| | | [44:44:12] (20 nm) | [44:44:12] (10 nm) | |
| Ex1 | PH-1 | PH-1:NH2-1:PD-1 | PH-1:NH1-1:PD-1 | NH1-1 |
| | | [44:44:12] (7.5 nm) | [44:44:12] (22.5 nm) | |
| Ex2 | PH-1 | PH-1:NH2-1:PD-1 | PH-1:NH1-1:PD-1 | NH1-1 |
| | | [44:44:12] (10 nm) | [44:44:12] (20 nm) | |
| Ex3 | PH-1 | PH-1:NH2-1:PD-1 | PH-1:NH1-1:PD-1 | NH1-1 |
| | | [44:44:12] (15 nm) | [44:44:12] (15 nm) | |
| Ex4 | PH-1 | PH-1:NH2-1:PD-1 | PH-1:NH1-1:PD-1 | NH1-1 |
| | | [44:44:12] (20 nm) | [44:44:12] (10 nm) | |
| Ex5 | PH-1 | PH-1:NH2-1:PD-1 | PH-1:NH1-1:PD-1 | NH1-1 |
| | | [44:44:12] (22.5 nm) | [44:44:12] (7.5 nm) | |

TABLE 2

| | V | EQE [%] | CIEy | λ_{MAX} | LT95 |
|---|---|---|---|---|---|
| Ref1 | 100% | 20.3 | 0.151 | 462 | 100% |
| Ref2 | 95% | 19.4 | 0.159 | 462 | 128% |
| Ref3 | 99% | 19.6 | 0.154 | 462 | 61% |
| Ref4 | 98% | 19.7 | 0.154 | 462 | 93% |
| Ref5 | 99% | 19.9 | 0.156 | 462 | 76% |
| Ex1 | 99% | 19.8 | 0.154 | 462 | 127% |
| Ex2 | 100% | 20.0 | 0.153 | 462 | 143% |
| Ex3 | 98% | 20.1 | 0.153 | 462 | 171% |
| Ex4 | 97% | 19.7 | 0.155 | 462 | 151% |
| Ex5 | 97% | 19.7 | 0.154 | 462 | 125% |

As shown in Table 2, in comparison to the OLED of Comparative Examples 1 to 5, the OLED of Examples 1 to 5 provide improved lifespan.

The blue EML in the OLED of Comparative Examples 1 and 2 has a single-layered structure. On the other hand, the blue EML in the OLED of Examples 1 to 5 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 1 and 2, the lifespan of the OLED of Examples 1 to 5 is significantly improved.

In comparison to the OLED of Comparative Examples 3 to 5, where the blue EML has a double-layered structure including a first blue emitting layer, which is adjacent to an anode and includes a first n-type host represented by Formula 3 and a first phosphorescent dopant represented by Formula 7, and a second blue mitting layer, which is adjacent to a cathode and includes a second p-type host represented by Formula 1, a second n-type host represented by Formula 5 and a second phosphorescent dopant represented by Formula 7, the lifespan of the OLED of Examples 1 to 5 is significantly improved. Namely, when the blue EML has a double-layered structure including a blue emitting layer with a delayed fluorescent property and a blue emitting layer with an exciplex property and the blue emitting layer with the exciplex property is disposed to be closer to the cathode, the lifespan of the OLED is increased.

In addition, in comparison to the OLED of Examples 1, 2, 4 and 5, where a blue emitting layer with a delayed fluorescent property and a blue emitting layer with an exciplex property have different thickness, the lifespan of the OLED of Example 3, where a blue emitting layer with a delayed fluorescent property and a blue emitting layer with an exciplex property have the same thickness, is further increased.

### 3. Comparative Examples

### (1) Comparative Example 6 (Ref6)

The compound PH-2 in Formula 2 (44 wt %), the compound NH1-1 in Formula 4 (44 wt %) and the compound PD-1 in Formula 8 (12 wt %) were used to form the blue EML (30 nm). The compound PH-2 in Formula 2 was used to form the EBL, and the compound NH1-1 in Formula 4 was used to form the HBL.

### (2) Comparative Example 7 (Ref7)

The compound PH-2 in Formula 2 (44 wt %), the compound NH2-1 in Formula 6 (44 wt %) and the compound PD-1 in Formula 8 (12 wt %) were used to form the blue EML (30 nm). The compound PH-2 in Formula 2 was used to form the EBL, and the compound NH2-1 in Formula 6 was used to form the HBL.

### (3) Comparative Example 8 (Ref8)

The compound PH-2 in Formula 2 (44 wt %), the compound NH1-1 in Formula 4 (44 wt %) and the compound PD-1 in Formula 8 (12 wt %) were used to form a first blue emitting layer (10 nm) on the EBL, and the compound PH-2 in Formula 2 (44 wt %), the compound NH2-1 in Formula 6 (44 wt %) and the compound PD-1 in Formula 8 (12 wt %) were used to form a second blue emitting layer (20 nm) on the first blue emitting layer. The compound PH-2 in Formula 2 was used to form the EBL, and the compound NH2-1 in Formula 6 was used to form the HBL.

### (4) Comparative Example 9 (Ref9)

The compound PH-2 in Formula 2 (44 wt %), the compound NH1-1 in Formula 4 (44 wt %) and the compound PD-1 in Formula 8 (12 wt %) were used to form a first blue emitting layer (15 nm) on the EBL, and the compound PH-2 in Formula 2 (44 wt %), the compound NH2-1 in Formula 6 (44 wt %) and the compound PD-1 in Formula 8 (12 wt %) were used to form a second blue emitting layer (15 nm) on the first blue emitting layer. The compound PH-2 in Formula 2 was used to form the EBL, and the compound NH2-1 in Formula 6 was used to form the HBL.

### (5) Comparative Example 10 (Ref10)

The compound PH-2 in Formula 2 (44 wt %), the compound NH1-1 in Formula 4 (44 wt %) and the compound PD-1 in Formula 8 (12 wt %) were used to form a first blue emitting layer (20 nm) on the EBL, and the compound PH-2 in Formula 2 (44 wt %), the compound NH2-1 in Formula 6 (44 wt %) and the compound PD-1 in Formula 8 (12 wt %) were used to form a second blue emitting layer (10 nm) on the first blue emitting layer. The compound PH-2 in Formula 2 was used to form the EBL, and the compound NH2-1 in Formula 6 was used to form the HBL.

### 4. Examples

### (1) Example 6 (Ex6)

The compound PH-2 in Formula 2 (44 wt %), the compound NH2-1 in Formula 6 (44 wt %) and the compound PD-1 in Formula 8 (12 wt %) were used to form a first blue emitting layer (10 nm) on the EBL, and the compound PH-2 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-2 in Formula 2 was used to form the EBL, and the compound NH1-1 in Formula 6 was used to form the HBL.

### (2) Example 7 (Ex7)

The compound PH-2 in Formula 2 (44 wt %), the compound NH2-1 in Formula 6 (44 wt %) and the compound PD-1 in Formula 8 (12 wt %) were used to form a first blue emitting layer (15 nm) on the EBL, and the compound PH-2 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-2 in Formula 2 was used to form the EBL, and the compound NH1-1 in Formula 6 was used to form the HBL.

### (3) Example 8 (Ex8)

The compound PH-2 in Formula 2 (44 wt %), the compound NH2-1 in Formula 6 (44 wt %) and the compound PD-1 in Formula 8 (12 wt %) were used to form a first blue emitting layer (20 nm) on the EBL, and the compound PH-2 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-2 in Formula 2 was used to form the EBL, and the compound NH1-1 in Formula 6 was used to form the HBL.

A part of the structure of the OLED in Comparative Examples 6 to 10 and Examples 6 to 8 is listed in Table 3, and the emitting properties, i.e., a driving voltage (V, %), an external quantum efficiency (EQE, %), a color coordinate index (CIEx, CIEy), a maximum emission wavelength (Δ_{MAX}, nm) and the lifespan (LT95(1) and LT95), of the OLED in Comparative Examples 6 to 10 and Examples 6 to 8 was measured and listed in Table 4. The property of the OLED was measured under a condition of 8.6 mA/cm². The driving voltage and the lifespan (LT95(1)) are a relative value to Comparative Example 1, and the lifespan (LT95) is a relative value to Comparative Example 6.

TABLE 3

| | EBL | EML | | HBL |
|---|---|---|---|---|
| Ref6 | PH-2 | PH-2:NH1-1:PD-1 [44:44:12] (30 nm) | | NH1-1 |
| Ref7 | PH-2 | PH-2:NH2-1:PD-1 [44:44:12] (30 nm) | | NH2-1 |
| Ref8 | PH-2 | PH-2:NH1-1:PD-1 | PH-2:NH2-1:PD-1 | NH2-1 |
| | | [44:44:12] (10 nm) | [44:44:12] (20 nm) | |
| Ref9 | PH-2 | PH-2:NH1-1:PD-1 | PH-2:NH2-1:PD-1 | NH2-1 |
| | | [44:44:12] (15 nm) | [44:44:12] (15 nm) | |
| Ref10 | PH-2 | PH-2:NH1-1:PD-1 | PH-2:NH2-1:PD-1 | NH2-1 |
| | | [44:44:12] (20 nm) | [44:44:12] (10 nm) | |
| Ex6 | PH-2 | PH-2:NH2-1:PD-1 | PH-2:NH1-1:PD-1 | NH1-1 |
| | | [44:44: 12] (10 nm) | [44:44:12] (20 nm) | |
| Ex7 | PH-2 | PH-2:NH2-1:PD-1 | PH-2:NH1-1:PD-1 | NH1-1 |
| | | [44:44:12] (15 nm) | [44:44:12] (15 nm) | |
| Ex8 | PH-2 | PH-2:NH2-1:PD-1 | PH-2:NH1-1:PD-1 | NH1-1 |
| | | [44:44:12] (20 nm) | [44:44:12] (10 nm) | |

TABLE 4

| | V | EQE [%] | CIEy | λmax | LT95(1) | LT95 |
|---|---|---|---|---|---|---|
| Ref6 | 104% | 17.9 | 0.153 | 462 | 85% | 100% |
| Ref7 | 99% | 16.2 | 0.161 | 462 | 93% | 109% |
| Ref8 | 100% | 17.4 | 0.158 | 462 | 54% | 64% |
| Ref9 | 101% | 17.5 | 0.156 | 462 | 65% | 76% |
| Ref10 | 103% | 17.8 | 0.156 | 462 | 49% | 58% |
| Ex6 | 103% | 17.8 | 0.158 | 462 | 98% | 115% |
| Ex7 | 103% | 17.7 | 0.159 | 462 | 121% | 142% |
| Ex8 | 102% | 16.8 | 0.159 | 462 | 105% | 124% |

As shown in Table 4, in comparison to the OLED of Comparative Examples 6 to 10, the OLED of Examples 6 to 8 provides improved lifespan.

The blue EML in the OLED of Comparative Examples 6 and 7 has a single-layered structure. On the other hand, the blue EML in the OLED of Examples 6 to 8 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 6 and 7, the lifespan of the OLED of Examples 6 to 8 is significantly improved.

In comparison to the OLED of Comparative Examples 8 to 10, where the blue EML has a double-layered structure including a first blue emitting layer, which is adjacent to an anode and includes a first n-type host represented by Formula 3 and a first phosphorescent dopant represented by Formula 7, and a second blue mitting layer, which is adjacent to a cathode and includes a second p-type host represented by Formula 1, a second n-type host represented by Formula 5 and a second phosphorescent dopant represented by Formula 7, the lifespan of the OLED of Examples 6 to 8 is significantly improved. Namely, when the blue EML has a double-layered structure including a blue emitting layer with a delayed fluorescent property and a blue emitting layer with an exciplex property and the blue emitting layer with the exciplex property is disposed to be closer to the cathode, the lifespan of the OLED is increased.

In addition, in comparison to the OLED of Examples 6 and 8, where a blue emitting layer with a delayed fluorescent property and a blue emitting layer with an exciplex property have different thickness, the lifespan of the OLED of Example 7, where a blue emitting layer with a delayed fluorescent property and a blue emitting layer with an exciplex property have the same thickness, is further increased.

### 5. Comparative Examples

### (1) Comparative Example 11 (Ref11)

The compound PH-3 in Formula 2 (44 wt %), the compound NH1-1 in Formula 4 (44 wt %) and the compound PD-1 in Formula 8 (12 wt %) were used to form the blue EML (30 nm). The compound PH-3 in Formula 2 was used to form the EBL, and the compound NH1-1 in Formula 4 was used to form the HBL.

### (2) Comparative Example 12 (Ref12)

The compound PH-3 in Formula 2 (44 wt %), the compound NH2-1 in Formula 6 (44 wt %) and the compound PD-1 in Formula 8 (12 wt %) were used to form the blue EML (30 nm). The compound PH-3 in Formula 2 was used to form the EBL, and the compound NH2-1 in Formula 6 was used to form the HBL.

### (3) Comparative Example 13 (Ref13)

The compound PH-3 in Formula 2 (44 wt %), the compound NH1-1 in Formula 4 (44 wt %) and the compound PD-1 in Formula 8 (12 wt %) were used to form a first blue emitting layer (10 nm) on the EBL, and the compound PH-3 in Formula 2 (44 wt %), the compound NH2-1 in Formula 6 (44 wt %) and the compound PD-1 in Formula 8 (12 wt %) were used to form a second blue emitting layer (20 nm) on the first blue emitting layer. The compound PH-3 in Formula 2 was used to form the EBL, and the compound NH2-1 in Formula 6 was used to form the HBL.

### (4) Comparative Example 14 (Ref14)

The compound PH-3 in Formula 2 (44 wt %), the compound NH1-1 in Formula 4 (44 wt %) and the compound PD-1 in Formula 8 (12 wt %) were used to form a first blue emitting layer (15 nm) on the EBL, and the compound PH-3 in Formula 2 (44 wt %), the compound NH2-1 in Formula 6 (44 wt %) and the compound PD-1 in Formula 8 (12 wt %) were used to form a second blue emitting layer (15 nm) on the first blue emitting layer. The compound PH-3 in Formula 2 was used to form the EBL, and the compound NH2-1 in Formula 6 was used to form the HBL.

### (5) Comparative Example 15 (Ref15)

The compound PH-3 in Formula 2 (44 wt %), the compound NH1-1 in Formula 4 (44 wt %) and the compound PD-1 in Formula 8 (12 wt %) were used to form a first blue emitting layer (20 nm) on the EBL, and the compound PH-3 in Formula 2 (44 wt %), the compound NH2-1 in Formula 6 (44 wt %) and the compound PD-1 in Formula 8 (12 wt %) were used to form a second blue emitting layer (10 nm) on the first blue emitting layer. The compound PH-3 in Formula 2 was used to form the EBL, and the compound NH2-1 in Formula 6 was used to form the HBL.

### 6. Examples

### (1) Example 9 (Ex9)

The compound PH-3 in Formula 2 (44 wt %), the compound NH2-1 in Formula 6 (44 wt %) and the compound PD-1 in Formula 8 (12 wt %) were used to form a first blue emitting layer (10 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-3 in Formula 2 was used to form the EBL, and the compound NH1-1 in Formula 6 was used to form the HBL.

### (2) Example 10 (Ex10)

The compound PH-3 in Formula 2 (44 wt %), the compound NH2-1 in Formula 6 (44 wt %) and the compound PD-1 in Formula 8 (12 wt %) were used to form a first blue emitting layer (15 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-3 in Formula 2 was used to form the EBL, and the compound NH1-1 in Formula 6 was used to form the HBL.

### (3) Example 11 (Ex11)

The compound PH-3 in Formula 2 (44 wt %), the compound NH2-1 in Formula 6 (44 wt %) and the compound PD-1 in Formula 8 (12 wt %) were used to form a first blue emitting layer (20 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-3 in Formula 2 was used to form the EBL, and the compound NH1-1 in Formula 6 was used to form the HBL.

A part of the structure of the OLED in Comparative Examples 11 to 15 and Examples 9 to 11 is listed in Table 5, and the emitting properties, i.e., a driving voltage (V, %), an external quantum efficiency (EQE, %), a color coordinate index (CIEx, CIEy), a maximum emission wavelength (Δ_{MAX}, nm) and the lifespan (LT95(1) and LT95), of the OLED in Comparative Examples 11 to 15 and Examples 9 to 11 was measured and listed in Table 6. The property of the OLED was measured under a condition of 8.6 mA/m. The driving voltage and the lifespan (LT95(1)) are a relative value to Comparative Example 1, and the lifespan (LT95) is a relative value to Comparative Example 11.

TABLE 5

| | EBL | EML | | HBL |
|---|---|---|---|---|
| Ref11 | PH-3 | PH-3:NH1-1:PD-1 [44:44:12] (30 nm) | | NH1-1 |
| Ref12 | PH-3 | PH-3:NH2-1:PD-1 [44:44:12] (30 nm) | | NH2-1 |
| Ref13 | PH-3 | PH-3:NH1-1:PD-1 | PH-3:NH2-1:PD-1 | NH2-1 |
| | | [44:44:12] (10 nm) | [44:44:12] (20 nm) | |
| Ref14 | PH-3 | PH-3:NH1-1:PD-1 | PH-3:NH2-1:PD-1 | NH2-1 |
| | | [44:44:12] (15 nm) | [44:44:12] (15 nm) | |
| Ref15 | PH-3 | PH-3:NH1-1:PD-1 | PH-3:NH2-1:PD-1 | NH2-1 |
| | | [44:44:12] (20 nm) | [44:44:12] (10 nm) | |
| Ex9 | PH-3 | PH-3:NH2-1:PD-1 | PH-3:NH1-1:PD-1 | NH1-1 |
| | | [44:44:12] (10 nm) | [44:44:12] (20 nm) | |
| Ex10 | PH-3 | PH-3:NH2-1:PD-1 | PH-3:NH1-1:PD-1 | NH1-1 |
| | | [44:44:12] (15 nm) | [44:44:12] (15 nm) | |
| Ex11 | PH-3 | PH-3:NH2-1:PD-1 | PH-3:NH1-1:PD-1 | NH1-1 |
| | | [44:44:12] (20 nm) | [44:44:12] (10 nm) | |

TABLE 6

| | V | EQE [%] | CIEy | λmax | LT95(1) | LT95 |
|---|---|---|---|---|---|---|
| Ref11 | 103% | 20.7 | 0.151 | 462 | 106% | 100% |
| Ref12 | 95% | 18.9 | 0.158 | 462 | 121% | 114% |
| Ref13 | 100% | 19.5 | 0.155 | 462 | 61% | 58% |
| Ref14 | 100% | 19.7 | 0.154 | 462 | 68% | 64% |
| Ref15 | 101% | 19.8 | 0.154 | 462 | 63% | 59% |
| Ex9 | 102% | 20.1 | 0.154 | 462 | 138% | 130% |
| Ex10 | 100% | 19.8 | 0.154 | 462 | 169% | 159% |
| Ex11 | 99% | 19.3 | 0.155 | 462 | 142% | 134% |

As shown in Table 6, in comparison to the OLED of Comparative Examples 11 to 15, the OLED of Examples 9 to 11 provides improved lifespan.

The blue EML in the OLED of Comparative Examples 11 and 12 has a single-layered structure. On the other hand, the blue EML in the OLED of Examples 9 to 11 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 11 and 12, the lifespan of the OLED of Examples 9 to 11 is significantly improved.

In comparison to the OLED of Comparative Examples 13 to 15, where the blue EML has a double-layered structure including a first blue emitting layer, which is adjacent to an anode and includes a first n-type host represented by Formula 3 and a first phosphorescent dopant represented by Formula 7, and a second blue mitting layer, which is adjacent to a cathode and includes a second p-type host represented by Formula 1, a second n-type host represented by Formula 5 and a second phosphorescent dopant represented by Formula 7, the lifespan of the OLED of Examples 9 to 11 is significantly improved. Namely, when the blue EML has a double-layered structure including a blue emitting layer with a delayed fluorescent property and a blue emitting layer with an exciplex property and the blue emitting layer with the exciplex property is disposed to be closer to the cathode, the lifespan of the OLED is increased.

In addition, in comparison to the OLED of Examples 9 and 11, where a blue emitting layer with a delayed fluorescent property and a blue emitting layer with an exciplex property have different thickness, the lifespan of the OLED of Example 10, where a blue emitting layer with a delayed fluorescent property and a blue emitting layer with an exciplex property have the same thickness, is further increased.

### 7. Comparative Examples

### (1) Comparative Example 16 (Ref16)

The compound PH-3 in Formula 2 (44 wt %), the compound NH-A in Formula 12 (44 wt %) and the compound PD-1 in Formula 8 (12 wt %) were used to form the blue EML (30 nm). The compound PH-3 in Formula 2 was used to form the EBL, and the compound NH-A in Formula 12 was used to form the HBL.

### (2) Comparative Example 17 (Ref17)

The compound PH-3 in Formula 2 (44 wt %), the compound NH-A in Formula 12 (44 wt %) and the compound PD-1 in Formula 8 (12 wt %) were used to form a first blue emitting layer (10 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-3 in Formula 2 was used to form the EBL, and the compound NH1-1 in Formula 4 was used to form the HBL.

### (3) Comparative Example 18 (Ref18)

The compound PH-3 in Formula 2 (44 wt %), the compound NH-A in Formula 12 (44 wt %) and the compound PD-1 in Formula 8 (12 wt %) were used to form a first blue emitting layer (15 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-3 in Formula 2 was used to form the EBL, and the compound NH1-1 in Formula 4 was used to form the HBL.

### (4) Comparative Example 19 (Ref19)

The compound PH-3 in Formula 2 (44 wt %), the compound NH-A in Formula 12 (44 wt %) and the compound PD-1 in Formula 8 (12 wt %) were used to form a first blue emitting layer (20 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-3 in Formula 2 was used to form the EBL, and the compound NH1-1 in Formula 4 was used to form the HBL.

### (5) Comparative Example 20 (Ref20)

The compound PH-3 in Formula 2 (44 wt %), the compound NH1-1 in Formula 4 (44 wt %) and the compound PD-1 in Formula 8 (12 wt %) were used to form a first blue emitting layer (10 nm) on the EBL, and the compound PH-3 in Formula 2 (44 wt %), the compound NH-A in Formula 12 (44 wt %) and the compound PD-1 in Formula 8 (12 wt %) were used to form a second blue emitting layer (20 nm) on the first blue emitting layer. The compound PH-3 in Formula 2 was used to form the EBL, and the compound NH-A in Formula 12 was used to form the HBL.

### (6) Comparative Example 21 (Ref21)

The compound PH-3 in Formula 2 (44 wt %), the compound NH1-1 in Formula 4 (44 wt %) and the compound PD-1 in Formula 8 (12 wt %) were used to form a first blue emitting layer (15 nm) on the EBL, and the compound PH-3 in Formula 2 (44 wt %), the compound NH-A in Formula 12 (44 wt %) and the compound PD-1 in Formula 8 (12 wt %) were used to form a second blue emitting layer (15 nm) on the first blue emitting layer. The compound PH-3 in Formula 2 was used to form the EBL, and the compound NH-A in Formula 12 was used to form the HBL.

### (7) Comparative Example 22 (Ref22)

The compound PH-3 in Formula 2 (44 wt %), the compound NH1-1 in Formula 4 (44 wt %) and the compound PD-1 in Formula 8 (12 wt %) were used to form a first blue emitting layer (20 nm) on the EBL, and the compound PH-3 in Formula 2 (44 wt %), the compound NH-A in Formula 12 (44 wt %) and the compound PD-1 in Formula 8 (12 wt %) were used to form a second blue emitting layer (10 nm) on the first blue emitting layer. The compound PH-3 in Formula 2 was used to form the EBL, and the compound NH-A in Formula 12 was used to form the HBL.

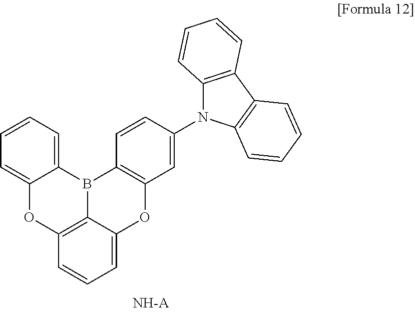 [SMILES: c1ccc2c(c1)Oc1cccc3c1B2c1ccc(-n2c4ccccc4c4ccccc42)cc1O3]

A part of the structure of the OLED in Comparative Examples 11 and 16 to 22 and Examples 9 to 11 is listed in Table 7, and the emitting properties, i.e., a driving voltage (V, %), an external quantum efficiency (EQE, %), a color coordinate index (CIEx, CIEy), a maximum emission wavelength (Δ_{MAX}, nm) and the lifespan (LT95(1) and LT95), of the OLED in Comparative Examples 11 and 16 to 22 and Examples 9 to 11 was measured and listed in Table 8. The property of the OLED was measured under a condition of 8.6 mA/cm². The driving voltage and the lifespan (LT95(1)) are a relative value to Comparative Example 1, and the lifespan (LT95) is a relative value to Comparative Example 11.

TABLE 7

| | EBL | EML | | HBL |
|---|---|---|---|---|
| Ref11 | PH-3 | PH-3:NH1-1:PD-1 [44:44:12] (30 nm) | | NH1-1 |
| Ref16 | PH-3 | PH-3:NH-A:PD-1 [44:44:12] (30 nm) | | NH-A |
| Ref17 | PH-3 | PH-3:NH-A:PD-1 | PH-3:NH1-1:PD-1 | NH1-1 |
| | | [44:44:12] (10 nm) | [44:44:12] (20 nm) | |
| Ref18 | PH-3 | PH-3:NH-A:PD-1 | PH-3:NH1-1:PD-1 | NH1-1 |
| | | [44:44:12] (15 nm) | [44:44:12] (15 nm) | |
| Ref19 | PH-3 | PH-3:NH-A:PD-1 | PH-3:NH1-1:PD-1 | NH1-1 |
| | | [44:44:12] (20 nm) | [44:44:12] (10 nm) | |
| Ref20 | PH-3 | PH-3:NH1-1:PD-1 | PH-3:NH-A:PD-1 | NH-A |
| | | [44:44:12] (10 nm) | [44:44:12] (20 nm) | |
| Ref21 | PH-3 | PH-3:NH1-1:PD-1 | PH-3:NH-A:PD-1 | NH-A |
| | | [44:44:12] (15 nm) | [44:44:12] (15 nm) | |
| Ref22 | PH-3 | PH-3:NH1-1:PD-1 | PH-3:NH-A:PD-1 | NH-A |
| | | [44:44:12] (20 nm) | [44:44:12] (10 nm) | |
| Ex9 | PH-3 | PH-3:NH2-1:PD-1 | PH-3:NH1-1:PD-1 | NH1-1 |
| | | [44:44:12] (10 nm) | [44:44:12] (20 nm) | |
| Ex10 | PH-3 | PH-3:NH2-1:PD-1 | PH-3:NH1-1:PD-1 | NH1-1 |
| | | [44:44:12] (15 nm) | [44:44:12] (15 nm) | |
| Ex11 | PH-3 | PH-3:NH2-1:PD-1 | PH-3:NH1-1:PD-1 | NH1-1 |
| | | [44:44:12] (20 nm) | [44:44:12] (10 nm) | |

TABLE 8

| | V | EQE [%] | CIEy | λmax | LT95(1) | LT95 |
|---|---|---|---|---|---|---|
| Ref11 | 103% | 20.7 | 0.151 | 462 | 106% | 100% |
| Ref16 | 91% | 16.8 | 0.161 | 462 | 59% | 56% |
| Ref17 | 93% | 17.8 | 0.157 | 462 | 79% | 75% |
| Ref18 | 94% | 17.5 | 0.157 | 462 | 88% | 83% |
| Ref19 | 94% | 17.3 | 0.158 | 462 | 68% | 64% |
| Ref20 | 95% | 16.8 | 0.158 | 462 | 49% | 46% |
| Ref21 | 95% | 16.9 | 0.158 | 462 | 66% | 62% |
| Ref22 | 94% | 17.1 | 0.157 | 462 | 53% | 50% |
| Ex9 | 102% | 20.1 | 0.154 | 462 | 138% | 130% |
| Ex10 | 100% | 19.8 | 0.154 | 462 | 169% | 159% |
| Ex11 | 99% | 19.3 | 0.155 | 462 | 142% | 134% |

As shown in Table 2, in comparison to the OLED of Comparative Example 11 and Examples 9 to 11, the lifespan of the OLED of Comparative Examples 16 to 22 is significantly decreased.

Namely, the compound NH-A in Formula 12 has similar structure as the compound NH2-1 in Formula 6 but does not include a triphenylsilyl moiety. The lifespan of the OLED of Comparative Examples 16 to 22 is significantly decreased by the above structural difference.

Although the OLED of Examples 9 to 11 and the OLED of Comparative Examples 17 to 19 have the same structure of the blue emitting layers, the lifespan increase of the OLED in Comparative Examples 17 to 19 is not provide by the structural difference of the n-type host.

### 8. Comparative Examples

### (1) Comparative Example 23 (Ref23)

The compound PH-4 in Formula 2 (44 wt %), the compound NH1-1 in Formula 4 (44 wt %) and the compound PD-1 in Formula 8 (12 wt %) were used to form the blue EML (30 nm). The compound PH-4 in Formula 2 was used to form the EBL, and the compound NH1-1 in Formula 4 was used to form the HBL.

### (2) Comparative Example 24 (Ref24)

The compound PH-4 in Formula 2 (44 wt %), the compound NH2-1 in Formula 6 (44 wt %) and the compound PD-1 in Formula 8 (12 wt %) were used to form the blue EML (30 nm). The compound PH-4 in Formula 2 was used to form the EBL, and the compound NH2-1 in Formula 6 was used to form the HBL.

### 9. Examples

### (1) Example 12 (Ex12)

The compound PH-4 in Formula 2 (44 wt %), the compound NH2-1 in Formula 6 (44 wt %) and the compound PD-1 in Formula 8 (12 wt %) were used to form a first blue emitting layer (10 nm) on the EBL, and the compound PH-4 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-4 in Formula 2 was used to form the EBL, and the compound NH1-1 in Formula 4 was used to form the HBL.

### (2) Example 13 (Ex13)

The compound PH-4 in Formula 2 (44 wt %), the compound NH2-1 in Formula 6 (44 wt %) and the compound PD-1 in Formula 8 (12 wt %) were used to form a first blue emitting layer (15 nm) on the EBL, and the compound PH-4 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-4 in Formula 2 was used to form the EBL, and the compound NH1-1 in Formula 4 was used to form the HBL.

### (3) Example 14 (Ex14)

The compound PH-4 in Formula 2 (44 wt %), the compound NH2-1 in Formula 6 (44 wt %) and the compound PD-1 in Formula 8 (12 wt %) were used to form a first blue emitting layer (20 nm) on the EBL, and the compound PH-4 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-4 in Formula 2 was used to form the EBL, and the compound NH1-1 in Formula 4 was used to form the HBL.

A part of the structure of the OLED in Comparative Examples 23 and 24 and Examples 12 to 14 is listed in Table 9, and the emitting properties, i.e., a driving voltage (V, %), an external quantum efficiency (EQE, %), a color coordinate index (CIEx, CIEy), a maximum emission wavelength (λ_{MAX}, nm) and the lifespan (LT95(1) and LT95), of the OLED in Comparative Examples 11 and 16 to 22 and Examples 9 to 11 was measured and listed in Table 10. The property of the OLED was measured under a condition of 8.6 mA/cm². The driving voltage and the lifespan (LT95(1)) are a relative value to Comparative Example 1, and the lifespan (LT95) is a relative value to Comparative Example 23.

TABLE 9

| | EBL | EML | | HBL |
|---|---|---|---|---|
| Ref23 | PH-4 | PH-4:NH1-1:PD-1 [44:44:12] (30 nm) | | NH1-1 |
| Ref24 | PH-4 | PH-4:NH2-1:PD-1 [44:44:12] (30 nm) | | NH2-1 |
| Ex12 | PH-4 | PH-4:NH2-1:PD-1 | PH-4:NH1-1:PD-1 | NH1-1 |
| | | [44:44:12] (10 nm) | [44:44:12] (20 nm) | |
| Ex13 | PH-4 | PH-4:NH2-1:PD-1 | PH-4:NH1-1:PD-1 | NH1-1 |
| | | [44:44:12] (15 nm) | [44:44:12] (15 nm) | |
| Ex14 | PH-4 | PH-4:NH2-1:PD-1 | PH-4:NH1-1:PD-1 | NH1-1 |
| | | [44:44:12] (20 nm) | [44:44:12] (10 nm) | |

TABLE 10

| | V | EQE [%] | CIEy | λmax | LT95(1) | LT95 |
|---|---|---|---|---|---|---|
| Ref23 | 106% | 21.3 | 0.151 | 462 | 131% | 100% |
| Ref24 | 102% | 19.1 | 0.158 | 462 | 135% | 103% |
| Ex12 | 104% | 20.8 | 0.153 | 462 | 141% | 108% |
| Ex13 | 106% | 20.6 | 0.154 | 462 | 159% | 121% |
| Ex14 | 105% | 19.7 | 0.156 | 462 | 147% | 112% |

As shown in Table 10, in comparison to the OLED of Comparative Examples 23 and 24, the OLED of Examples 12 to 14 provides improved lifespan.

The blue EML in the OLED of Comparative Examples 23 and 24 has a single-layered structure. On the other hand, the blue EML in the OLED of Examples 12 to 14 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 23 and 24, the lifespan of the OLED of Examples 12 to 14 is significantly improved.

In addition, in comparison to the OLED of Examples 12 and 14, where a blue emitting layer with a delayed fluorescent property and a blue emitting layer with an exciplex property have different thickness, the lifespan of the OLED of Example 13, where a blue emitting layer with a delayed fluorescent property and a blue emitting layer with an exciplex property have the same thickness, is further increased.

### 10. Comparative Examples

### (1) Comparative Example 25 (Ref25)

The compound PH-5 in Formula 2 (44 wt %), the compound NH1-1 in Formula 4 (44 wt %) and the compound PD-1 in Formula 8 (12 wt %) were used to form the blue EML (30 nm). The compound PH-5 in Formula 2 was used to form the EBL, and the compound NH1-1 in Formula 4 was used to form the HBL.

### (2) Comparative Example 26 (Ref26)

The compound PH-5 in Formula 2 (44 wt %), the compound NH2-1 in Formula 6 (44 wt %) and the compound PD-1 in Formula 8 (12 wt %) were used to form the blue EML (30 nm). The compound PH-5 in Formula 2 was used to form the EBL, and the compound NH2-1 in Formula 6 was used to form the HBL.

### 11. Examples

### (1) Example 15 (Ex15)

The compound PH-5 in Formula 2 (44 wt %), the compound NH2-1 in Formula 6 (44 wt %) and the compound PD-1 in Formula 8 (12 wt %) were used to form a first blue emitting layer (10 nm) on the EBL, and the compound PH-5 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-5 in Formula 2 was used to form the EBL, and the compound NH1-1 in Formula 4 was used to form the HBL.

### (2) Example 16 (Ex16)

The compound PH-5 in Formula 2 (44 wt %), the compound NH2-1 in Formula 6 (44 wt %) and the compound PD-1 in Formula 8 (12 wt %) were used to form a first blue emitting layer (15 nm) on the EBL, and the compound PH-5 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-5 in Formula 2 was used to form the EBL, and the compound NH1-1 in Formula 4 was used to form the HBL.

### (3) Example 17 (Ex17)

The compound PH-5 in Formula 2 (44 wt %), the compound NH2-1 in Formula 6 (44 wt %) and the compound PD-1 in Formula 8 (12 wt %) were used to form a first blue emitting layer (20 nm) on the EBL, and the compound PH-5 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-5 in Formula 2 was used to form the EBL, and the compound NH1-1 in Formula 4 was used to form the HBL.

A part of the structure of the OLED in Comparative Examples 25 and 26 and Examples 15 to 17 is listed in Table 11, and the emitting properties, i.e., a driving voltage (V, %), an external quantum efficiency (EQE, %), a color coordinate index (CIEx, CIEy), a maximum emission wavelength (λ_{MAX}, nm) and the lifespan (LT95(1) and LT95), of the OLED in Comparative Examples 25 and 26 and Examples 15 to 17 was measured and listed in Table 12. The property of the OLED was measured under a condition of 8.6 mA/cm². The driving voltage and the lifespan (LT95(1)) are a relative value to Comparative Example 1, and the lifespan (LT95) is a relative value to Comparative Example 25.

TABLE 11

| | EBL | EML | | HBL |
|---|---|---|---|---|
| Ref25 | PH-5 | PH-5:NH1-1:PD-1 [44:44:12] (30 nm) | | NH1-1 |
| Ref26 | PH-5 | PH-5:NH2-1:PD-1 [44:44:12] (30 nm) | | |
| Ex15 | PH-5 | PH-5:NH2-1:PD-1 | PH-5:NH1-1:PD-1 | NH1-1 |
| | | [44:44:12] (10 nm) | [44:44:12] (20 nm) | |
| Ex16 | PH-5 | PH-5:NH2-1:PD-1 | PH-5:NH1-1:PD-1 | NH1-1 |
| | | [44:44:12] (15 nm) | [44:44:12] (15 nm) | |
| Ex17 | PH-5 | PH-5:NH2-1:PD-1 | PH-5:NH1-1:PD-1 | NH1-1 |
| | | [44:44:12] (20 nm) | [44:44: 12] (10 nm) | |

TABLE 12

| | V | EQE [%] | CIEy | λmax | LT95(1) | LT95 |
|---|---|---|---|---|---|---|
| Ref25 | 95% | 21.0 | 0.150 | 462 | 83% | 100% |
| Ref26 | 92% | 17.8 | 0.157 | 462 | 92% | 111% |
| Ex15 | 96% | 20.3 | 0.152 | 462 | 98% | 118% |
| Ex16 | 94% | 19.5 | 0.154 | 462 | 119% | 143% |
| Ex17 | 94% | 18.9 | 0.155 | 462 | 101% | 122% |

As shown in Table 12, in comparison to the OLED of Comparative Examples 25 and 26, the OLED of Examples 15 to 17 provides improved lifespan.

The blue EML in the OLED of Comparative Examples 25 and 26 has a single-layered structure. On the other hand, the blue EML in the OLED of Examples 15 to 17 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 25 and 26, the lifespan of the OLED of Examples 15 to 17 is significantly improved.

In addition, in comparison to the OLED of Examples 15 and 17, where a blue emitting layer with a delayed fluorescent property and a blue emitting layer with an exciplex property have different thickness, the lifespan of the OLED of Example 16, where a blue emitting layer with a delayed fluorescent property and a blue emitting layer with an exciplex property have the same thickness, is further increased.

### 12. Comparative Example 27 (Ref27)

The compound PH-3 in Formula 2 (44 wt %), the compound NH2-2 in Formula 6 (44 wt %) and the compound PD-1 in Formula 8 (12 wt %) were used to form the blue EML (30 nm). The compound PH-3 in Formula 2 was used to form the EBL, and the compound NH2-2 in Formula 6 was used to form the HBL.

### 13. Examples

### (1) Example 18 (Ex18)

The compound PH-3 in Formula 2 (44 wt %), the compound NH2-2 in Formula 6 (44 wt %) and the compound PD-1 in Formula 8 (12 wt %) were used to form a first blue emitting layer (10 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (20 nm) on the first blue emitting layer. The compound PH-3 in Formula 2 was used to form the EBL, and the compound NH1-1 in Formula 4 was used to form the HBL.

### (2) Example 19 (Ex19)

The compound PH-3 in Formula 2 (44 wt %), the compound NH2-2 in Formula 6 (44 wt %) and the compound PD-1 in Formula 8 (12 wt %) were used to form a first blue emitting layer (15 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (15 nm) on the first blue emitting layer. The compound PH-3 in Formula 2 was used to form the EBL, and the compound NH1-1 in Formula 4 was used to form the HBL.

### (3) Example 20 (Ex20)

The compound PH-3 in Formula 2 (44 wt %), the compound NH2-2 in Formula 6 (44 wt %) and the compound PD-1 in Formula 8 (12 wt %) were used to form a first blue emitting layer (20 nm) on the EBL, and the compound PH-3 in Formula 2 (44 wt %), the compound NH1-1 in Formula 4 (44 wt %) and the compound PD-1 in Formula 8 (12 wt %) were used to form a second blue emitting layer (10 nm) on the first blue emitting layer. The compound PH-3 in Formula 2 was used to form the EBL, and the compound NH1-1 in Formula 4 was used to form the HBL.

A part of the structure of the OLED in Comparative Examples 11 and 27 and Examples 18 to 20 is listed in Table 13, and the emitting properties, i.e., a driving voltage (V, %), an external quantum efficiency (EQE, %), a color coordinate index (CIEx, CIEy), a maximum emission wavelength (λ_{MAX}, nm) and the lifespan (LT95(1) and LT95), of the OLED in Comparative Examples 11 and 27 and Examples 18 to 20 was measured and listed in Table 14. The property of the OLED was measured under a condition of 8.6 mA/cm². The driving voltage and the lifespan (LT95(1)) are a relative value to Comparative Example 1, and the lifespan (LT95) is a relative value to Comparative Example 11.

TABLE 13

| | EBL | EML | | HBL |
|---|---|---|---|---|
| Ref11 | PH-3 | PH-3:NH1-1:PD-1 [44:44:12] (30 nm) | | NH1-1 |
| Ref27 | PH-3 | PH-3:NH2-2:PD-1 [44:44:12] (30 nm) | | NH2-2 |
| Ex18 | PH-3 | PH-3:NH2-2:PD-1 | PH-3:NH1-1:PD-1 | |
| | | [44:44:12] (10 nm) | [44:44:12] (20 nm) | NH1-1 |
| Ex19 | PH-3 | PH-3:NH2-2:PD-1 | PH-3:NH1-1:PD-1 | NH1-1 |
| | | [44:44:12] (15 nm) | [44:44:12] (15 nm) | |
| Ex20 | PH-3 | PH-3:NH2-2:PD-1 | PH-3:NH1-1:PD-1 | NH1-1 |
| | | [44:44:12] (20 nm) | [44:44:12] (10 nm) | |

TABLE 14

| | V | EQE [%] | CIEy | λmax | LT95(1) | LT95 |
|---|---|---|---|---|---|---|
| Ref11 | 103% | 20.7 | 0.151 | 462 | 106% | 100% |
| Ref27 | 96% | 18.3 | 0.158 | 462 | 118% | 111% |
| Ex18 | 103% | 19.5 | 0.153 | 462 | 132% | 125% |
| Ex19 | 102% | 19.9 | 0.154 | 462 | 155% | 146% |
| Ex20 | 102% | 19.6 | 0.156 | 462 | 131% | 124% |

As shown in Table 12, in comparison to the OLED of Comparative Examples 11 and 27, the OLED of Examples 18 to 20 provides improved lifespan.

The blue EML in the OLED of Comparative Examples 11 and 27 has a single-layered structure. On the other hand, the blue EML in the OLED of Examples 18 to 20 has a double-layered structure including a first blue emitting layer adjacent to an anode and a second blue emitting layer adjacent to a cathode. In this case, the first blue emitting layer includes a first p-type host represented by Formula 1, a first n-type host represented by Formula 5 and a first phosphorescent dopant represented by Formula 7, and the second blue emitting layer includes a second p-type host represented by Formula 1, a second n-type host represented by Formula 3 and a second phosphorescent dopant represented by Formula 7.

In comparison to Comparative Examples 11 and 27, the lifespan of the OLED of Examples 18 to 20 is significantly improved.

In addition, in comparison to the OLED of Examples 18 and 20, where a blue emitting layer with a delayed fluorescent property and a blue emitting layer with an exciplex property have different thickness, the lifespan of the OLED of Example 19, where a blue emitting layer with a delayed fluorescent property and a blue emitting layer with an exciplex property have the same thickness, is further increased.

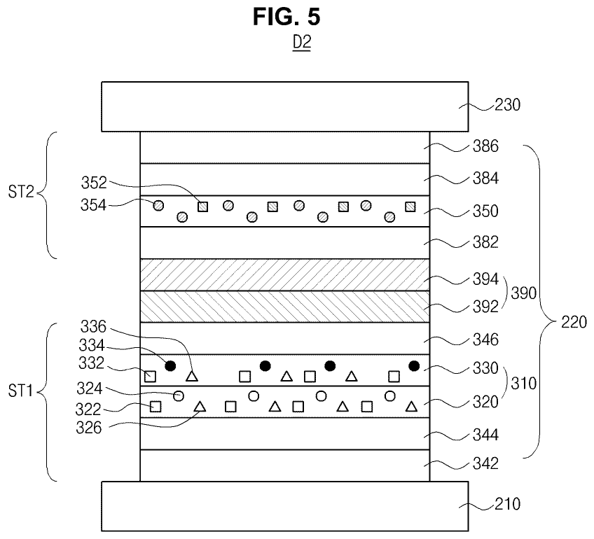

FIG. 5 is a schematic cross-sectional view of an OLED according to one or more embodiments of the present disclosure.

As illustrated in FIG. 5, the OLED D2 includes first and second electrodes 210 and 230 facing each other and an organic light emitting layer 220 therebetween. The organic light emitting layer 220 includes a first emitting part ST1 including a first blue EML 310 and a second emitting part ST2 including a second blue EML 350. The organic light emitting layer 220 can include a CGL 390 between the first and second emitting parts ST1 and ST2. The OLED D2 in a top-emission type can further include a capping layer on the second electrode 230 to enhance a light extraction efficiency.

The organic light emitting display device 100 can include a red pixel region, a green pixel region and a blue pixel region, and the OLED D2 can be positioned in the blue pixel region.

One of the first and second electrodes 210 and 230 can be an anode, and the other one of the first and second electrodes 210 and 230 can be a cathode. One of the first and second electrodes 210 and 230 can be a reflective electrode, and the other one of the first and second electrodes 210 and 230 can be a transparent (or a semi-transparent) electrode.

In a top-emission type OLED D2, the first electrode 210 can be a reflective electrode and can have a structure of ITO/Ag/ITO, and the second electrode 230 can be a transparent electrode and can be formed of Mg:Ag with a weight % ratio of 1:9.

In a bottom-emission type OLED D2, the first electrode 210 can be a transparent electrode and can be formed of ITO, and the second electrode 230 can be a reflective electrode and can be formed of Al.

The first blue EML 310 in the first emitting part ST1 includes a first blue emitting layer 320 and a second blue emitting layer 330. In the first blue EML 310, the second blue emitting layer 330 contacts the first blue emitting layer 320 and is disposed on the first blue emitting layer 320 so that the first blue EML 310 has a double-layered structure. The first blue emitting layer 320 is disposed to be closer to the first electrode 210 as an anode than the second blue emitting layer 330, and the second blue emitting layer 330 is disposed to be closer to the second electrode 230 as a cathode than the first blue emitting layer 320.

The first blue emitting layer 320 includes a first p-type host 322, a first n-type host 324 and a first phosphorescent dopant 326, and the second blue emitting layer 330 includes a second p-type host 332, a second n-type host 334 and a second phosphorescent dopant 336. For example, the first phosphorescent dopant 326 can be referred to as a first emitter, and the second phosphorescent dopant 336 can be referred to as a second emitter.

Each of the first and second p-type hosts 322 and 332 is represented by Formula 1 and is independently selected from the compounds in Formula 2. The first and second p-type hosts 322 and 332 can be same or different.

One of the first and second n-type hosts 324 and 334 is represented by Formula 3 and is selected from the compounds in Formula 2. The other one of the first and second n-type hosts 324 and 334 is represented by Formula 5 and is selected from the compounds in Formula 6.

Each of the first and second phosphorescent dopants 326 and 336 is represented by Formula 7 and is independently selected from the compounds in Formula 8. The first and second phosphorescent dopants 326 and 336 can be same or different.

Each of the first and second blue emitting layers 320 and 330 can have a thickness of 5 to 30 nm, e.g., 10 to 20 nm. For example, a thickness of each of the first and second blue emitting layers 320 and 330 can be 10 nm, 15 nm or 20 nm.

A thickness of the first emitting layer 320 and a thickness of the second blue emitting layer 330 can be same or different. In an aspect of the present disclosure, a thickness of the first emitting layer 320 and a thickness of the second blue emitting layer 330 can be same.

In the first blue emitting layer 320, a weight % of each of the first p-type host 322 and the first n-type host 324 can be greater than that of the first phosphorescent dopant 326, and a weight % of the first p-type host 322 and a weight % of the first n-type host 324 can be same or different. For example, a weight % of the first p-type host 322 and a weight % of the first n-type host 324 can be same.

In an aspect of the present disclosure, the first p-type host 322 can have a weight % of 25 to 50, the first n-type host 324 can have a weight % of 25 to 50, and the first phosphorescent dopant 326 can have a weight % of 4 to 25. In an aspect of the present disclosure, the first p-type host 322 can have a weight % of 44, the first n-type host 324 can have a weight % of 44, and the first phosphorescent dopant 326 can have a weight % of 12.

In the second blue emitting layer 330, a weight % of each of the second p-type host 332 and the second n-type host 334 can be greater than that of the second phosphorescent dopant 336, and a weight % of the second p-type host 332 and a weight % of the second n-type host 334 can be same or different. For example, a weight % of the second p-type host 332 and a weight % of the second n-type host 334 can be same.

In an aspect of the present disclosure, the second p-type host 332 can have a weight % of 25 to 50, the second n-type host 334 can have a weight % of 25 to 50, and the second phosphorescent dopant 336 can have a weight % of 4 to 25. In an aspect of the present disclosure, the second p-type host 332 can have a weight % of 44, the second n-type host 334 can have a weight % of 44, and the second phosphorescent dopant 336 can have a weight % of 12.

A weight % of the first p-type host 322 in the first blue emitting layer 320 and a weight % of the second p-type host 332 in the second blue emitting layer 330 can be same or different. A weight % of the first n-type host 324 in the first blue emitting layer 320 and a weight % of the second n-type host 334 in the second blue emitting layer 330 can be same or different. A weight % of the first phosphorescent dopant 326 in the first blue emitting layer 320 and a weight % of the second phosphorescent dopant 336 in the second blue emitting layer 330 can be same or different.

In the present disclosure, the first n-type host 324 included in the first blue emitting layer 320, which is disposed to be closer to the first electrode 210 as an anode, can be represented by Formula 5 and selected from the compounds in Formula 6, and the second n-type host 334 included in the second blue emitting layer 330, which is disposed to be closer to the second electrode 230 as a cathode, can be represented by Formula 3 and selected from the compounds in Formula 4. In this case, a delayed fluorescent property can be provided from the first blue emitting layer 320, and an exciplex property can be provided from the second blue emitting layer 330. As a result, the lifespan of the OLED D2 and the organic light emitting display device 100 including the same can be significantly increased.

The first emitting part ST1 can further include at least one of a first HTL 344 under the first blue EML 310 and a first ETL 346 over the first blue EML 310.

In addition, the first emitting part ST1 can further include an HIL 342 between the first electrode 210 and the first HTL 344.

Moreover, the first emitting part ST1 can further include at least one of a first EBL between the first HTL 344 and the first blue EML 310 and a first HBL between the first blue EML 310 and the first ETL 346.

The second blue EML 350 can have a single-layered structure. The second blue EML 350 can have a thickness of 10 to 60 nm.

The second blue EML 350 can include a blue host 352 and a blue dopant (e.g., an emitter) 354. The second blue EML 350 can further include an auxiliary dopant (or an auxiliary host). In the second blue EML 350, a weight % of the blue dopant 354 can be smaller than that of each of the blue host 352 and the auxiliary dopant.

For example, the blue host 352 can be selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1), and 9,9′-(5-(triphenylsilyl)-1,3-phenylene)bis(9H-carbazole) (SimCP).

For example, the blue dopant 354 can be selected from the group consisting of perylene, 4,4′-bis[4-(di-p-tolylamino)styryl]biphenyl (DPAVBi), 4-(di-p-tolylamino)-4,4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spiorfluorene (spiro-DPVBi), [1,4-bis[2-[4-[N,N-di(p-tolyl)amino]phenyl]vinyl]benzene (DSB), 1,4-di-[4-(N,N-diphenyl)amino]styryl-benzene (DSA), 2,5,8,11-tetra-tetr-butylperylene (TBPe), bis(2-hydroxylphenyl)-pyridine)beryllium (Bepp2) and 9-(9-Phenylcarbazole-3-yl)-10-(naphthalene-1-yl)anthracene (PCAN).

In an aspect of the present disclosure, the blue host 352 can include at least one of compounds in Formula 13.

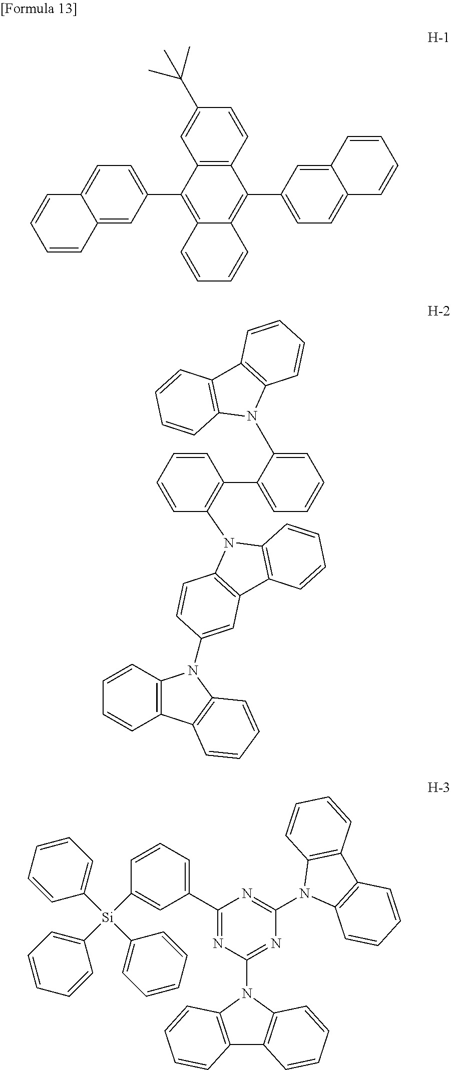

In an aspect of the present disclosure, the blue dopant 354 can be a fluorescent compound being selected from compounds in Formula 14.

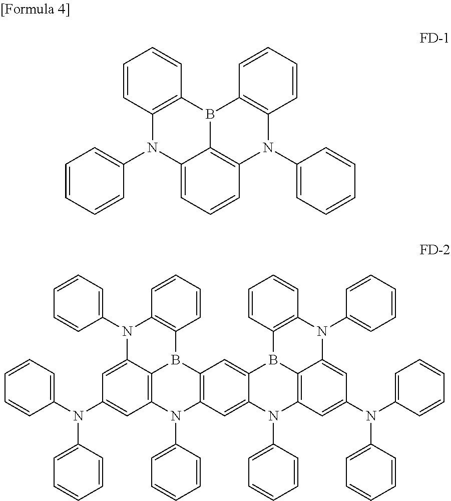 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

In an aspect of the present disclosure, the auxiliary dopant can be a phosphorescent compound or a delayed fluorescent compound. For example, the auxiliary dopant can be selected from compounds in Formula 15.

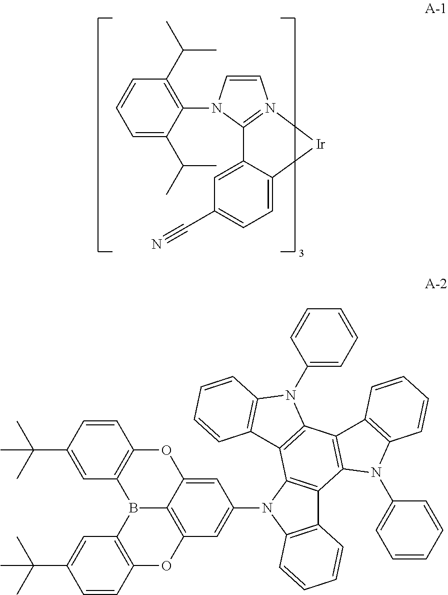

In an aspect of the present disclosure, the second blue EML 350 can be a fluorescent emitting layer including the compound H-1 in Formula 13 and the compound FD-1 in Formula 14.

In an aspect of the present disclosure, the second blue EML 350 can be a PSF emitting layer including the compound H-2 in Formula 13, the compound H-3 in Formula 13, the compound FD-2 in Formula 14 and the compound A-1 in Formula 15.

In an aspect of the present disclosure, the second blue EML 350 can be a hyper-fluorescence emitting layer including the compound H-2 in Formula 13, the compound H-3 in Formula 13, the compound FD-2 in Formula 14 and the compound A-2 in Formula 15.

The second emitting part ST2 can further include at least one of a second HTL 382 under the second blue EML 350 and a second ETL 384 over the second blue EML 350.

In addition, the second emitting part ST2 can further include an EIL 386 between the second electrode 230 and the second ETL 384.

Moreover, the second emitting part ST2 can further include at least one of a second EBL between the second HTL 382 and the second blue EML 350 and a second HBL between the second blue EML 350 and the second ETL 384.

For example, the HIL 342 can include the above-mentioned hole injection material and can have a thickness of 1 to 30 nm, preferably 5 to 15 nm.

Each of the first and second HTLs 344 and 382 can include the above-mentioned hole transporting material and can have a thickness of 20 to 60 nm, preferably 30 to 40 nm.

Each of the first and second ETLs 346 and 384 can include the above-mentioned electron transporting material and can have a thickness of 10 to 50 nm, preferably 20 to 40 nm.

The EIL 386 can include the above-mentioned electron injection material and can have a thickness of 0.1 to 10 nm, preferably 0.5 to 2 nm.

Each of the first and second EBLs can include the above-mentioned electron blocking material and can have a thickness of 5 to 40 nm, preferably 10 to 20 nm.

Each of the first and second HBLs can include the above-mentioned hole blocking material and can have a thickness of 1 to 20 nm, preferably 1 to 10 nm.

The CGL 390 is positioned between the first and second emitting parts ST1 and ST2. Namely, the first and second emitting parts ST1 and ST2 is connected to each other through the CGL 390. The CGL 390 can be a PN-junction CGL of an N-type CGL 392 and a P-type CGL 394.

The N-type CGL 392 is positioned between the first ETL 346 and the second HTL 382, and the P-type CGL 394 is positioned between the N-type CGL 392 and the second HTL 382.

The N-type CGL 392 provides an electron into the first blue EML 310 of the first emitting part ST1, and the P-type CGL 394 provides a hole into the second blue EML 350 of the second emitting part ST2.

The N-type CGL 392 can be an organic layer doped with an alkali metal, e.g., Li, Na, K and Cs, and/or an alkali earth metal, e.g., Mg, Sr, Ba and Ra. For example, the N-type CGL 392 can be formed of an N-type charge generation material including a host being the organic material, e.g., 4,7-dipheny-1,10-phenanthroline (Bphen) and MTDATA, a dopant being an alkali metal and/or an alkali earth metal, and the dopant can be doped with a weight % of 0.01 to 30.

The P-type CGL 394 can be formed of a P-type charge generation material including an inorganic material, e.g., tungsten oxide (WOx), molybdenum oxide (MoOx), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The capping layer can include the above-mentioned hole transporting material and can have a thickness of 50 to 100, preferably 70 to 80 nm.

In the blue pixel region, the organic light emitting layer 220 of the OLED D2 includes the first blue EML 310 and the second blue EML 350 to have a tandem structure.

The first blue EML 310 includes the first blue emitting layer 320, which includes the first p-type host 322, the first n-type host 324 and the first phosphorescent compound 326, and the second blue emitting layer 330, which includes the second p-type host 332, the second n-type host 334 and the second phosphorescent compound 336. Each of the first and second p-type hosts 322 and 332 is a compound represented by Formula 1, and each of the first and second phosphorescent compounds 326 and 336 is a compound represented by Formula 7. One of the first and second n-type hosts 324 and 334 is a compound represented by Formula 3, and the other one of the first and second n-type hosts 324 and 334 is a compound represented by Formula 5.

Accordingly, the lifespan the OLED D2 and the organic light emitting display device 100 of the present disclosure is increased.

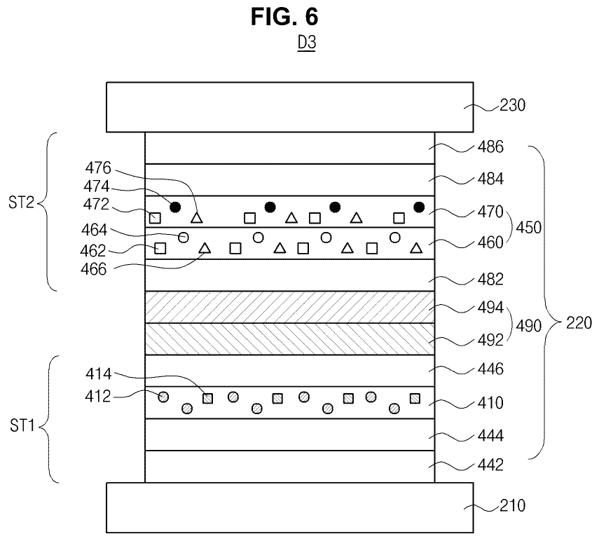

FIG. 6 is a schematic cross-sectional view of an OLED according to one or more embodiments of the present disclosure.

As illustrated in FIG. 6, the OLED D3 includes first and second electrodes 210 and 230 facing each other and an organic light emitting layer 220 therebetween. The organic light emitting layer 220 includes a first emitting part ST1 including a first blue EML 410 and a second emitting part ST2 including a second blue EML 450. The organic light emitting layer 220 can include a CGL 490 between the first and second emitting parts ST1 and ST2. The top-emission type OLED D3 can further include a capping layer on the second electrode 230 to enhance a light extraction efficiency.

The organic light emitting display device 100 (of FIG. 2) can include a red pixel region, a green pixel region and a blue pixel region, and the OLED D3 can be positioned in the blue pixel region.

One of the first and second electrodes 210 and 230 can be an anode, and the other one of the first and second electrodes 210 and 230 can be a cathode. One of the first and second electrodes 210 and 230 can be a reflective electrode, and the other one of the first and second electrodes 210 and 230 can be a transparent (or a semi-transparent) electrode.

In a top-emission type OLED D3, the first electrode 210 can be a reflective electrode and can have a structure of ITO/Ag/ITO, and the second electrode 230 can be a transparent electrode and can be formed of Mg:Ag with a weight % ratio of 1:9.

In a bottom-emission type OLED D3, the first electrode 210 can be a transparent electrode and can be formed of ITO, and the second electrode 230 can be a reflective electrode and can be formed of Al.

The first emitting part ST1 can further include at least one of a first HTL 444 under the first blue EML 410 and a first ETL 446 over the first blue EML 410.

In addition, the first emitting part ST1 can further include an HIL 442 between the first electrode 210 and the first HTL 444.

Moreover, the first emitting part ST1 can further include at least one of a first EBL between the first HTL 444 and the first blue EML 410 and a first HBL between the first blue EML 410 and the first ETL 446.

The second emitting part ST2 can further include at least one of a second HTL 482 under the second blue EML 450 and a second ETL 484 over the second blue EML 450.

In addition, the second emitting part ST2 can further include an EIL 486 between the second electrode 230 and the second ETL 484.

Moreover, the second emitting part ST2 can further include at least one of a second EBL between the second HTL 482 and the second blue EML 450 and a second HBL between the second blue EML 450 and the second ETL 484.

For example, the HIL 442 can include the above-mentioned hole injection material and can have a thickness of 1 to 30 nm, preferably 5 to 15 nm.

Each of the first and second HTLs 444 and 482 can include the above-mentioned hole transporting material and can have a thickness of 20 to 60 nm, preferably 30 to 40 nm.

Each of the first and second ETLs 446 and 484 can include the above-mentioned electron transporting material and can have a thickness of 10 to 100 nm, preferably 20 to 40 nm.

The EIL 486 can include the above-mentioned electron injection material and can have a thickness of 0.1 to 10 nm, preferably 0.5 to 2 nm.

Each of the first and second EBLs can include the above-mentioned electron blocking material and can have a thickness of 5 to 40 nm, preferably 10 to 20 nm.

Each of the first and second HBLs can include the above-mentioned hole blocking material and can have a thickness of 1 to 20 nm, preferably 1 to 10 nm.

The CGL 490 is positioned between the first and second emitting parts ST1 and ST2. Namely, the first and second emitting parts ST1 and ST2 is connected to each other through the CGL 490. The CGL 490 can be a PN-junction CGL of an N-type CGL 492 and a P-type CGL 494.

The N-type CGL 492 is positioned between the first ETL 446 and the second HTL 482, and the P-type CGL 494 is positioned between the N-type CGL 492 and the second HTL 482.

The N-type CGL 492 provides an electron into the first blue EML 410 of the first emitting part ST1, and the P-type CGL 494 provides a hole into the second blue EML 450 of the second emitting part ST2.

The N-type CGL 492 can include the above-mentioned N-type charge generation material, and the P-type CGL 494 can include the above-mentioned P-type charge generation material.

The capping layer can include the above-mentioned hole transporting material and can have a thickness of 50 to 100 nm, preferably 70 to 80 nm.

The first blue EML 410 in the first emitting part ST1 can have a single-layered structure. The first blue EML 410 can have a thickness of 10 to 60 nm.

The first blue EML 410 can include a blue host 452 and a blue dopant (e.g., an emitter) 454. The first blue EML 410 can further include an auxiliary dopant (or an auxiliary host). In the first blue EML 410, a weight % of the blue dopant 454 can be smaller than that of each of the blue host 452 and the auxiliary dopant.

For example, the first blue EML 410 can be a fluorescent emitting layer including the compound H-1 in Formula 13 and the compound FD-1 in Formula 14.

In an aspect of the present disclosure, the first blue EML 410 can be a phosphor-sensitized fluorescence (PSF) emitting layer including the compound H-1 in Formula 13, the compound H-3 in Formula 13, the compound FD-2 in Formula 14 and the compound A-1 in Formula 15.

In an aspect of the present disclosure, the first blue EML 410 can be a hyperfluorescence emitting layer including the compound H-2 in Formula 13, the compound H-3 in Formula 13, the compound FD-2 in Formula 14 and the compound A-2 in Formula 15.

The second blue EML 450 in the second emitting part ST2 includes a first blue emitting layer 460 and a second blue emitting layer 470. In the second blue EML 450, the second blue emitting layer 470 contacts the first blue emitting layer 460 and is disposed on the first blue emitting layer 460 so that the second blue EML 450 has a double-layered structure. The first blue emitting layer 460 is disposed to be closer to the first electrode 210 as an anode than the second blue emitting layer 470, and the second blue emitting layer 470 is disposed to be closer to the second electrode 230 as a cathode than the first blue emitting layer 460.

The first blue emitting layer 460 includes a first p-type host 462, a first n-type host 464 and a first phosphorescent dopant 466, and the second blue emitting layer 470 includes a second p-type host 472, a second n-type host 474 and a second phosphorescent dopant 476. For example, the first phosphorescent dopant 466 can be referred to as a first emitter, and the second phosphorescent dopant 476 can be referred to as a second emitter.

Each of the first and second p-type hosts 462 and 472 is represented by Formula 1 and is independently selected from the compounds in Formula 2. The first and second p-type hosts 462 and 472 can be same or different.

One of the first and second n-type hosts 464 and 474 is represented by Formula 3 and is selected from the compounds in Formula 2. The other one of the first and second n-type hosts 464 and 474 is represented by Formula 5 and is selected from the compounds in Formula 6.

Each of the first and second phosphorescent dopants 466 and 476 is represented by Formula 7 and is independently selected from the compounds in Formula 8. The first and second phosphorescent dopants 466 and 476 can be same or different.

Each of the first and second blue emitting layers 460 and 470 can have a thickness of 5 to 30 nm, e.g., 10 to 20 nm. For example, a thickness of each of the first and second blue emitting layers 460 and 470 can be 10 nm, 15 nm or 20 nm.

A thickness of the first emitting layer 460 and a thickness of the second blue emitting layer 470 can be same or different. In an aspect of the present disclosure, a thickness of the first emitting layer 460 and a thickness of the second blue emitting layer 470 can be same.

In the first blue emitting layer 460, a weight % of each of the first p-type host 462 and the first n-type host 464 can be greater than that of the first phosphorescent dopant 466, and a weight % of the first p-type host 462 and a weight % of the first n-type host 464 can be same or different. For example, a weight % of the first p-type host 462 and a weight % of the first n-type host 464 can be same.

In an aspect of the present disclosure, the first p-type host 462 can have a weight % of 25 to 50, the first n-type host 464 can have a weight % of 25 to 50, and the first phosphorescent dopant 466 can have a weight % of 4 to 25. In an aspect of the present disclosure, the first p-type host 462 can have a weight % of 44, the first n-type host 464 can have a weight % of 44, and the first phosphorescent dopant 466 can have a weight % of 12.

In the second blue emitting layer 470, a weight % of each of the second p-type host 472 and the second n-type host 474 can be greater than that of the second phosphorescent dopant 476, and a weight % of the second p-type host 472 and a weight % of the second n-type host 474 can be same or different. For example, a weight % of the second p-type host 472 and a weight % of the second n-type host 474 can be same.

In an aspect of the present disclosure, the second p-type host 472 can have a weight % of 25 to 50, the second n-type host 474 can have a weight % of 25 to 50, and the second phosphorescent dopant 476 can have a weight % of 4 to 25. In an aspect of the present disclosure, the second p-type host 472 can have a weight % of 44, the second n-type host 474 can have a weight % of 44, and the second phosphorescent dopant 476 can have a weight % of 12.

A weight % of the first p-type host 462 in the first blue emitting layer 460 and a weight % of the second p-type host 472 in the second blue emitting layer 470 can be same or different. A weight % of the first n-type host 464 in the first blue emitting layer 460 and a weight % of the second n-type host 474 in the second blue emitting layer 470 can be same or different. A weight % of the first phosphorescent dopant 466 in the first blue emitting layer 460 and a weight % of the second phosphorescent dopant 476 in the second blue emitting layer 470 can be same or different.

In the present disclosure, the first n-type host 464 included in the first blue emitting layer 460, which is disposed to be closer to the first electrode 210 as an anode, can be represented by Formula 5 and selected from the compounds in Formula 6, and the second n-type host 474 included in the second blue emitting layer 470, which is disposed to be closer to the second electrode 230 as a cathode, can be represented by Formula 3 and selected from the compounds in Formula 4. In this case, a delayed fluorescent property can be provided from the first blue emitting layer 460, and an exciplex property can be provided from the second blue emitting layer 470. As a result, the lifespan of the OLED D3 and the organic light emitting display device 100 including the same can be significantly increased.

In the blue pixel region, the organic emitting layer 220 of the OLED D3 includes the first blue EML 410 and the second blue EML 450 to have a tandem structure.

The second blue EML 450 includes the first blue emitting layer 460, which includes the first p-type host 462, the first n-type host 464 and the first phosphorescent compound 466, and the second blue emitting layer 470, which includes the second p-type host 472, the second n-type host 474 and the second phosphorescent compound 476. Each of the first and second p-type hosts 462 and 472 is a compound represented by Formula 1, and each of the first and second phosphorescent compounds 466 and 476 is a compound represented by Formula 7. One of the first and second n-type hosts 464 and 474 is a compound represented by Formula 3, and the other one of the first and second n-type hosts 464 and 474 is a compound represented by Formula 5.

Accordingly, the lifespan of the OLED D3 and the organic light emitting display device 100 of the present disclosure is increased.

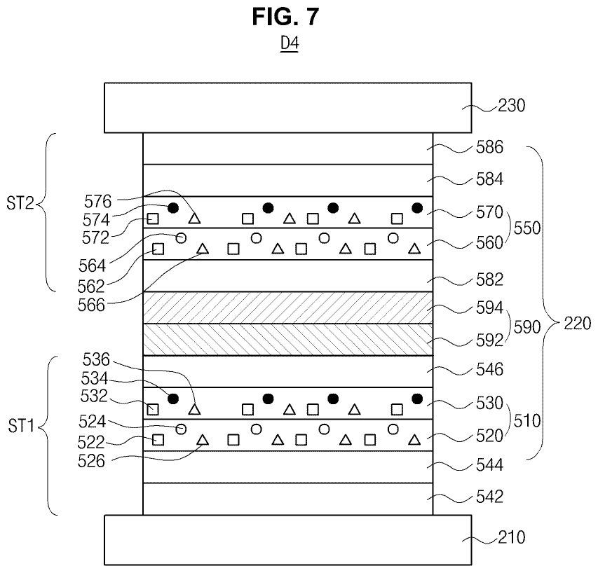

FIG. 7 is a schematic cross-sectional view of an OLED according to one or more embodiments of the present disclosure.

As illustrated in FIG. 7, the OLED D4 includes first and second electrodes 210 and 230 facing each other and an organic light emitting layer 220 therebetween. The organic light emitting layer 220 includes a first emitting part ST1 including a first blue EML 510 and a second emitting part ST2 including a second blue EML 550. The organic light emitting layer 220 can include a CGL 590 between the first and second emitting parts ST1 and ST2. The OLED D4 in a top-emission type can further include a capping layer on the second electrode 230 to enhance a light extraction efficiency.

The organic light emitting display device 100 can include a red pixel region, a green pixel region and a blue pixel region, and the OLED D4 can be positioned in the blue pixel region.

One of the first and second electrodes 210 and 230 can be an anode, and the other one of the first and second electrodes 210 and 230 can be a cathode. One of the first and second electrodes 210 and 230 can be a reflective electrode, and the other one of the first and second electrodes 210 and 230 can be a transparent (or a semi-transparent) electrode.

In a top-emission type OLED D4, the first electrode 210 can be a reflective electrode and can have a structure of ITO/Ag/ITO, and the second electrode 230 can be a transparent electrode and can be formed of Mg:Ag with a weight % ratio of 1:9.

In a bottom-emission type OLED D4, the first electrode 210 can be a transparent electrode and can be formed of ITO, and the second electrode 230 can be a reflective electrode and can be formed of Al.

The first emitting part ST1 can further include at least one of a first HTL 544 under the first blue EML 510 and a first ETL 546 over the first blue EML 510.

In addition, the first emitting part ST1 can further include an HIL 542 between the first electrode 210 and the first HTL 544.

Moreover, the first emitting part ST1 can further include at least one of a first EBL between the first HTL 544 and the first blue EML 510 and a first HBL between the first blue EML 510 and the first ETL 546.

The second emitting part ST2 can further include at least one of a second HTL 582 under the second blue EML 550 and a second ETL 584 over the second blue EML 550.

In addition, the second emitting part ST2 can further include an EIL 586 between the second electrode 230 and the second ETL 584.

Moreover, the second emitting part ST2 can further include at least one of a second EBL between the second HTL 582 and the second blue EML 550 and a second HBL between the second blue EML 550 and the second ETL 584.

For example, the HIL 542 can include the above-mentioned hole injection material and can have a thickness of 1 to 30 nm, preferably 5 to 15 nm.

Each of the first and second HTLs 544 and 582 can include the above-mentioned hole transporting material and can have a thickness of 20 to 60 nm, preferably 30 to 40 nm.

Each of the first and second ETLs 546 and 584 can include the above-mentioned electron transporting material and can have a thickness of 10 to 100 nm, preferably 20 to 40 nm.

The EIL 586 can include the above-mentioned electron injection material and can have a thickness of 0.1 to 10 nm, preferably 0.5 to 2 nm.

Each of the first and second EBLs can include the above-mentioned electron blocking material and can have a thickness of 5 to 40 nm, preferably 10 to 20 nm.

Each of the first and second HBLs can include the above-mentioned hole blocking material and can have a thickness of 1 to 20 nm, preferably 1 to 10 nm.

The CGL 590 is positioned between the first and second emitting parts ST1 and ST2. Namely, the first and second emitting parts ST1 and ST2 is connected to each other through the CGL 590. The CGL 590 can be a PN-junction CGL of an N-type CGL 592 and a P-type CGL 594.

The N-type CGL 592 is positioned between the first ETL 546 and the second HTL 582, and the P-type CGL 594 is positioned between the N-type CGL 592 and the second HTL 582.

The N-type CGL 592 provides an electron into the first blue EML 510 of the first emitting part ST1, and the P-type CGL 594 provides a hole into the second blue EML 550 of the second emitting part ST2.

The N-type CGL 592 can include the above-mentioned N-type charge generation material, and the P-type CGL 594 can include the above-mentioned P-type charge generation material.

The capping layer can include the above-mentioned hole transporting material and can have a thickness of 50 to 100 nm, preferably 70 to 80 nm.

The first blue EML 510 in the first emitting part ST1 includes a first blue emitting layer 520 and a second blue emitting layer 530. In the first blue EML 510, the second blue emitting layer 530 contacts the first blue emitting layer 520 and is disposed on the first blue emitting layer 520 so that the first blue EML 510 has a double-layered structure. The first blue emitting layer 520 is disposed to be closer to the first electrode 210 as an anode than the second blue emitting layer 530, and the second blue emitting layer 530 is disposed to be closer to the second electrode 230 as a cathode than the first blue emitting layer 520.

The first blue emitting layer 520 includes a first p-type host 522, a first n-type host 524 and a first phosphorescent dopant 526, and the second blue emitting layer 530 includes a second p-type host 552, a second n-type host 534 and a second phosphorescent dopant 536. For example, the first phosphorescent dopant 526 can be referred to as a first emitter, and the second phosphorescent dopant 536 can be referred to as a second emitter.

Each of the first and second p-type hosts 522 and 532 is represented by Formula 1 and is independently selected from the compounds in Formula 2. The first and second p-type hosts 522 and 532 can be same or different.

One of the first and second n-type hosts 524 and 534 is represented by Formula 3 and is selected from the compounds in Formula 2. The other one of the first and second n-type hosts 524 and 534 is represented by Formula 5 and is selected from the compounds in Formula 6.

Each of the first and second phosphorescent dopants 526 and 536 is represented by Formula 7 and is independently selected from the compounds in Formula 8. The first and second phosphorescent dopants 526 and 536 can be same or different.

Each of the first and second blue emitting layers 520 and 530 can have a thickness of 5 to 30 nm, e.g., 10 to 20 nm. For example, a thickness of each of the first and second blue emitting layers 520 and 530 can be 10 nm, 15 nm or 20 nm.

A thickness of the first emitting layer 520 and a thickness of the second blue emitting layer 530 can be same or different. In an aspect of the present disclosure, a thickness of the first emitting layer 520 and a thickness of the second blue emitting layer 530 can be same.

In the first blue emitting layer 520, a weight % of each of the first p-type host 522 and the first n-type host 524 can be greater than that of the first phosphorescent dopant 526, and a weight % of the first p-type host 522 and a weight % of the first n-type host 524 can be same or different. For example, a weight % of the first p-type host 522 and a weight % of the first n-type host 524 can be same.

In an aspect of the present disclosure, the first p-type host 522 can have a weight % of 25 to 50, the first n-type host 524 can have a weight % of 25 to 50, and the first phosphorescent dopant 526 can have a weight % of 4 to 25. In an aspect of the present disclosure, the first p-type host 522 can have a weight % of 44, the first n-type host 524 can have a weight % of 44, and the first phosphorescent dopant 526 can have a weight % of 12.

In the second blue emitting layer 530, a weight % of each of the second p-type host 532 and the second n-type host 534 can be greater than that of the second phosphorescent dopant 536, and a weight % of the second p-type host 532 and a weight % of the second n-type host 534 can be same or different. For example, a weight % of the second p-type host 532 and a weight % of the second n-type host 534 can be same.

In an aspect of the present disclosure, the second p-type host 532 can have a weight % of 25 to 50, the second n-type host 534 can have a weight % of 25 to 50, and the second phosphorescent dopant 536 can have a weight % of 4 to 25. In an aspect of the present disclosure, the second p-type host 532 can have a weight % of 44, the second n-type host 534 can have a weight % of 44, and the second phosphorescent dopant 536 can have a weight % of 12.

A weight % of the first p-type host 522 in the first blue emitting layer 520 and a weight % of the second p-type host 532 in the second blue emitting layer 530 can be same or different. A weight % of the first n-type host 524 in the first blue emitting layer 520 and a weight % of the second n-type host 534 in the second blue emitting layer 530 can be same or different. A weight % of the first phosphorescent dopant 526 in the first blue emitting layer 520 and a weight % of the second phosphorescent dopant 536 in the second blue emitting layer 530 can be same or different.

In the present disclosure, the first n-type host 524 included in the first blue emitting layer 520, which is disposed to be closer to the first electrode 210 as an anode, can be represented by Formula 5 and selected from the compounds in Formula 6, and the second n-type host 534 included in the second blue emitting layer 530, which is disposed to be closer to the second electrode 230 as a cathode, can be represented by Formula 3 and selected from the compounds in Formula 4. In this case, a delayed fluorescent property can be provided from the first blue emitting layer 520, and an exciplex property can be provided from the second blue emitting layer 530. As a result, the lifespan of the OLED D4 and the organic light emitting display device 100 including the same can be significantly increased.

The second blue EML 550 in the second emitting part ST2 includes a third blue emitting layer 560 and a fourth blue emitting layer 570. In the second blue EML 550, the fourth blue emitting layer 570 contacts the third blue emitting layer 560 and is disposed on the third blue emitting layer 560 so that the second blue EML 550 has a double-layered structure. The third blue emitting layer 560 is disposed to be closer to the first electrode 210 as an anode than the fourth blue emitting layer 570, and the fourth blue emitting layer 570 is disposed to be closer to the second electrode 230 as a cathode than the third blue emitting layer 560.

The third blue emitting layer 560 includes a third p-type host 562, a third n-type host 564 and a third phosphorescent dopant 566, and the fourth blue emitting layer 570 includes a fourth p-type host 572, a fourth n-type host 574 and a fourth phosphorescent dopant 576. For example, the third phosphorescent dopant 566 can be referred to as a first emitter, and the fourth phosphorescent dopant 576 can be referred to as a second emitter.

Each of the first and fourth p-type hosts 562 and 572 is represented by Formula 1 and is independently selected from the compounds in Formula 2. The first and fourth p-type hosts 562 and 572 can be same or different.

One of the first and fourth n-type hosts 564 and 574 is represented by Formula 3 and is selected from the compounds in Formula 2. The other one of the first and fourth n-type hosts 564 and 574 is represented by Formula 5 and is selected from the compounds in Formula 6.

Each of the first and fourth phosphorescent dopants 566 and 576 is represented by Formula 7 and is independently selected from the compounds in Formula 8. The first and fourth phosphorescent dopants 566 and 576 can be same or different.

Each of the first and fourth blue emitting layers 560 and 570 can have a thickness of 5 to 30 nm, e.g., 10 to 20 nm. For example, a thickness of each of the first and fourth blue emitting layers 560 and 570 can be 10 nm, 15 nm or 20 nm.

A thickness of the first emitting layer 560 and a thickness of the fourth blue emitting layer 570 can be same or different. In an aspect of the present disclosure, a thickness of the first emitting layer 560 and a thickness of the fourth blue emitting layer 570 can be same.

In the third blue emitting layer 560, a weight % of each of the third p-type host 562 and the third n-type host 564 can be greater than that of the third phosphorescent dopant 566, and a weight % of the third p-type host 562 and a weight % of the third n-type host 564 can be same or different. For example, a weight % of the third p-type host 562 and a weight % of the third n-type host 564 can be same.

In an aspect of the present disclosure, the third p-type host 562 can have a weight % of 25 to 50, the third n-type host 564 can have a weight % of 25 to 50, and the third phosphorescent dopant 566 can have a weight % of 4 to 25. In an aspect of the present disclosure, the third p-type host 562 can have a weight % of 44, the third n-type host 564 can have a weight % of 44, and the third phosphorescent dopant 566 can have a weight % of 12.

In the fourth blue emitting layer 570, a weight % of each of the fourth p-type host 572 and the fourth n-type host 574 can be greater than that of the fourth phosphorescent dopant 576, and a weight % of the fourth p-type host 572 and a weight % of the fourth n-type host 574 can be same or different. For example, a weight % of the fourth p-type host 572 and a weight % of the fourth n-type host 574 can be same.

In an aspect of the present disclosure, the fourth p-type host 572 can have a weight % of 25 to 50, the fourth n-type host 574 can have a weight % of 25 to 50, and the fourth phosphorescent dopant 576 can have a weight % of 4 to 25. In an aspect of the present disclosure, the fourth p-type host 572 can have a weight % of 44, the fourth n-type host 574 can have a weight % of 44, and the fourth phosphorescent dopant 576 can have a weight % of 12.

A weight % of the third p-type host 562 in the third blue emitting layer 560 and a weight % of the fourth p-type host 572 in the fourth blue emitting layer 570 can be same or different. A weight % of the third n-type host 564 in the third blue emitting layer 560 and a weight % of the fourth n-type host 574 in the fourth blue emitting layer 570 can be same or different. A weight % of the third phosphorescent dopant 566 in the third blue emitting layer 560 and a weight % of the fourth phosphorescent dopant 576 in the fourth blue emitting layer 570 can be same or different.

In the present disclosure, the third n-type host 564 included in the third blue emitting layer 560, which is disposed to be closer to the first electrode 210 as an anode, can be represented by Formula 5 and selected from the compounds in Formula 6, and the fourth n-type host 574 included in the fourth blue emitting layer 570, which is disposed to be closer to the second electrode 230 as a cathode, can be represented by Formula 3 and selected from the compounds in Formula 4. In this case, a delayed fluorescent property can be provided from the third blue emitting layer 560, and an exciplex property can be provided from the fourth blue emitting layer 570. As a result, the lifespan of the OLED D4 and the organic light emitting display device 100 including the same can be significantly increased.

In the blue pixel region, the organic emitting layer 220 of the OLED D4 includes the first blue EML 510 and the second blue EML 550 to have a tandem structure.

The first blue EML 510 includes the first blue emitting layer 520, which includes the first p-type host 522, the first n-type host 524 and the first phosphorescent compound 526, and the second blue emitting layer 530, which includes the second p-type host 532, the second n-type host 534 and the second phosphorescent compound 536. Each of the first and second p-type hosts 522 and 532 is a compound represented by Formula 1, and each of the first and second phosphorescent compounds 526 and 536 is a compound represented by Formula 7. One of the first and second n-type hosts 524 and 534 is a compound represented by Formula 3, and the other one of the first and second n-type hosts 524 and 534 is a compound represented by Formula 5.

The second blue EML 550 includes the third blue emitting layer 560, which includes the third p-type host 562, the third n-type host 564 and the third phosphorescent compound 566, and the fourth blue emitting layer 570, which includes the fourth p-type host 572, the fourth n-type host 574 and the fourth phosphorescent compound 576. Each of the third and fourth p-type hosts 562 and 572 is a compound represented by Formula 1, and each of the third and fourth phosphorescent compounds 566 and 576 is a compound represented by Formula 7. One of the third and fourth n-type hosts 564 and 574 is a compound represented by Formula 3, and the other one of the third and fourth n-type hosts 564 and 574 is a compound represented by Formula 5.

Accordingly, the lifespan of the OLED D4 and the organic light emitting display device 100 of the present disclosure is increased.

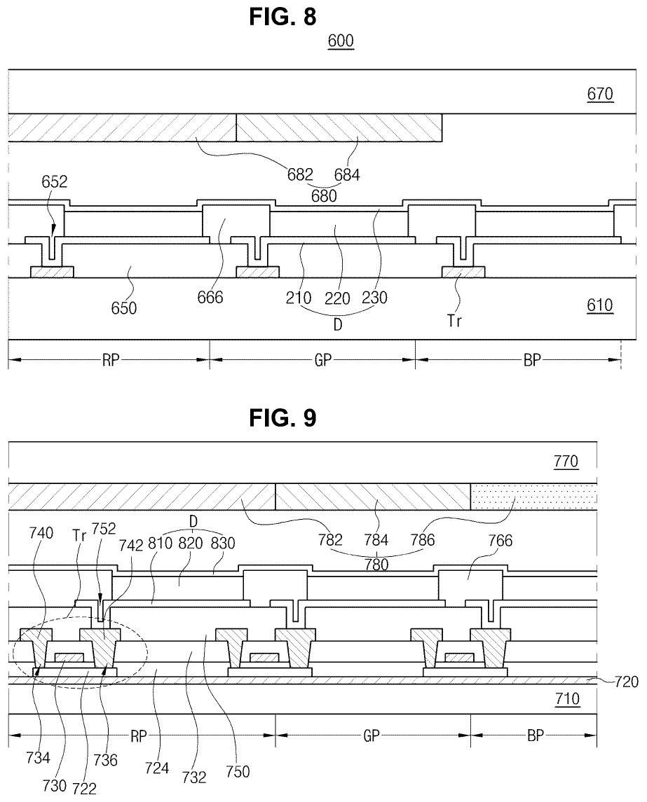

FIG. 8 is a schematic cross-sectional view illustrating an organic light emitting display device according to one or more embodiments of the present disclosure.

As illustrated in FIG. 8, the organic light emitting display device 600 includes a first substrate 610, where a red pixel region RP, a green pixel region GP and a blue pixel region BP are defined, a second substrate 670 facing the first substrate 610, an OLED D, which is positioned between the first and second substrates 610 and 670 and providing blue emission, and a color conversion layer 680 between the OLED D and the second substrate 670.

In some embodiments, a color filter can be formed between the second substrate 670 and each color conversion layer 680.

Each of the first and second substrates 610 and 670 can be a glass substrate or a flexible substrate. For example, the flexible substrate can be a polyimide (PI) substrate, a polyethersulfone (PES) substrate, a polyethylenenaphthalate (PEN) substrate, a polyethylene terephthalate (PET) substrate or a polycarbonate (PC) substrate.

A TFT Tr, which corresponding to each of the red, green and blue pixel regions RP, GP and BP, is formed on the first substrate 610, and a planarization layer 650, which has a drain contact hole 652 exposing an electrode, e.g., a drain electrode, of the TFT Tr is formed to cover the TFT Tr.

The OLED D including a first electrode 210, an organic light emitting layer 220 and a second electrode 230 is formed on the planarization layer 650. In this instance, the first electrode 210 can be connected to the drain electrode of the TFT Tr through the drain contact hole 652.

One of the first and second electrodes 210 and 230 can be an anode, and the other one of the first and second electrodes 210 and 230 can be a cathode. One of the first and second electrodes 210 and 230 can be a reflective electrode, and the other one of the first and second electrodes 210 and 230 can be a transparent (or a semi-transparent) electrode.

In a top-emission type OLED D, the first electrode 210 can be a reflective electrode and can have a structure of ITO/Ag/ITO, and the second electrode can be a transparent electrode and can be formed of Mg:Ag with a weight % ratio of 1:9. In a bottom-emission type OLED D, the first electrode 210 can be a transparent electrode and can be formed of ITO, and the second electrode can be a reflective electrode and can be formed of Al.

A bank layer 666 is formed on the planarization layer 650 to cover an edge of the first electrode 210. Namely, the bank layer 666 is positioned at a boundary of each of the red, green and blue pixel regions and exposes a center of the first electrode 210 in each of the red, green and blue pixel regions RP, GP and BP.

The OLED D emits a blue light and can have a structure shown in FIGS. 3, 5, 6 and 7. Namely, the OLED D is formed in each of the red, green and blue pixel regions RP, GP and BP and provides the blue light.

For example, referring to FIG. 3, the organic light emitting layer 220 of the OLED D includes the blue EML 240, and the blue EML 240 include the first blue emitting layer 250, which includes the first p-type host 252, the first n-type host 254 and the first phosphorescent compound 256, and the second blue emitting layer 260, which includes the second p-type host 262, the second n-type host 264 and the second phosphorescent compound 266.

Each of the first p-type host 252 in the first blue emitting layer 250 and the second p-type host 262 in the second blue emitting layer 260 is a compound represented by Formula 1 and is independently selected from the compounds in Formula 2. One of the first n-type host 254 in the first blue emitting layer 250 and the second n-type host 264 in the second blue emitting layer 260 is a compound represented by Formula 3 and is selected from the compounds in Formula 4. The other one of the first n-type host 254 in the first blue emitting layer 250 and the second n-type host 264 in the second blue emitting layer 260 is a compound represented by Formula 5 and is selected from the compounds in Formula 6. Each of the first and second phosphorescent compounds 256 and 266 is represented by Formula 7 and is independently selected from the compounds in Formula 8.

Since the OLED D emits blue light in each of the red, green and blue pixel regions RP, GP and BP, the organic light emitting layer 220 can be integrally formed as a common layer in the red, green and blue pixel regions RP, GP and BP without separation. The bank layer 666 can be formed to prevent a current leakage at an edge of the first electrode 210 and can be omitted.

The color conversion layer 680 includes a first color conversion layer 682 corresponding to the red pixel region RP and a second color conversion layer 684 corresponding to the green pixel region GP. For example, the color conversion layer 680 can include an inorganic color conversion material such as a quantum dot. The color conversion layer is not presented in the blue pixel region BP so that the OLED D in the blue pixel region BP can directly face the second substrate 670.

The blue light from the OLED D is converted into the red light by the first color conversion layer 682 in the red pixel region RP, and the blue light from the OLED D is converted into the green light by the second color conversion layer 684 in the green pixel region GP.

Accordingly, the organic light emitting display device 600 can display a full-color image.

When the light from the OLED D passes through the first substrate 610 to display an image, the color conversion layer 680 can be disposed between the OLED D and the first substrate 610.

FIG. 9 is a schematic cross-sectional view illustrating an organic light emitting display device according to one or more embodiments of the present disclosure.

As illustrated in FIG. 9, the organic light emitting display device 700 includes a first substrate 710, where a red pixel region RP, a green pixel region GP and a blue pixel region BP are defined, a second substrate 770 facing the first substrate 710, an OLED D, which is positioned between the first and second substrates 710 and 770 and providing white emission, and a color filter layer 780 between the OLED D and the second substrate 770.

Each of the first and second substrates 710 and 770 can be a glass substrate or a flexible substrate. For example, the flexible substrate can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 720 is formed on the substrate, and the TFT Tr corresponding to each of the red, green and blue pixel regions RP, GP and BP is formed on the buffer layer 720. The buffer layer 720 can be omitted.

A semiconductor layer 722 is formed on the buffer layer 720. The semiconductor layer 722 can include an oxide semiconductor material or polycrystalline silicon.

A gate insulating layer 724 is formed on the semiconductor layer 722. The gate insulating layer 724 can be formed of an inorganic insulating material such as silicon oxide or silicon nitride.

A gate electrode 730, which is formed of a conductive material, e.g., metal, is formed on the gate insulating layer 724 to correspond to a center of the semiconductor layer 722.

An interlayer insulating layer 732, which is formed of an insulating material, is formed on the gate electrode 730. The interlayer insulating layer 732 can be formed of an inorganic insulating material, e.g., silicon oxide or silicon nitride, or an organic insulating material, e.g., benzocyclobutene or photo-acryl.

The interlayer insulating layer 732 includes first and second contact holes 734 and 736 exposing both sides of the semiconductor layer 722. The first and second contact holes 734 and 736 are positioned at both sides of the gate electrode 730 to be spaced apart from the gate electrode 730.

A source electrode 740 and a drain electrode 742, which are formed of a conductive material, e.g., metal, are formed on the interlayer insulating layer 732.

The source electrode 740 and the drain electrode 742 are spaced apart from each other with respect to the gate electrode 730 and respectively contact both sides of the semiconductor layer 722 through the first and second contact holes 734 and 736.

The semiconductor layer 722, the gate electrode 730, the source electrode 740 and the drain electrode 742 constitute the TFT Tr. The TFT Tr serves as a driving element. Namely, the TFT Tr can correspond to the driving TFT Td (of FIG. 1).

In some embodiments, the gate line and the data line cross each other to define the pixel regions, and the switching TFT is formed to be connected to the gate and data lines. The switching TFT is connected to the TFT Tr as the driving element.

In addition, the power line, which can be formed to be parallel to and spaced apart from one of the gate and data lines, and the storage capacitor for maintaining the voltage of the gate electrode of the TFT Tr in one frame can be further formed.

A planarization layer 750, which includes a drain contact hole 752 exposing the drain electrode 742 of the TFT Tr, is formed to cover the TFT Tr.

A first electrode 810, which is connected to the drain electrode 742 of the TFT Tr through the drain contact hole 752, is separately formed in each pixel and on the planarization layer 750. The first electrode 810 can be an anode and can be formed of a conductive material having a relatively high work function. For example, the first electrode 810 can include a transparent conductive oxide layer formed of a transparent conductive oxide (TCO) and a reflective layer.

For example, the transparent conductive oxide material layer of the first electrode 810 can be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

For example, the reflective layer can be formed of one of silver (Ag), an alloy of Ag and one of palladium (Pd), copper (Cu), indium (In) and neodymium (Nd), and aluminum-palladium-copper (APC) alloy. For example, the first electrode 210 can have a double-layered structure of Ag/ITO or APC/ITO or a triple-layered structure of ITO/Ag/ITO or ITO/APC/ITO.

A bank layer 766 is formed on the planarization layer 750 to cover an edge of the first electrode 810. Namely, the bank layer 766 is positioned at a boundary of the pixel and exposes a center of the first electrode 810 in the pixel. Since the OLED D emits blue light in each of the red, green and blue pixel regions RP, GP and BP, the organic light emitting layer 820 can be integrally formed as a common layer in the red, green and blue pixel regions RP, GP and BP without separation. The bank layer 766 can be formed to prevent a current leakage at an edge of the first electrode 810 and can be omitted.

An organic emitting layer 820 is formed on the first electrode 810.

A second electrode 830 is formed over the first substrate 710 where the organic emitting layer 820 is formed. The second electrode 830 is disposed over an entire surface of a display device and can be formed of a conductive material having a relatively low work fuction to serve as a cathode. For example, the second electrode 830 can be formed of Al, Mg, Ca, Ag or their alloys, e.g., Mg:Ag.

In the organic light emitting display device 700, since the light emitted from the organic emitting layer 820 is incident to the color filter layer 780 through the second electrode 830, the second electrode 830 has a thin profile for transmitting the light.

The first electrode 810, the organic emitting layer 820 and the second electrode 830 constitute the OLED D.

The color filter layer 780 is disposed over the OLED D and includes a red color filter 782, a green color filter 784 and a blue color filter 786 respectively corresponding to the red pixel region RP, the green pixel region GP and the blue pixel region BP. The red color filter 782 includes at least one of a red dye and a red pigment, the green color filter 784 includes at least one of a green dye and a green pigment, and the blue color filter 786 includes at least one of a blue dye and a blue pigment.

The color filter layer 780 can be attached to the OLED D using an adhesive layer. Alternatively, the color filter layer 780 can be formed directly on the OLED D. When an encapsulation layer (or an encapsulation film) is formed to cover the OLED D, the color filter layer 780 can be formed on the encapsulation layer.

An encapsulation layer (or an encapsulation film) can be formed to prevent penetration of moisture into the OLED D. For example, the encapsulation film can include a first inorganic insulating layer, an organic insulating layer and a second inorganic insulating layer sequentially stacked, but it is not limited thereto. The encapsulation film can be omitted.

A polarization plate for reducing an ambient light reflection can be disposed over an outer side of the second substrate 770 in the top-emission type OLED D. For example, the polarization plate can be a circular polarization plate.

In the OLED D of FIG. 9, the first electrode 810 and the second electrode 830 are a reflective electrode and a transparent (a semitransparent) electrode, respectively, and the color filter layer 780 is disposed over the OLED D.

Alternatively, the first electrode 810 and the second electrode 830 can be a transparent (a semitransparent) electrode and a reflective electrode, respectively, and the color filter layer 780 can be disposed between the OLED D and the first substrate 710. In this case, first electrode 810 can have a single-layered structure of the transparent conductive oxide layer.

A color conversion layer can be formed between the OLED D and the color filter layer 780. The color conversion layer can include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

The color conversion layer can be included instead of the color filter layer 780.

As described above, in the organic light emitting display device 700, the OLED D in the red, green and blue pixel regions RP, GP and BP emits the white light, and the white light from the organic light emitting diode D passes through the red color filter 782, the green color filter 784 and the blue color filter 786. As a result, the red light, the green light and the blue light are provided from the red pixel region RP, the green pixel region GP and the blue pixel region BP, respectively.

In FIG. 9, the OLED D emitting the white light is used for a display device. Alternatively, the OLED D can be formed on an entire surface of a substrate without at least one of the driving element and the color filter layer to be used for a lightening device. The display device and the lightening device each including the OLED D of the present disclosure can be referred to as an organic light emitting device.

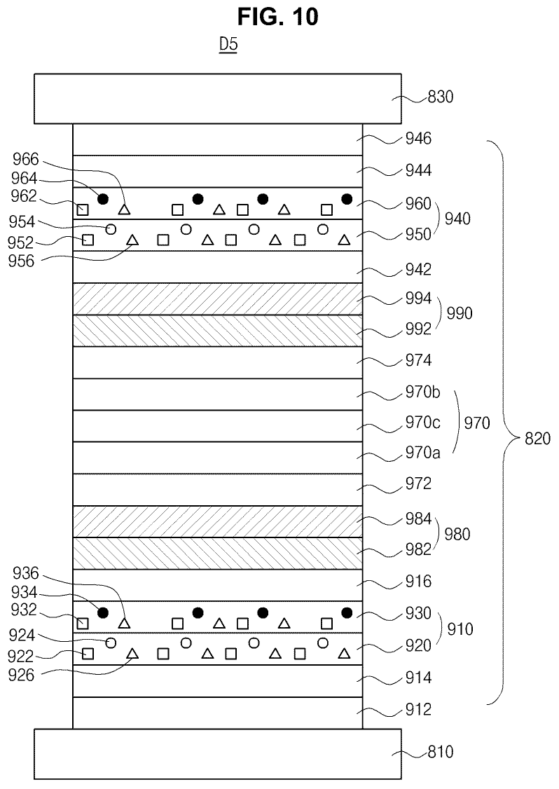

FIG. 10 is a schematic cross-sectional view of an OLED according to one or more embodiments of the present disclosure.

As illustrated in FIG. 10, the OLED D7 includes first and second electrodes 810 and 830, which face each other and an organic light emitting layer 820 therebetween. The organic light emitting layer 820 includes a first emitting part ST1 including a first EML, e.g., a first blue EML, 910, a second emitting part ST2 including a second EML, e.g., a second blue EML, 940, and a third emitting part ST3 including a third EML 970. The organic light emitting layer 820 can further includes a first CGL 980 between the first and third emitting parts ST1 and ST3 and a second CGL 990 between the second and third emitting parts ST2 and ST3. The OLED D7 in a top-emission type can further include a capping layer on the second electrode 830 to enhance a light extraction efficiency.

The organic light emitting display device 700 can include a red pixel region RP, a green pixel region GP and a blue pixel region BP, and the OLED D7 can be positioned in the red, green and blue pixel regions RP, GP and BP and emits white light.

One of the first and second electrodes 810 and 830 can be an anode, and the other one of the first and second electrodes 810 and 830 can be a cathode. One of the first and second electrodes 810 and 830 can be a reflective electrode, and the other one of the first and second electrodes 810 and 830 can be a transparent (or a semi-transparent) electrode.

In a top-emission type OLED D7, the first electrode 810 can be a reflective electrode and can have a structure of ITO/Ag/ITO, and the second electrode 830 can be a transparent electrode and can be formed of Mg:Ag with a weight % ratio of 1:9.

In a bottom-emission type OLED D7, the first electrode 810 can be a transparent electrode and can be formed of ITO, and the second electrode 830 can be a reflective electrode and can be formed of Al.

The first emitting part ST1 can further include at least one of a first HTL 914 under the first blue EML 910 and a first ETL 916 over the first blue EML 910.

In addition, the first emitting part ST1 can further include an HIL 912 between the first electrode 810 and the first HTL 914.

Moreover, the first emitting part ST1 can further include at least one of a first EBL between the first HTL 914 and the first blue EML 910 and a first HBL between the first blue EML 910 and the first ETL 916.

The second emitting part ST2 can further include at least one of a second HTL 942 under the second blue EML 940 and a second ETL 944 over the second blue EML 940.

In addition, the second emitting part ST2 can further include an EIL 946 between the second electrode 830 and the second ETL 944.

Moreover, the second emitting part ST2 can further include at least one of a second EBL between the second HTL 942 and the second EML 940 and a second HBL between the second EML 940 and the second ETL 944.

In the third emitting part ST3, the third EML 970 can include a red EML 970a, a yellow-green EML 970c and a green EML 970b. In this case, the yellow-green EML 970c is disposed between the red and green EMLs 970a and 970b. Alternatively, the yellow-green EML 970c can be omitted, and the third EML 970 can have a double-layered structure including the red and green EMLs 970a and 970b.

The red EML 970a includes a red host and a red dopant, the green EML 970b includes a green host and a green dopant, and the yellow-green EML 970c includes a yellow-green host and a yellow-green dopant. Each of the red dopant, the green dopant and the yellow-green dopant can be one of a fluorescent compound, a phosphorescent compound and a delayed fluorescent compound.

For example, the red host can be selected from the group consisting of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), 2,7-bis(carbazole-9-yl)-9,9-dimethylfluorene (DMFL-CBP), 2,2′,7,7′-tetrakis(carbazole-9-yl)-9,9-spiorofluorene (Spiro-CBP), and 3,6-bis(carbazole-9-yl)-9-(2-ethyl-hexyl)-9H-carbazole (TCzl), but it is not limited thereto.

The red dopant can be selected from the group consisting of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)2(acac)), tris[2-(4-n-hexylphenyl)quinoline]iridium(III) (Hex-Ir(phq)3), tris[2-phenyl-4-methylquinoline]iridium(III) (Ir(Mphq)3), bis(2-phenylquinoline)(2,2,6,6-tetramethylheptene-3,5-dionate)iridium(III) (Ir(dpm)PQ2), bis(phenylisoquinoline)(2,2,6,6-tetramethylheptene-3,5-dionate)iridium(III) (Ir(dpm)(piq)2), bis[(4-n-hexylphenyl)isoquinoline](acetylacetonate)iridium(III) (Hex-Ir(piq)2(acac)), tris[2-(4-n-hexylphenyl)quinoline]iridium(III) (Hex-Ir(piq)3), tris(2-(3-methylphenyl)-7-methyl-quinolato)iridium (Ir(dmpq)3), bis[2-(2-methylphenyl)-7-methyl-quinoline](acetylacetonate)iridium(III) (Ir(dmpq)2(acac)), bis[2-(3,5-dimethylphenyl)-4-methyl-quinoline](acetylacetonate)iridium(III) (Ir(mphmq)2(acac)), and tris(dibenzoylmethane)mono(1,10-phenanthroline)europium(III) (Eu(dbm)3(phen)), but it is not limited thereto.

Each of the green host and the yellow-green host can be independently selected from the group consisting of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

The green dopant can be selected from the group consisting of [bis(2-phenylpyridine)](pyridyl-2-benzofuro[2,3-b]pyridine)iridium), tris[2-phenylpyridine]iridium(III) (Ir(ppy)3), fac-tris(2-phenylpyridine)iridium(III) (fac-Ir(ppy)3), bis(2-phenylpyridine)(acetylacetonate)iridium(III) (Ir(ppy)2(acac)), tris[2-(p-tolyl)pyridine]iridium(III) (Ir(mppy)3), bis(2-(naphthalene-2-yl)pyridine)(acetylacetonate)iridium(III) (Ir(npy)2acac), tris(2-phenyl-3-methyl-pyridine)iridium (Ir(3mppy)3), and fac-tris(2-(3-p-xylyl)phenyl)pyridine iridium(III) (TEG), but it is not limited thereto.

The yellow-green dopant can be selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)iridium(III) (Ir(BT)2(acac)), bis(2-(9,9-diethyl-fluoren-2-yl)-1-phenyl-1H-benzo[d]imdiazolato)(acetylacetonate)iridium(III) (Ir(fbi)2(acac)), bis(2-phenylpyridine)(3-(pyridine-2-yl)-2H-chromen-2-onate)iridium(III) (fac-Ir(ppy)2Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) (PO-01), but it is not limited thereto.

The third emitting part ST3 can include at least one of a third HTL 972 under the third EML 970 and a third ETL 974 over the third EML 970.

In addition, the third emitting part ST3 can further include at least one of a third EBL between the third HTL 972 and the third EML 970 and a third HBL between the third EML 970 and the third ETL 974.

For example, the HIL 912 can include the above-mentioned hole injection material and can have a thickness of 1 to 30 nm, preferably 5 to 15 nm.

Each of the first to third HTLs 914, 942 and 972 can include the above-mentioned hole transporting material and can have a thickness of 20 to 60 nm, preferably 30 to 40.

Each of the first to third ETLs 916, 944 and 974 can include the above-mentioned electron transporting material and can have a thickness of 10 to 50 nm, preferably 20 to 40.

The EIL 946 can include the above-mentioned electron injection material and can have a thickness of 0.1 to 10 nm, preferably 0.5 to 2 nm.

Each of the first to third EBLs can include the above-mentioned electron blocking material and can have a thickness of 5 to 40 nm, preferably 10 to 20 nm.

Each of the first to third HBLs can include the above-mentioned hole blocking material and can have a thickness of 1 to 20 nm, preferably 1 to 10 nm.

The first CGL 980 is positioned between the first and third emitting parts ST1 and ST3, and the second CGL 990 is positioned between the second and third emitting parts ST2 and ST3. Namely, the first emitting part ST1, the first CGL 980, the third emitting part ST3, the second CGL 990 and the second emitting part ST2 are sequentially stacked on the first electrode 810. In other words, the first emitting part ST1 is positioned between the first electrode 810 and the first CGL 980, the third emitting part ST3 is positioned between the first and second CGLs 980 and 990, and the second emitting part ST2 is positioned between the second CGL 990 and the second electrode 830.

The first CGL 980 can be a P-N junction CGL of a first N-type CGL 982 and a first P-type CGL 984, and the second CGL 990 can be a P-N junction CGL of a second N-type CGL 992 and a second P-type CGL 994.

In the first CGL 980, the first N-type CGL 982 is positioned between the first ETL 916 and the third HTL 972, and the first P-type CGL 984 is positioned between the first N-type CGL 982 and the third HTL 972.

In the second CGL 990, the second N-type CGL 992 is positioned between the third ETL 974 and the second HTL 942, and the second P-type CGL 994 is positioned between the second N-type CGL 992 and the second HTL 942.

Each of the first and second N-type CGLs 982 and 992 can include the above-mentioned N-type charge generation material, and each of the first and second P-type CGLs 984 and 994 can include the above-mentioned P-type charge generation material.

The capping layer can include the above-mentioned hole transporting material and can have a thickness of 50 to 100 nm, preferably 70 to 80 nm.

The first blue EML 910 in the first emitting part ST1 includes a first blue emitting layer 920 and a second blue emitting layer 930. In the first blue EML 910, the second blue emitting layer 930 contacts the first blue emitting layer 920 and is disposed on the first blue emitting layer 920 so that the first blue EML 910 has a double-layered structure. The first blue emitting layer 920 is disposed to be closer to the first electrode 810 as an anode than the second blue emitting layer 930, and the second blue emitting layer 930 is disposed to be closer to the second electrode 830 as a cathode than the first blue emitting layer 920.

The first blue emitting layer 920 includes a first p-type host 922, a first n-type host 924 and a first phosphorescent dopant 926, and the second blue emitting layer 930 includes a second p-type host 952, a second n-type host 934 and a second phosphorescent dopant 936. For example, the first phosphorescent dopant 926 can be referred to as a first emitter, and the second phosphorescent dopant 936 can be referred to as a second emitter.

Each of the first and second p-type hosts 922 and 932 is represented by Formula 1 and is independently selected from the compounds in Formula 2. The first and second p-type hosts 922 and 932 can be same or different.

One of the first and second n-type hosts 924 and 934 is represented by Formula 3 and is selected from the compounds in Formula 2. The other one of the first and second n-type hosts 924 and 934 is represented by Formula 5 and is selected from the compounds in Formula 6.

Each of the first and second phosphorescent dopants 926 and 936 is represented by Formula 7 and is independently selected from the compounds in Formula 8. The first and second phosphorescent dopants 926 and 936 can be same or different.

Each of the first and second blue emitting layers 920 and 930 can have a thickness of 5 to 30 nm, e.g., 10 to 20 nm. For example, a thickness of each of the first and second blue emitting layers 920 and 930 can be 10 nm, 15 nm or 20 nm.

A thickness of the first emitting layer 920 and a thickness of the second blue emitting layer 930 can be same or different. In an aspect of the present disclosure, a thickness of the first emitting layer 920 and a thickness of the second blue emitting layer 930 can be same.

In the first blue emitting layer 920, a weight % of each of the first p-type host 922 and the first n-type host 924 can be greater than that of the first phosphorescent dopant 926, and a weight % of the first p-type host 922 and a weight % of the first n-type host 924 can be same or different. For example, a weight % of the first p-type host 922 and a weight % of the first n-type host 924 can be same.

In an aspect of the present disclosure, the first p-type host 922 can have a weight % of 25 to 50, the first n-type host 924 can have a weight % of 25 to 50, and the first phosphorescent dopant 926 can have a weight % of 4 to 25. In an aspect of the present disclosure, the first p-type host 922 can have a weight % of 44, the first n-type host 924 can have a weight % of 44, and the first phosphorescent dopant 926 can have a weight % of 12.

In the second blue emitting layer 930, a weight % of each of the second p-type host 932 and the second n-type host 934 can be greater than that of the second phosphorescent dopant 936, and a weight % of the second p-type host 932 and a weight % of the second n-type host 934 can be same or different. For example, a weight % of the second p-type host 932 and a weight % of the second n-type host 934 can be same.

In an aspect of the present disclosure, the second p-type host 932 can have a weight % of 25 to 50, the second n-type host 934 can have a weight % of 25 to 50, and the second phosphorescent dopant 936 can have a weight % of 4 to 25. In an aspect of the present disclosure, the second p-type host 932 can have a weight % of 44, the second n-type host 934 can have a weight % of 44, and the second phosphorescent dopant 936 can have a weight % of 12.

A weight % of the first p-type host 922 in the first blue emitting layer 920 and a weight % of the second p-type host 932 in the second blue emitting layer 930 can be same or different. A weight % of the first n-type host 924 in the first blue emitting layer 920 and a weight % of the second n-type host 934 in the second blue emitting layer 930 can be same or different. A weight % of the first phosphorescent dopant 926 in the first blue emitting layer 920 and a weight % of the second phosphorescent dopant 936 in the second blue emitting layer 930 can be same or different.

In the present disclosure, the first n-type host 924 included in the first blue emitting layer 920, which is disposed to be closer to the first electrode 210 as an anode, can be represented by Formula 5 and selected from the compounds in Formula 6, and the second n-type host 934 included in the second blue emitting layer 930, which is disposed to be closer to the second electrode 230 as a cathode, can be represented by Formula 3 and selected from the compounds in Formula 4. In this case, a delayed fluorescent property can be provided from the first blue emitting layer 920, and an exciplex property can be provided from the second blue emitting layer 930. As a result, the lifespan of the OLED D4 and the organic light emitting display device 100 including the same can be significantly increased.

The second blue EML 940 in the second emitting part ST2 includes a third blue emitting layer 950 and a fourth blue emitting layer 960. In the second blue EML 940, the fourth blue emitting layer 960 contacts the third blue emitting layer 950 and is disposed on the third blue emitting layer 950 so that the second blue EML 940 has a double-layered structure. The third blue emitting layer 950 is disposed to be closer to the first electrode 210 as an anode than the fourth blue emitting layer 960, and the fourth blue emitting layer 960 is disposed to be closer to the second electrode 230 as a cathode than the third blue emitting layer 950.

The third blue emitting layer 950 includes a third p-type host 952, a third n-type host 954 and a third phosphorescent dopant 956, and the fourth blue emitting layer 960 includes a fourth p-type host 962, a fourth n-type host 964 and a fourth phosphorescent dopant 966. For example, the third phosphorescent dopant 956 can be referred to as a first emitter, and the fourth phosphorescent dopant 966 can be referred to as a second emitter.

Each of the first and fourth p-type hosts 952 and 962 is represented by Formula 1 and is independently selected from the compounds in Formula 2. The first and fourth p-type hosts 952 and 962 can be same or different.

One of the first and fourth n-type hosts 954 and 964 is represented by Formula 3 and is selected from the compounds in Formula 2. The other one of the first and fourth n-type hosts 954 and 964 is represented by Formula 5 and is selected from the compounds in Formula 6.

Each of the first and fourth phosphorescent dopants 956 and 966 is represented by Formula 7 and is independently selected from the compounds in Formula 8. The first and fourth phosphorescent dopants 956 and 966 can be same or different.

Each of the first and fourth blue emitting layers 950 and 960 can have a thickness of 5 to 30 nm, e.g., 10 to 20 nm. For example, a thickness of each of the first and fourth blue emitting layers 950 and 960 can be 10 nm, 15 nm or 20 nm.

A thickness of the first emitting layer 950 and a thickness of the fourth blue emitting layer 960 can be same or different. In an aspect of the present disclosure, a thickness of the first emitting layer 950 and a thickness of the fourth blue emitting layer 960 can be same.

In the third blue emitting layer 950, a weight % of each of the third p-type host 952 and the third n-type host 954 can be greater than that of the third phosphorescent dopant 956, and a weight % of the third p-type host 952 and a weight % of the third n-type host 954 can be same or different. For example, a weight % of the third p-type host 952 and a weight % of the third n-type host 954 can be same.

In an aspect of the present disclosure, the third p-type host 952 can have a weight % of 25 to 50, the third n-type host 954 can have a weight % of 25 to 50, and the third phosphorescent dopant 956 can have a weight % of 4 to 25. In an aspect of the present disclosure, the third p-type host 952 can have a weight % of 44, the third n-type host 954 can have a weight % of 44, and the third phosphorescent dopant 956 can have a weight % of 12.

In the fourth blue emitting layer 960, a weight % of each of the fourth p-type host 962 and the fourth n-type host 964 can be greater than that of the fourth phosphorescent dopant 966, and a weight % of the fourth p-type host 962 and a weight % of the fourth n-type host 964 can be same or different. For example, a weight % of the fourth p-type host 962 and a weight % of the fourth n-type host 964 can be same.

In an aspect of the present disclosure, the fourth p-type host 962 can have a weight % of 25 to 50, the fourth n-type host 964 can have a weight % of 25 to 50, and the fourth phosphorescent dopant 966 can have a weight % of 4 to 25. In an aspect of the present disclosure, the fourth p-type host 962 can have a weight % of 44, the fourth n-type host 964 can have a weight % of 44, and the fourth phosphorescent dopant 966 can have a weight % of 12.

A weight % of the third p-type host 952 in the third blue emitting layer 950 and a weight % of the fourth p-type host 962 in the fourth blue emitting layer 960 can be same or different. A weight % of the third n-type host 954 in the third blue emitting layer 950 and a weight % of the fourth n-type host 964 in the fourth blue emitting layer 960 can be same or different. A weight % of the third phosphorescent dopant 956 in the third blue emitting layer 950 and a weight % of the fourth phosphorescent dopant 966 in the fourth blue emitting layer 960 can be same or different.

In the present disclosure, the third n-type host 954 included in the third blue emitting layer 950, which is disposed to be closer to the first electrode 210 as an anode, can be represented by Formula 5 and selected from the compounds in Formula 6, and the fourth n-type host 964 included in the fourth blue emitting layer 960, which is disposed to be closer to the second electrode 230 as a cathode, can be represented by Formula 3 and selected from the compounds in Formula 4. In this case, a delayed fluorescent property can be provided from the third blue emitting layer 950, and an exciplex property can be provided from the fourth blue emitting layer 960. As a result, the lifespan of the OLED D4 and the organic light emitting display device 100 including the same can be significantly increased.

In FIG. 10, each of the first and second blue EMLs 910 and 940 has a double-layered structure. Alternatively, one of the first and second blue EMLs 910 and 940 can have a double-layered structure, and the other one of the first and second blue EMLs 910 and 940 can have a single-layered structure.

For example, the blue EML having a single-layered structure can include a blue host and a blue dopant (e.g., an emitter). The blue EML can further include an auxiliary dopant (or an auxiliary host). In the blue EML having a single-layered structure, a weight % of the blue dopant can be smaller than that of each of the blue host and the auxiliary dopant.

In an aspect of the present disclosure, the first blue EML 910 can be a fluorescent emitting layer including the compound H-1 in Formula 13 and the compound FD-1 in Formula 14.

In an aspect of the present disclosure, the first blue EML 910 can be a phosphor-sensitized fluorescence (PSF) emitting layer including the compound H-2 in Formula 13, the compound H-3 in Formula 13, the compound FD-2 in Formula 14 and the compound A-1 in Formula 15.

In an aspect of the present disclosure, the first blue EML 910 can be a hyperfluorescence emitting layer including the compound H-2 in Formula 13, the compound H-3 in Formula 13, the compound FD-2 in Formula 14 and the compound A-2 in Formula 15.

The first blue EML 910 includes the first blue emitting layer 920, which includes the first p-type host 922, the first n-type host 924 and the first phosphorescent compound 926, and the second blue emitting layer 930, which includes the second p-type host 932, the second n-type host 934 and the second phosphorescent compound 936. Each of the first and second p-type hosts 922 and 932 is a compound represented by Formula 1, and each of the first and second phosphorescent compounds 926 and 936 is a compound represented by Formula 7. One of the first and second n-type hosts 924 and 934 is a compound represented by Formula 3, and the other one of the first and second n-type hosts 924 and 934 is a compound represented by Formula 5.

The second blue EML 950 includes the third blue emitting layer 950, which includes the third p-type host 952, the third n-type host 954 and the third phosphorescent compound 956, and the fourth blue emitting layer 960, which includes the fourth p-type host 962, the fourth n-type host 964 and the fourth phosphorescent compound 966. Each of the third and fourth p-type hosts 952 and 962 is a compound represented by Formula 1, and each of the third and fourth phosphorescent compounds 956 and 966 is a compound represented by Formula 7. One of the third and fourth n-type hosts 954 and 964 is a compound represented by Formula 3, and the other one of the third and fourth n-type hosts 954 and 964 is a compound represented by Formula 5.

Accordingly, the lifespan of the OLED D5 and the organic light emitting display device 700 of the present disclosure is increased.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode;
a second electrode facing the first electrode; and
a first emitting part including a first blue emitting material layer and positioned between the first and second electrodes, the first blue emitting material layer including a first blue emitting layer and a second blue emitting layer,
wherein the first blue emitting layer includes a first p-type host, a first n-type host and a first phosphorescent dopant, and the second blue emitting layer includes a second p-type host, a second n-type host and a second phosphorescent dopant,
wherein each of the first and second p-type hosts is independently represented by Formula 1: 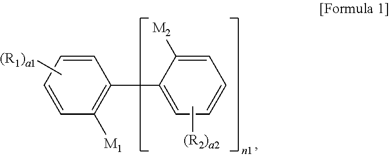
in the Formula 1,
each of a1 and a2 is independently an integer of 0 to 4, n1 is 0 or 1,
when a1 is 2 or more, two or more R₁ can be same or different, when a2 is 2 or more, two or more R₂ can be same or different,
each of R₁ and R₂ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany alkylgermanyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
each of M₁ and M₂ is independently selected from Formula 1a-1 and Formula 1-2: 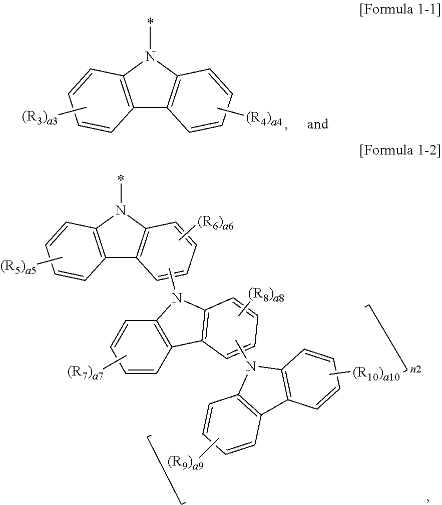
in the Formula 1-1,
each of a3 and a4 is independently an integer of 0 to 4,
when a3 is 2 or more, two or more R₃ can be same or different, when a4 is 2 or more, two or more R₄ can be same or different,
each of R₃ and R₄ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
in the Formula 1-2,
each of a5, a7, a8, a9 and a10 is independently an integer of 0 to 4, a6 is an integer of 0 to 3, n2 is 0 or 1,
when a5 is 2 or more, two or more R₅ can be same or different, when a6 is 2 or more, two or more R₆ can be same or different, when a7 is 2 or more, two or more R₇ can be same or different, when a8 is 2 or more, two or more R₈ can be same or different, when a9 is 2 or more, two or more R₉ can be same or different, when a10 is 2 or more, two or more R₁₀ can be same or different, and
each of R₅, R₆, R₇, R₈, R₉ and R₁₀ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
wherein the first n-type host is represented by Formula 3: 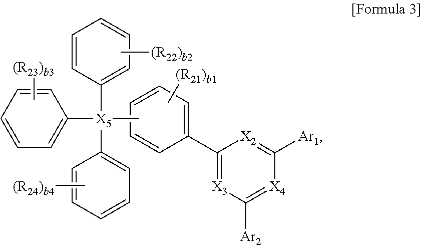
in the Formula 3,
b1 is an integer of 0 to 4, each of b2, b3 and b4 is independently an integer of 0 to 5,
when b1 is 2 or more, two or more R₂₁ can be same or different, when b2 is 2 or more, two or more R₂₂ can be same or different, when b3 is 2 or more, two or more R₂₃ can be same or different, when b4 is 2 or more, two or more R₂₄ can be same or different,
each of X₂, X₃ and X₄ is independently selected from N and CR₂₉, at least one of X₂, X₃ and X₄ is N,
R₂₁, R₂₂, R₂₃ and R₂₄ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
R₂₉ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C₆ to C₃₀ aryl group and a substituted or unsubstituted C3 to C₃₀ heteroaryl group,
each of Ar₁ and Ar₂ is independently selected from the group consisting of a substituted or unsubstituted C6 to C30 arylamino group, a substituted or unsubstituted C6 to C30 aryl group and a substituted or unsubstituted C3 to C30 heteroaryl group, and
X₅ is one of C, Si and Ge,
wherein the second n-type host is represented by Formula 5: 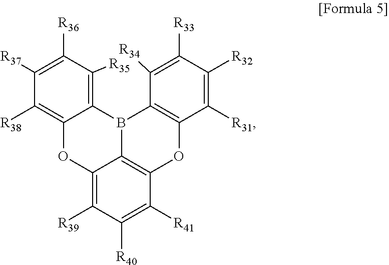
in the Formula 5,
one of R₃₁ to R₄₁ is represented by Formula 5-1, at least one of R₃₁ to R₄₁ is represented by Formula 5-2,
each of the rest of R₃₁ to R₄₁ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or optionally, adjacent two of the rest of R₃₁ to R₄₁ are combined to form a ring, 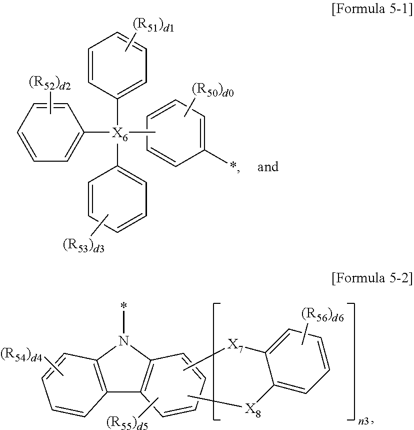
in the Formula 5-1,
d0 is an integer of 0 to 4, each of d1, d2 and d3 is independently an integer of 0 to 5,
when d0 is 2 or more, two or more R₅₀ can be same or different, when d1 is 2 or more, two or more R₅₁ can be same or different, when d2 is 2 or more, two or more R₅₂ can be same or different, when d3 is 2 or more, two or more R₅₃ can be same or different,
each of R₅₀, R₅₁, R₅₂ and R₅₃ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
X₆ is one of C, Si and Ge,
in the Formula 5-2,
n3 is 0 or 1, each of d4 and d6 is independently an integer of 0 to 4, d5 is an integer of 0 to 2,
when d4 is 2 or more, two or more R₅₄ can be same or different, when d5 is 2 or more, two or more R₅₅ can be same or different, when d6 is 2, two R₅₆ can be same or different,
each of R₅₄, R₅₅ and R₅₆ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
one of X₇ and X₈ is a single bond, the other one of X₇ and X₈ is selected from NR₅₇, CR₅₈R₅₉, O and S, and
each of R₅₇, R₅₅ and R₅₉ is independently selected from the group consisting of hydrogen, deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

2. The organic light emitting diode according to claim 1, wherein each of the first and the second p-type hosts is independently selected from below compounds in Formula 2:

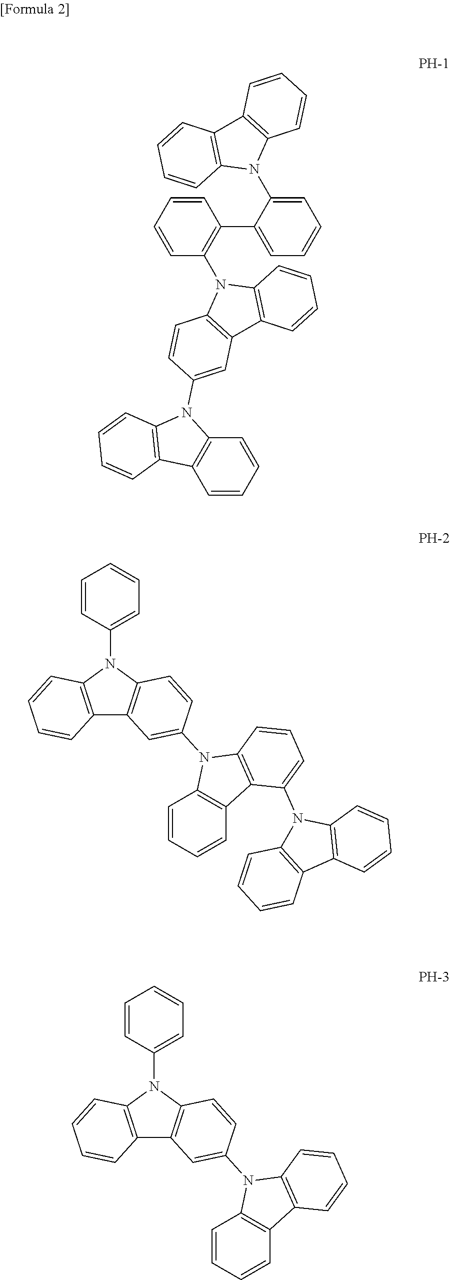 [SMILES: c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3cc(-n4c5ccccc5c5c(-n6c7ccccc7c7ccccc76)cccc54)ccc32)cc1 ; c1ccc(-n2c3ccccc3c3cc(-n4c5ccccc5c5ccccc54)ccc32)cc1]

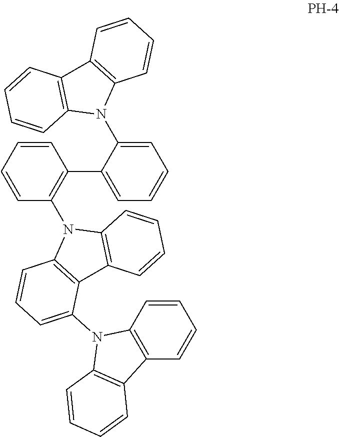 [SMILES: c1ccc(-n2c3ccccc3c3ccccc32)c(-c2ccccc2-n2c3ccccc3c3c(-n4c5ccccc5c5ccccc54)cccc32)c1]

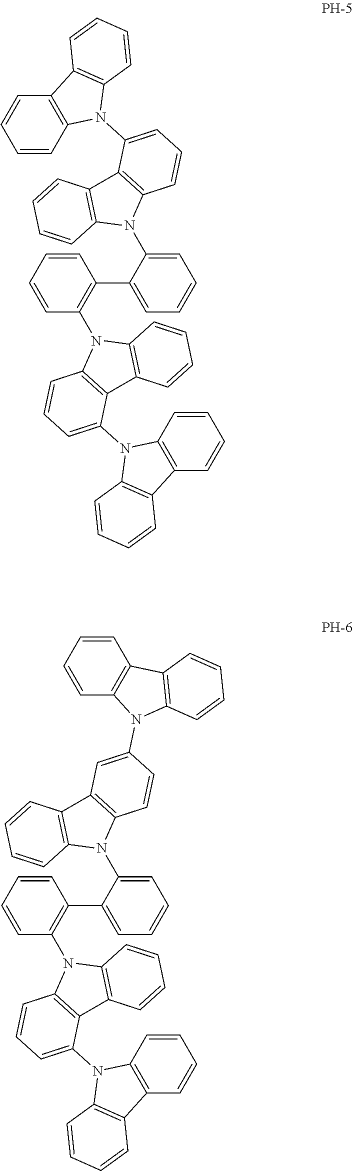 [SMILES: c1ccc(-n2c3ccccc3c3c(-n4c5ccccc5c5ccccc54)cccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1]

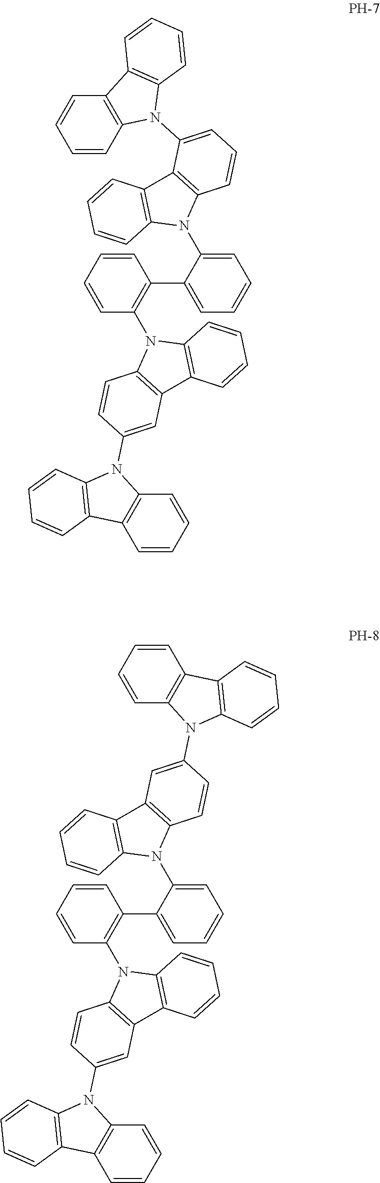 [SMILES: c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3cc(-n4c5ccccc5c5ccccc54)ccc32)c1]

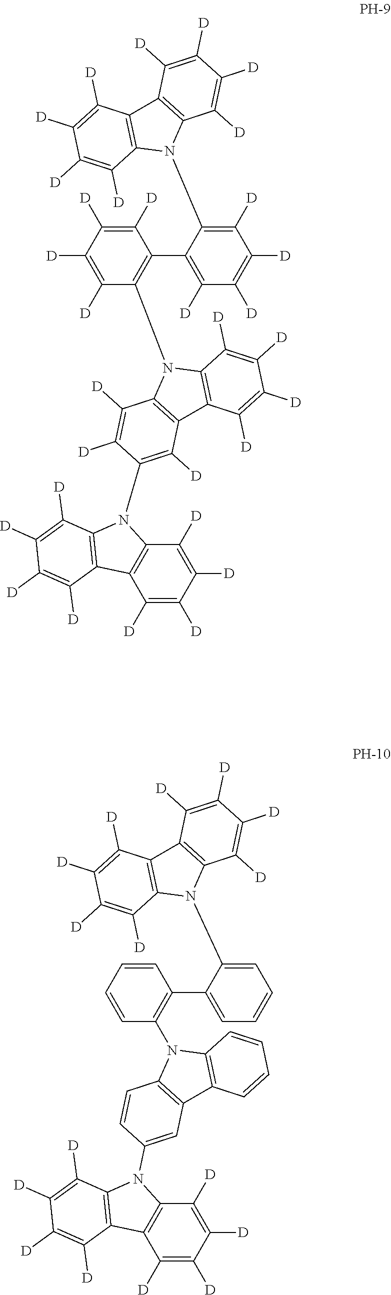 [SMILES: [2H]c1c([2H])c([2H])c(-n2c3c([2H])c([2H])c([2H])c([2H])c3c3c([2H])c([2H])c([2H])c([2H])c32)c(-c2c([2H])c([2H])c([2H])c([2H])c2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c1[2H] ; [2H]c1c([2H])c([2H])c2c(c1[2H])c1c([2H])c([2H])c([2H])c([2H])c1n2-c1ccc2c(c1)c1ccccc1n2-c1ccccc1-c1ccccc1-n1c2c([2H])c([2H])c([2H])c([2H])c2c2c([2H])c([2H])c([2H])c([2H])c21]

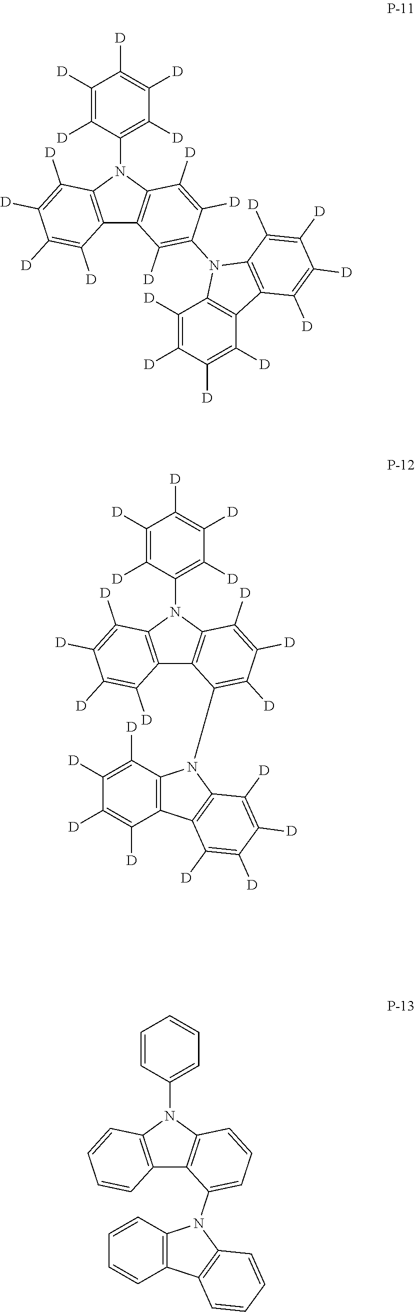 [SMILES: [2H]c1c([2H])c([2H])c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c([2H])c1[2H] ; [2H]c1c([2H])c([2H])c(-n2c3c([2H])c([2H])c([2H])c([2H])c3c3c(-n4c5c([2H])c([2H])c([2H])c([2H])c5c5c([2H])c([2H])c([2H])c([2H])c54)c([2H])c([2H])c([2H])c32)c([2H])c1[2H] ; c1ccc(-n2c3ccccc3c3c(-n4c5ccccc5c5ccccc54)cccc32)cc1]

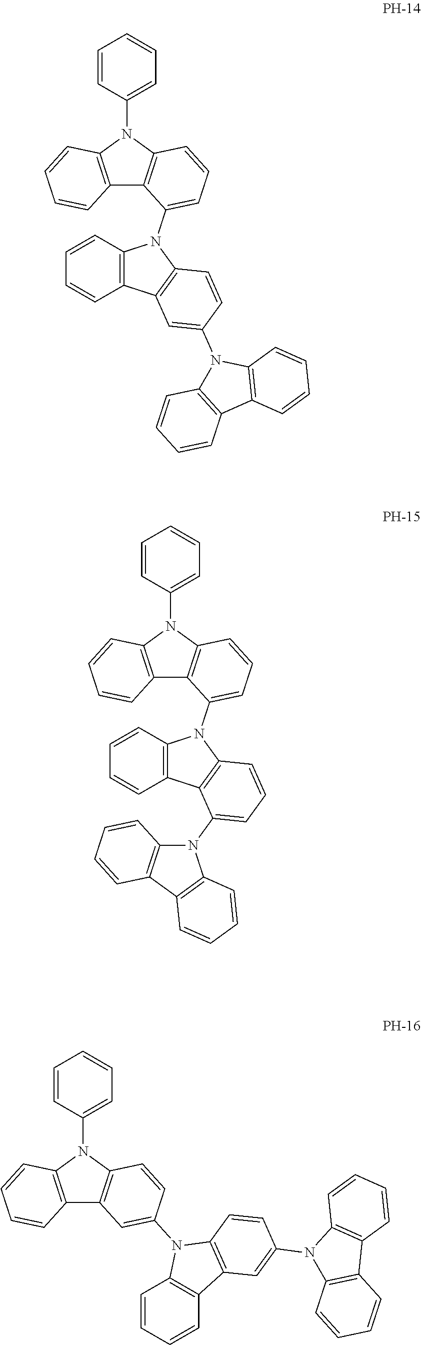 [SMILES: c1ccc(-n2c3ccccc3c3c(-n4c5ccccc5c5cc(-n6c7ccccc7c7ccccc76)ccc54)cccc32)cc1 ; c1ccc(-n2c3ccccc3c3c(-n4c5ccccc5c5c(-n6c7ccccc7c7ccccc76)cccc54)cccc32)cc1 ; c1ccc(-n2c3ccccc3c3cc(-n4c5ccccc5c5cc(-n6c7ccccc7c7ccccc76)ccc54)ccc32)cc1]

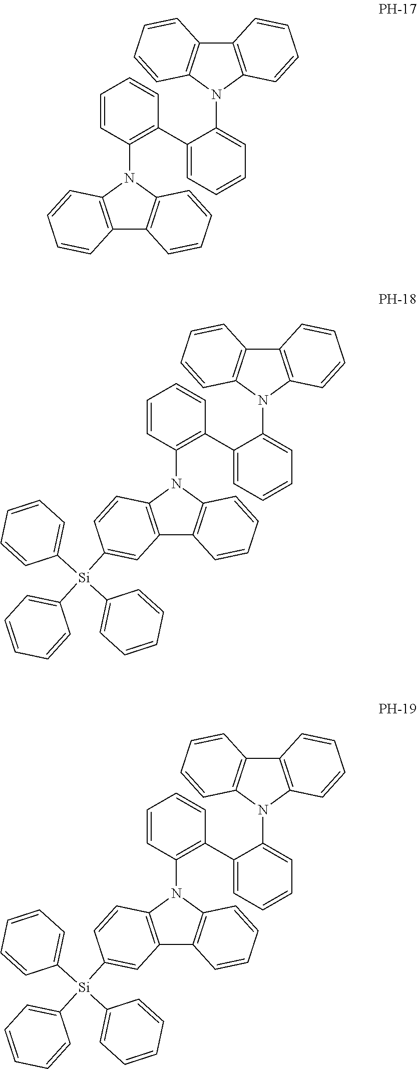 [SMILES: c1ccc(-n2c3ccccc3c3ccccc32)c(-c2ccccc2-n2c3ccccc3c3ccccc32)c1 ; c1ccc([Si](c2ccccc2)(c2ccccc2)c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3ccccc32)cc1]

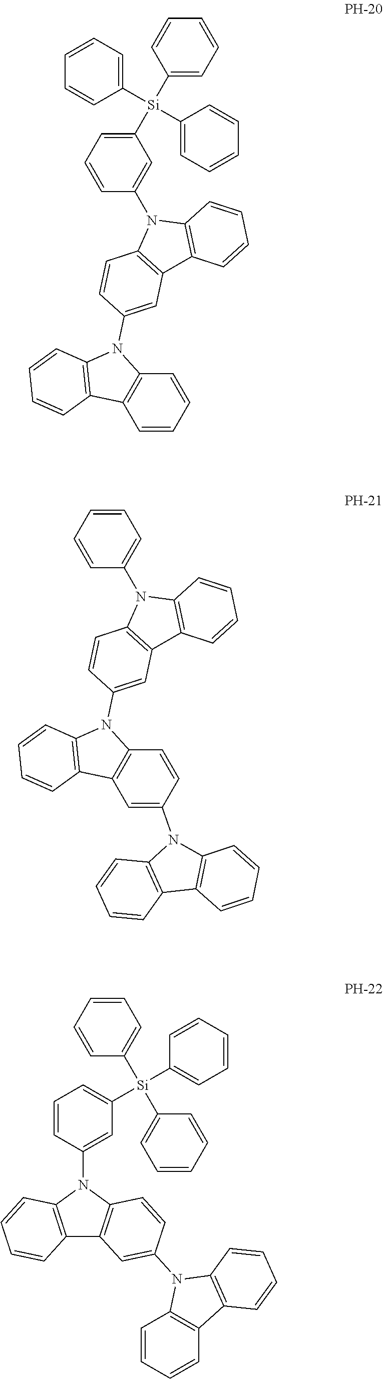 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc(-n2c3ccccc3c3cc(-n4c5ccccc5c5cc(-n6c7ccccc7c7ccccc76)ccc54)ccc32)cc1 ; c1ccc([Si](c2ccccc2)(c2ccccc2)c2cccc(-n3c4ccccc4c4cc(-n5c6ccccc6c6ccccc65)ccc43)c2)cc1]

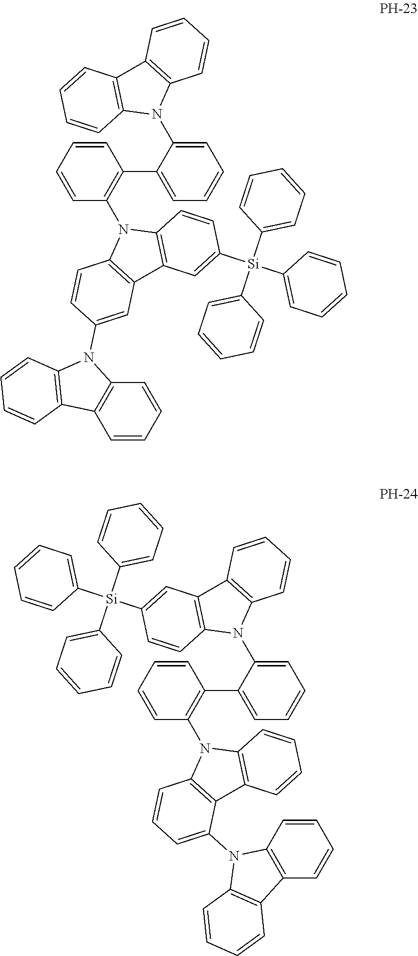 [SMILES: c1ccc([Si](c2ccccc2)(c2ccccc2)c2ccc3c(c2)c2cc(-n4c5ccccc5c5ccccc54)ccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3c(-n4c5ccccc5c5ccccc54)cccc32)cc1]

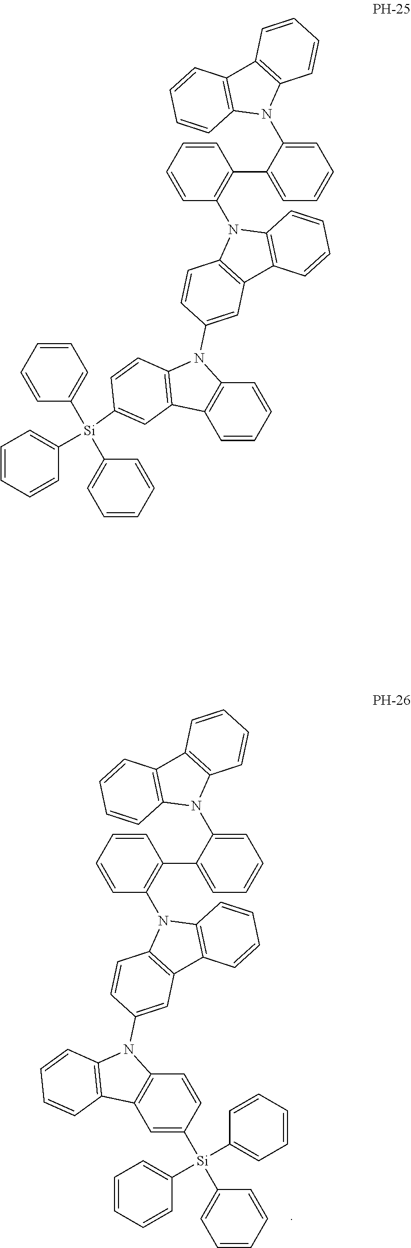 [SMILES: c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1]

3. The organic light emitting diode according to claim 1, wherein the Formula 3 is represented by Formula 3a: 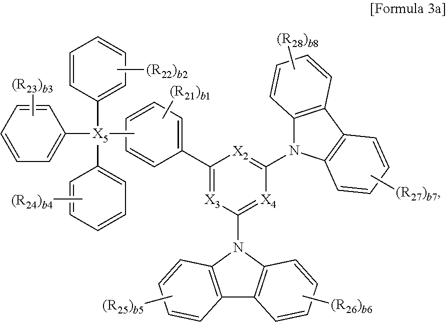
in the Formula 3a,
the definitions of b1 to b4 and R₂₁ to R₂₄ are same as those in Formula 3,
each of b5, b6, b7 and b8 is independently an integer of 0 to 4,
when b5 is 2 or more, two or more R₂₅ can be same or different, when b6 is 2 or more, two or more R₂₆ can be same or different, when b7 is 2 or more, two or more R₂₇ can be same or different, when b8 is 2 or more, two or more R₂₈ can be same or different, and
R₂₅, R₂₆, R₂₇ and R₂₈ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or, optionally, adjacent two of R₂₅, R₂₆, R₂₇ and R₂₈ are combined to form a ring.

4. The organic light emitting diode according to claim 1, wherein the first n-type host selected from below compounds in Formula 4:

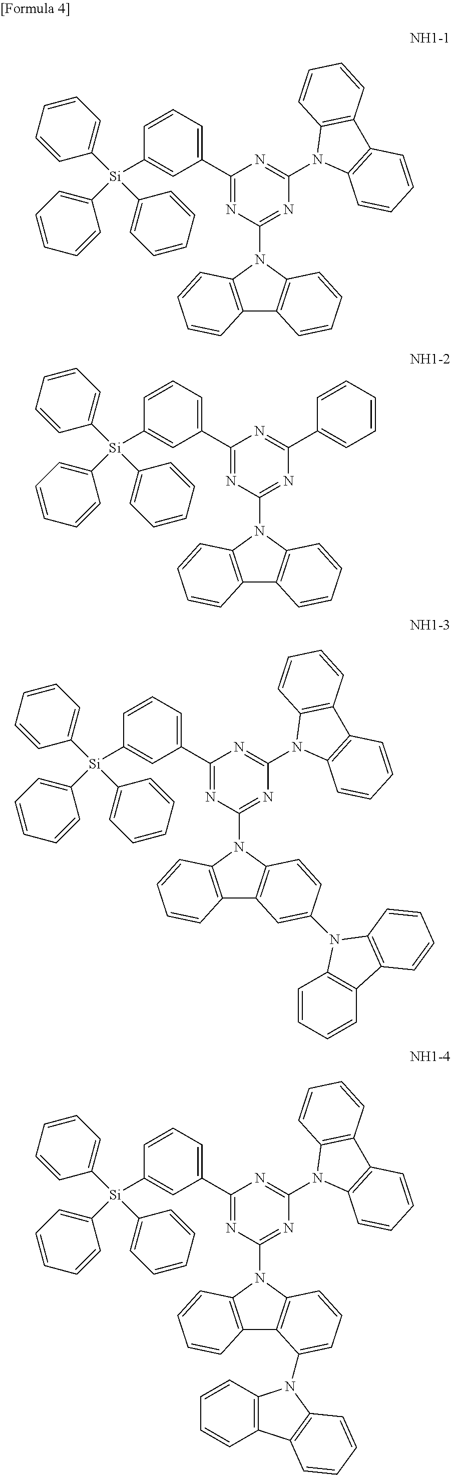

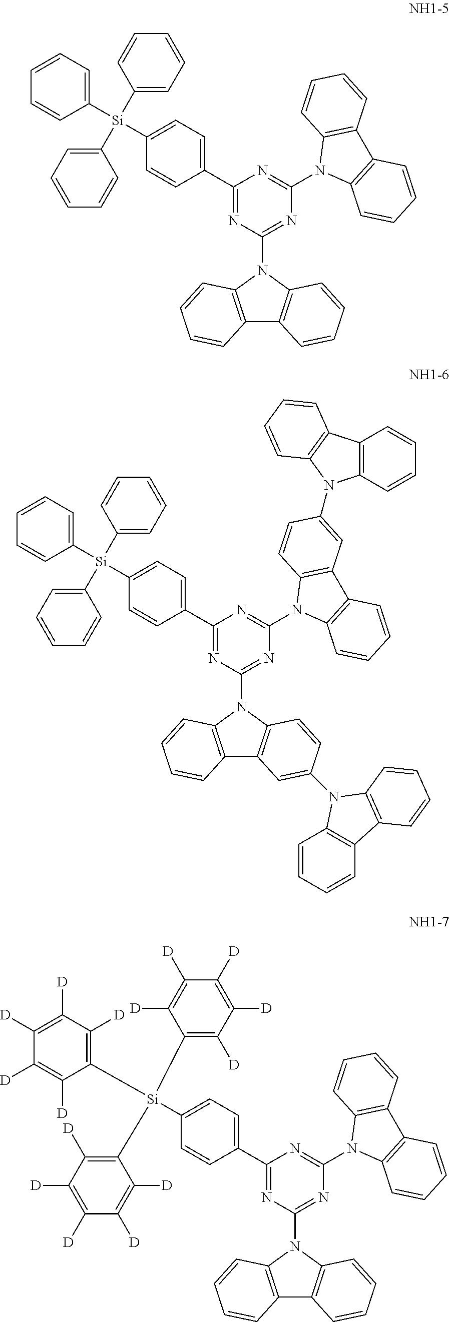 [SMILES: c1ccc([Si](c2ccccc2)(c2ccccc2)c2ccc(-c3nc(-n4c5ccccc5c5ccccc54)nc(-n4c5ccccc5c5ccccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1 ; [2H]c1c([2H])c([2H])c([Si](c2ccc(-c3nc(-n4c5ccccc5c5ccccc54)nc(-n4c5ccccc5c5ccccc54)n3)cc2)(c2c([2H])c([2H])c([2H])c([2H])c2[2H])c2c([2H])c([2H])c([2H])c([2H])c2[2H])c([2H])c1[2H]]

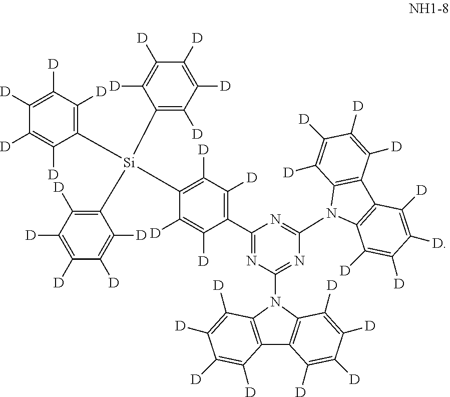

5. The organic light emitting diode according to claim 1, wherein the second n-type host is selected from below compounds in Formula 6:

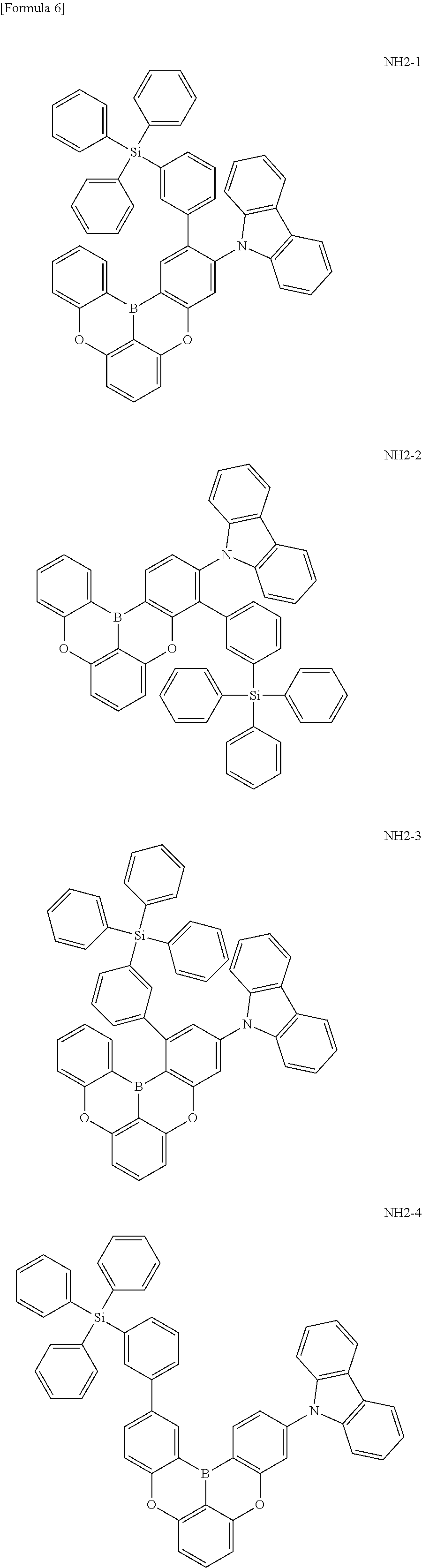 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1 ; c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1]

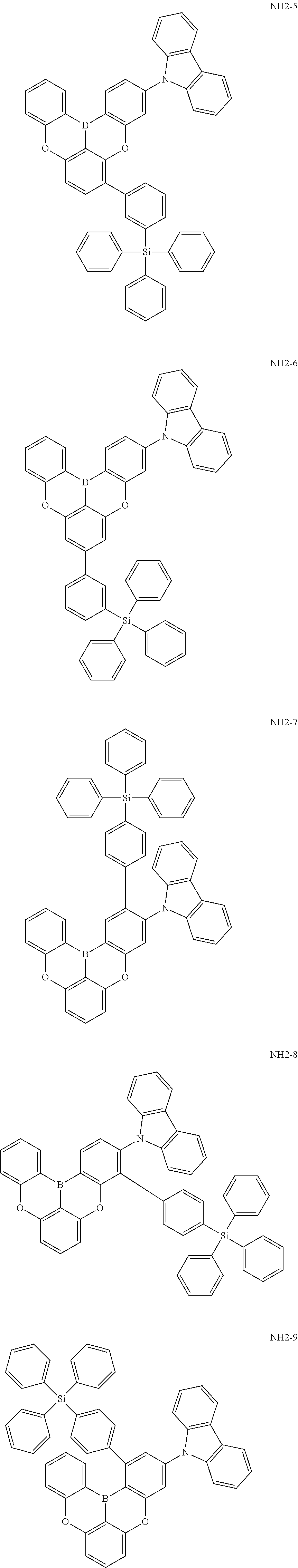

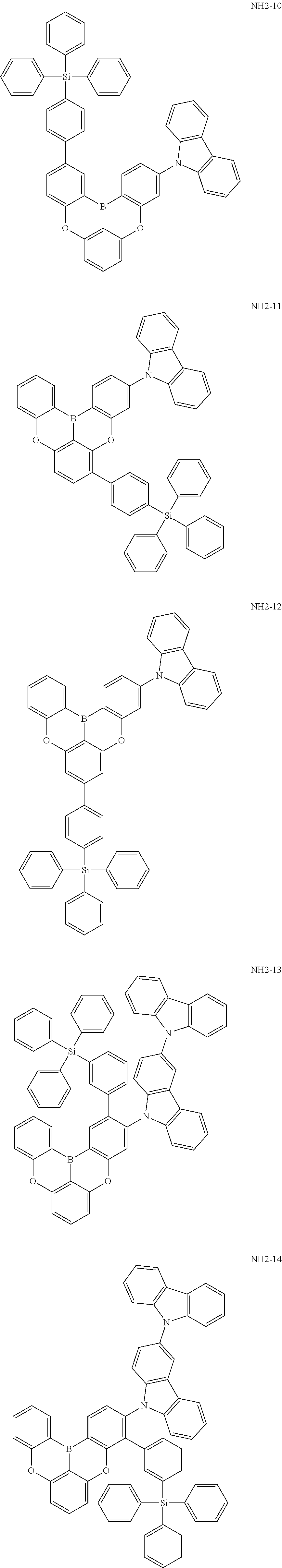

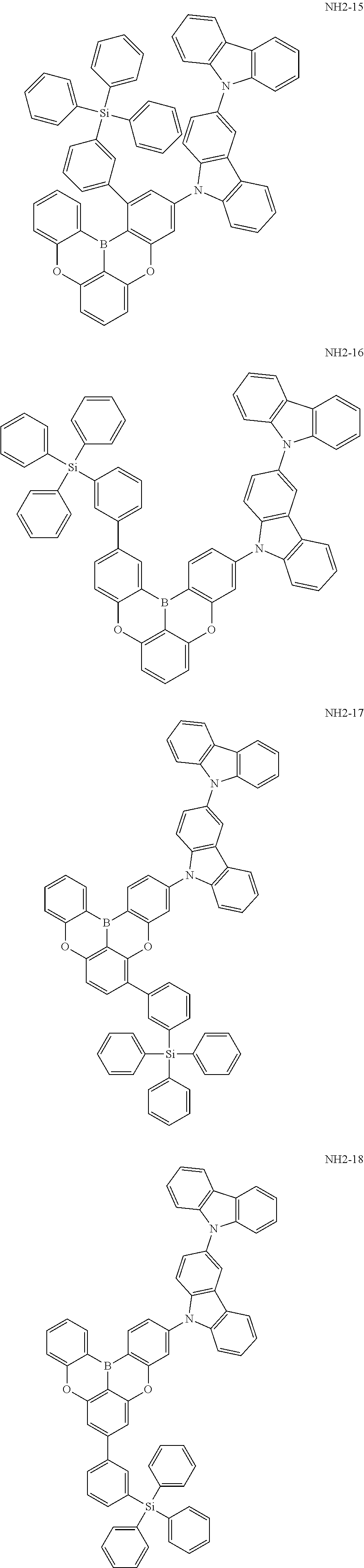 [SMILES: c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1 ; c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1]

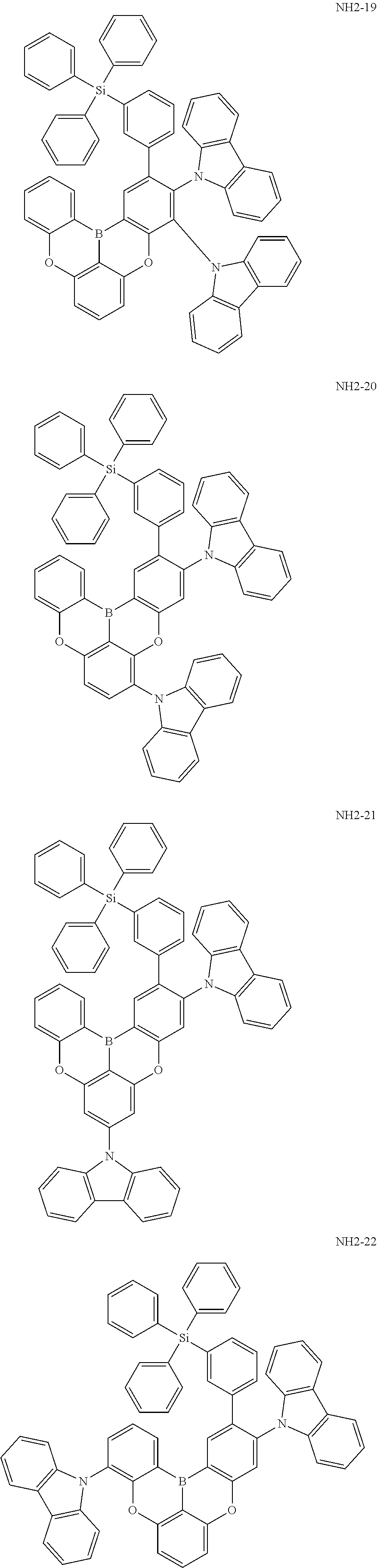 [SMILES: c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1]

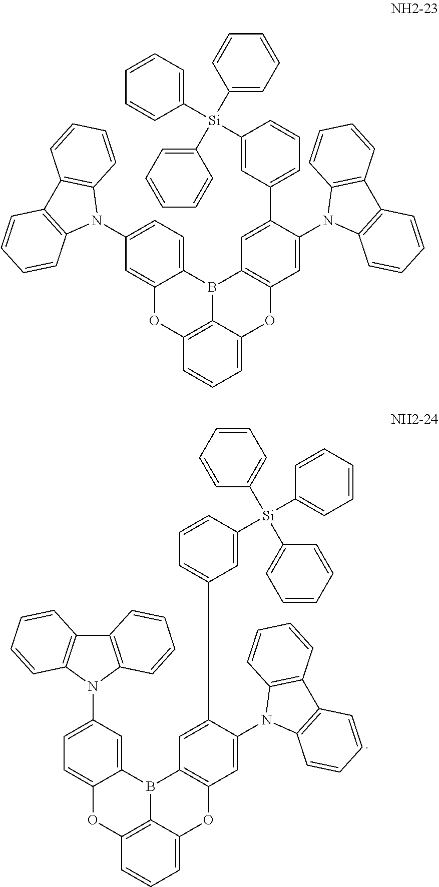

6. The organic light emitting diode according to claim 1, wherein each of the first and second phosphorescent dopants is independently represented by Formula 7: 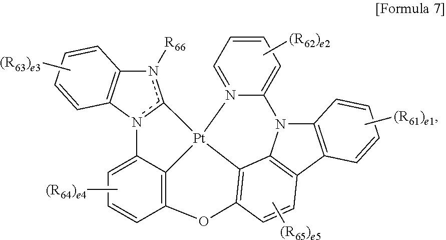
in the Formula 7,
each of e1, e2 and e3 is independently an integer of 0 to 4, e4 is an integer of 0 to 3, e5 is an integer of 0 to 2,
when e1 is 2 or more, two or more R₆₁ can be same or different, when e2 is 2 or more, two or more R₆₂ can be same or different, when e3 is 2 or more, two or more R₆₃ can be same or different, when e4 is 2 or more, two or more R₆₄ can be same or different, when e5 is 2, two R₆₅ can be same or different,
each of R₆₁ to R₆₅ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
R₆₆ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

7. The organic light emitting diode according to claim 6, wherein each of the first and the second phosphorescent dopants is independently selected from below compounds in Formula 8:

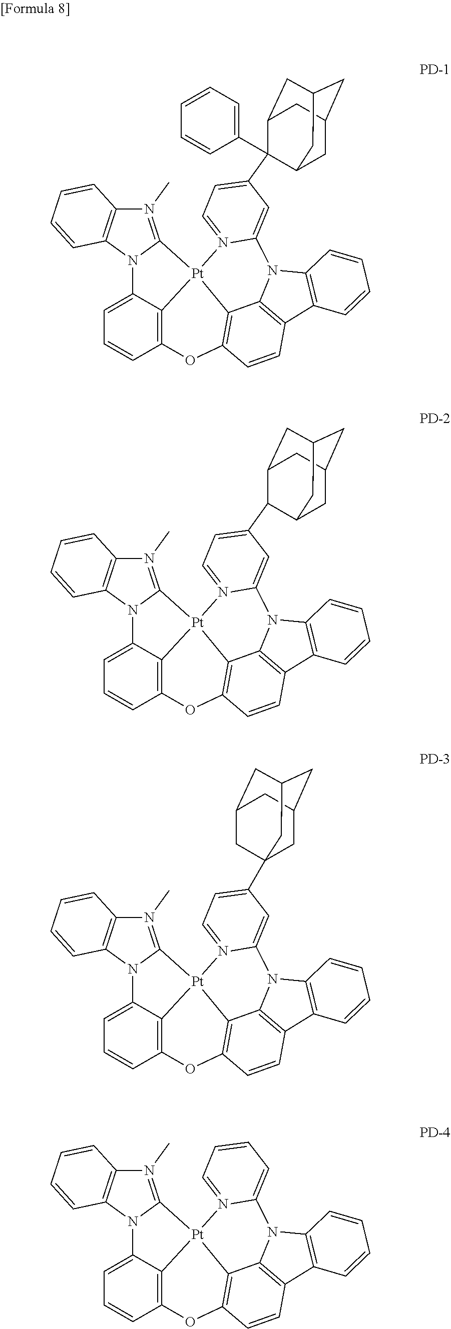

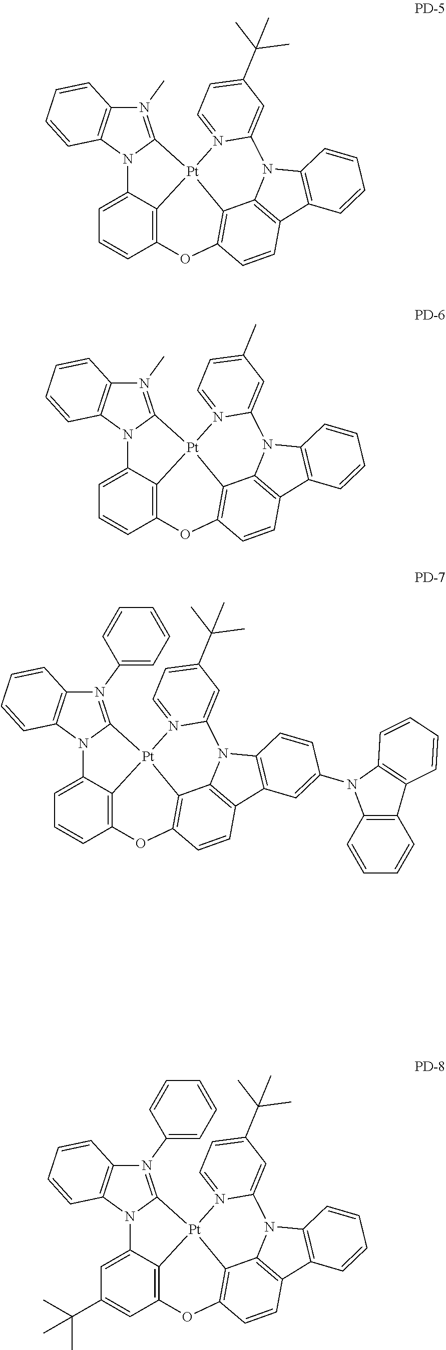

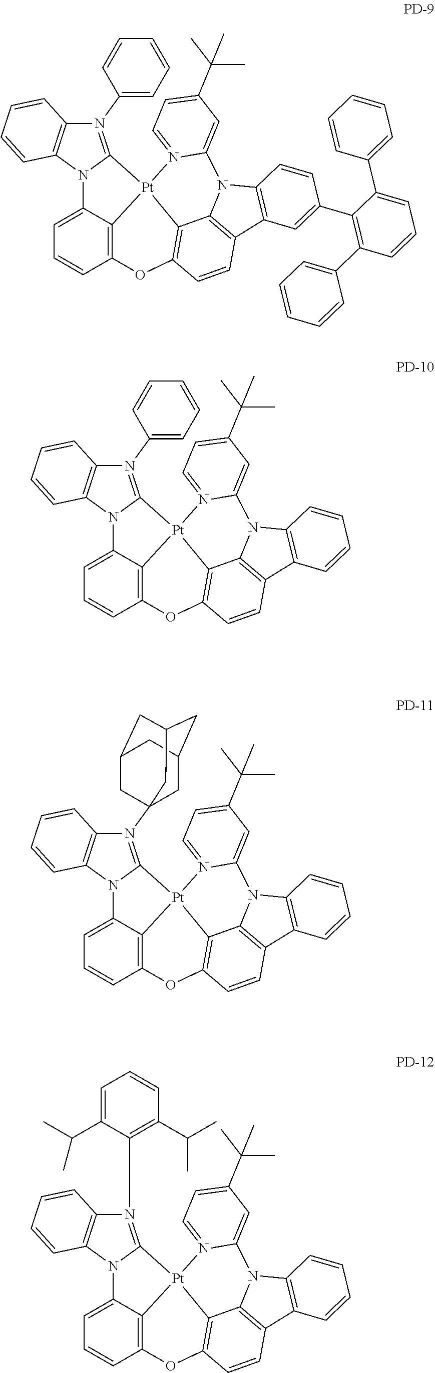

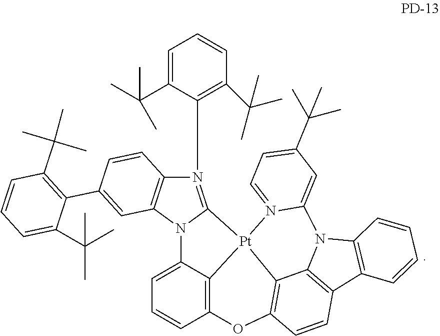

8. The organic light emitting diode according to claim 1, wherein the first electrode is an anode, the second electrode is a cathode, and the second blue emitting layer is positioned between the first electrode and the first blue emitting layer.

9. The organic light emitting diode according to claim 1, wherein a thickness of the first blue emitting layer is same as a thickness of the second blue emitting layer.

10. The organic light emitting diode according to claim 1, further comprising:
a second emitting part including a second blue emitting material layer and positioned between the first emitting part and the second electrode.

11. The organic light emitting diode according to claim 10, wherein the second blue emitting material layer includes a third blue emitting layer and a fourth blue emitting layer,
wherein the third blue emitting layer includes a third p-type host, a third n-type host and a third phosphorescent dopant, and the fourth blue emitting layer includes a fourth p-type host, a fourth n-type host and a fourth phosphorescent dopant,
wherein each of the third and fourth p-type hosts is independently represented by the Formula 1, 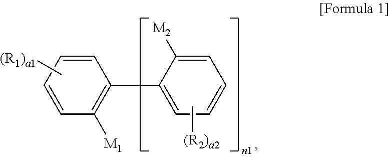
in the Formula 1,
each of a1 and a2 is independently an integer of 0 to 4, n1 is 0 or 1,
when a1 is 2 or more, two or more R₁ can be same or different, when a2 is 2 or more, two or more R₂ can be same or different,
each of R₁ and R₂ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany alkylgermanyl group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
each of M₁ and M₂ is independently selected from Formula 1a-1 and Formula 1-2: 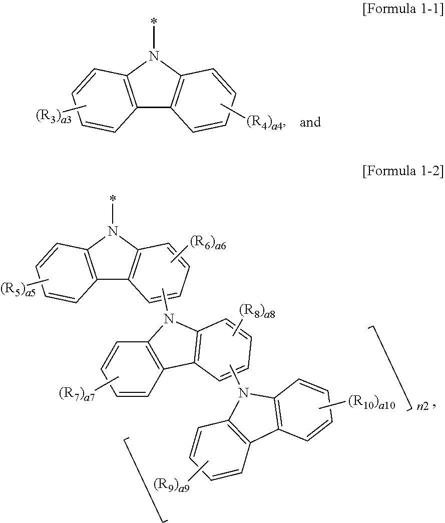
in the Formula 1-1,
each of a3 and a4 is independently an integer of 0 to 4,
when a3 is 2 or more, two or more R₃ can be same or different, when a4 is 2 or more, two or more R₄ can be same or different,
each of R₃ and R₄ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group,
in the Formula 1-2,
each of a5, a7, a8, a9 and a10 is independently an integer of 0 to 4, a6 is an integer of 0 to 3, n2 is 0 or 1,
when a5 is 2 or more, two or more R₅ can be same or different, when a6 is 2 or more, two or more R₆ can be same or different, when a7 is 2 or more, two or more R₇ can be same or different, when a8 is 2 or more, two or more R₈ can be same or different, when a9 is 2 or more, two or more R₉ can be same or different, when a10 is 2 or more, two or more R₁₀ can be same or different, and
each of R₅, R₆, R₇, R₈, R₉ and R₁₀ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C1 to C20 alkylsilyl group, a substituted or unsubstituted C1 to C20 alkylgermany group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 arylsilyl group, a substituted or unsubstituted C6 to C30 arylgermanyl group and a substituted or unsubstituted C6 to C30 aryl group, and
wherein the third n-type host is represented by Formula 3, and the fourth n-type host is represented by Formula 5 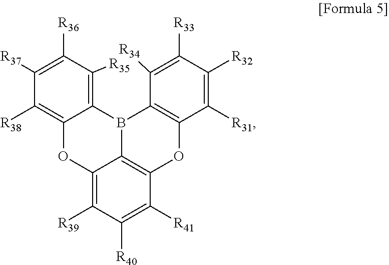
in the Formula 5,
one of R₃₁ to R₄₁ is represented by Formula 5-1, at least one of R₃₁ to R₄₁ is represented by Formula 5-2,
each of the rest of R₃₁ to R₄₁ is independently selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or optionally, adjacent two of the rest of R₃₁ to R₄₁ are combined to form a ring, 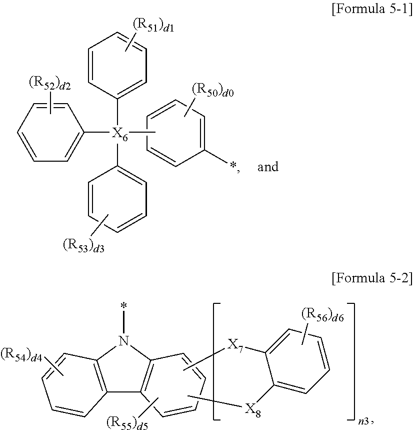
in the Formula 5-1,
d0 is an integer of 0 to 4, each of d1, d2 and d3 is independently an integer of 0 to 5, when d0 is 2 or more, two or more R₅₀ can be same or different, when d1 is 2 or more, two or more R₅₁ can be same or different, when d2 is 2 or more, two or more R₅₂ can be same or different, when d3 is 2 or more, two or more R₅₃ can be same or different,
each of R₅₀, R₅₁, R₅₂ and R₅₃ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
X₆ is one of C, Si and Ge,
in the Formula 5-2,
n3 is 0 or 1, each of d4 and d6 is independently an integer of 0 to 4, d5 is an integer of 0 to 2,
when d4 is 2 or more, two or more R₅₄ can be same or different, when d5 is 2 or more, two or more R₅₅ can be same or different, when d6 is 2, two R₅₆ can be same or different,
each of R₅₄, R₅₅ and R₅₆ is independently selected from the group consisting of deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group,
one of X₇ and X₈ is a single bond, the other one of X₇ and X₈ is selected from NR₅₇, CR₅₈R₅₉, O and S, and
each of R₅₇, R₅₈ and R₅₉ is independently selected from the group consisting of hydrogen, deuterium, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

12. The organic light emitting diode according to claim 11, wherein the Formula 3 is represented by Formula 3a: 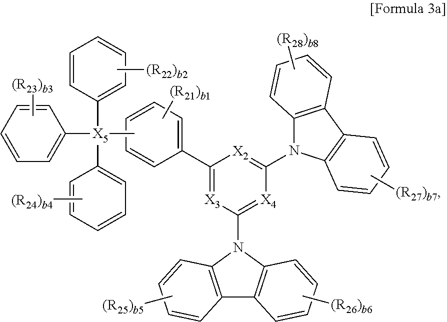
in the Formula 3a,
the definitions of b1 to b4 and R₂₁ to R₂₄ are same as those in Formula 3,
each of b5, b6, b7 and b8 is independently an integer of 0 to 4,
when b5 is 2 or more, two or more R₂₅ can be same or different, when b6 is 2 or more, two or more R₂₆ can be same or different, when b7 is 2 or more, two or more R₂₇ can be same or different, when b8 is 2 or more, two or more R₂₈ can be same or different, and
R₂₅, R₂₆, R₂₇ and R₂₈ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or, optionally, adjacent two of R₂₅, R₂₆, R₂₇ and R₂₈ are combined to form a ring.

13. The organic light emitting diode according to claim 11, wherein each of the third and fourth phosphorescent dopants is independently represented by Formula 7: 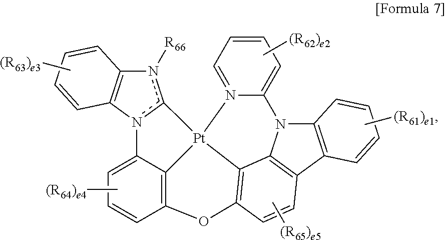
in the Formula 7,
each of e1, e2 and e3 is independently an integer of 0 to 4, e4 is an integer of 0 to 3, e5 is an integer of 0 to 2,
when e1 is 2 or more, two or more R₆₁ can be same or different, when e2 is 2 or more, two or more R₆₂ can be same or different, when e3 is 2 or more, two or more R₆₃ can be same or different, when e4 is 2 or more, two or more R₆₄ can be same or different, when e5 is 2, two R₆₅ can be same or different,
each of R₆₁ to R₆₅ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, and
R₆₆ is selected from the group consisting of hydrogen, deuterium, halogen, cyano, a substituted or unsubstituted C1 to C20 alkyl group, a substituted or unsubstituted C1 to C20 alkoxy group, a substituted or unsubstituted C3 to C20 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group.

14. An organic light emitting diode, comprising:
a first electrode;
a second electrode facing the first electrode; and
a first emitting part including a first blue emitting material layer and positioned between the first and second electrodes, the first blue emitting material layer including a first blue emitting layer and a second blue emitting layer,
wherein the first blue emitting layer includes a first p-type host, a first n-type host and a first phosphorescent dopant, and the second blue emitting layer includes a second p-type host, a second n-type host and a second phosphorescent dopant,
wherein each of the first and second p-type hosts is independently represented by Formula 2: 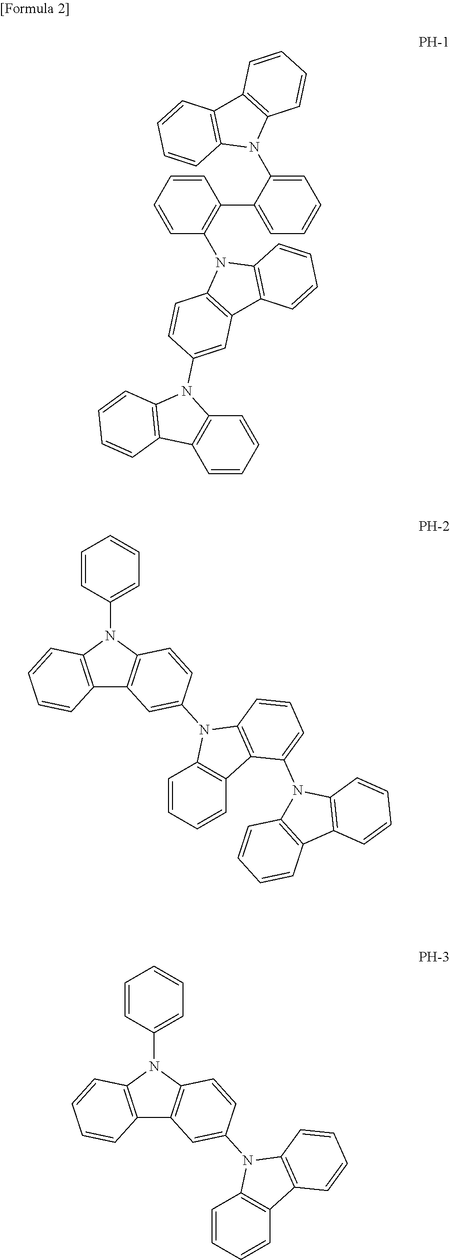 [SMILES: c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3cc(-n4c5ccccc5c5c(-n6c7ccccc7c7ccccc76)cccc54)ccc32)cc1 ; c1ccc(-n2c3ccccc3c3cc(-n4c5ccccc5c5ccccc54)ccc32)cc1] 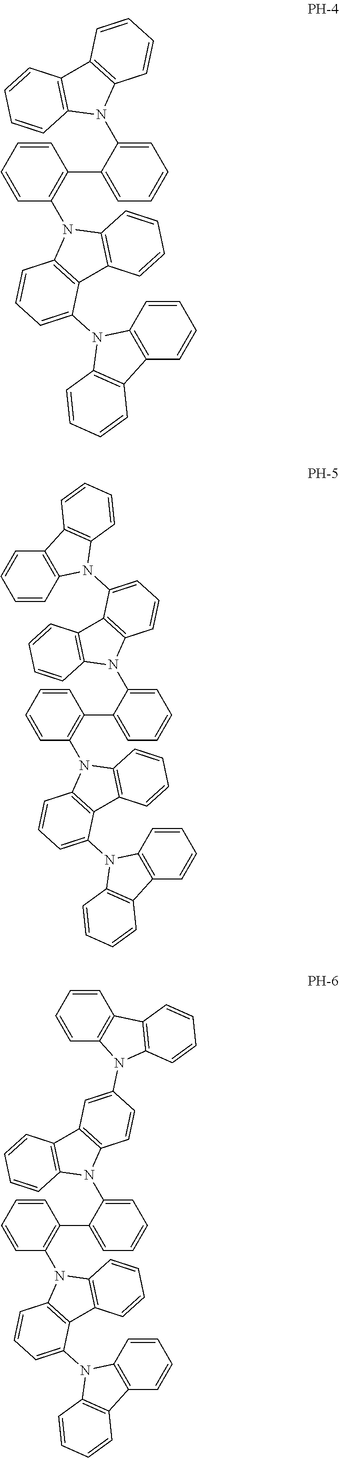 [SMILES: c1ccc(-n2c3ccccc3c3ccccc32)c(-c2ccccc2-n2c3ccccc3c3c(-n4c5ccccc5c5ccccc54)cccc32)c1 ; c1ccc(-n2c3ccccc3c3c(-n4c5ccccc5c5ccccc54)cccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1] 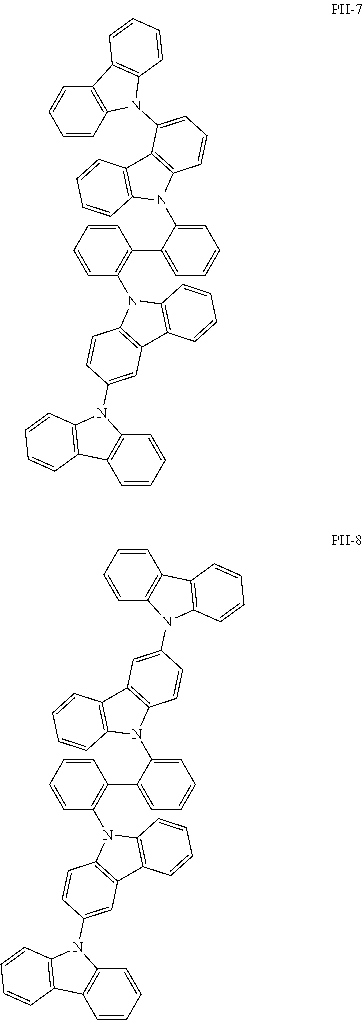 [SMILES: c1ccc(-n2c3ccccc3c3cc(-n4c5ccccc5c5ccccc54)ccc32)c(-c2ccccc2-n2c3ccccc3c3c(-n4c5ccccc5c5ccccc54)cccc32)c1 ; c1ccc(-n2c3ccccc3c3cc(-n4c5ccccc5c5ccccc54)ccc32)c(-c2ccccc2-n2c3ccccc3c3cc(-n4c5ccccc5c5ccccc54)ccc32)c1] 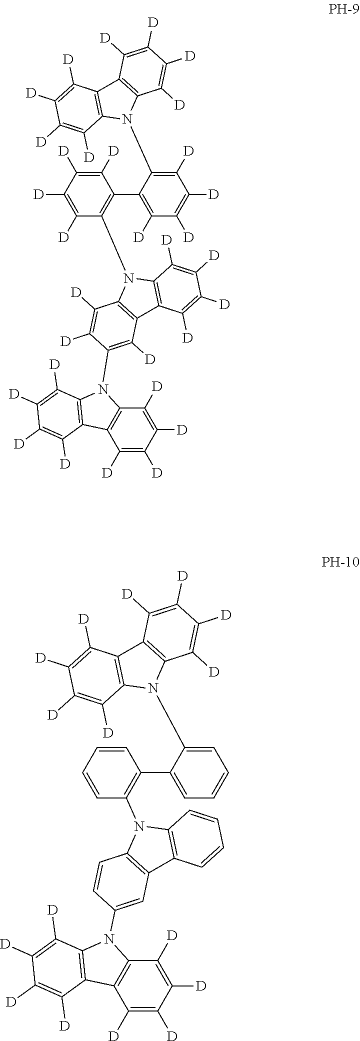 [SMILES: [2H]c1c([2H])c([2H])c(-n2c3c([2H])c([2H])c([2H])c([2H])c3c3c([2H])c([2H])c([2H])c([2H])c32)c(-c2c([2H])c([2H])c([2H])c([2H])c2-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c1[2H] ; [2H]c1c([2H])c([2H])c2c(c1[2H])c1c([2H])c([2H])c([2H])c([2H])c1n2-c1ccc2c(c1)c1ccccc1n2-c1ccccc1-c1ccccc1-n1c2c([2H])c([2H])c([2H])c([2H])c2c2c([2H])c([2H])c([2H])c([2H])c21] 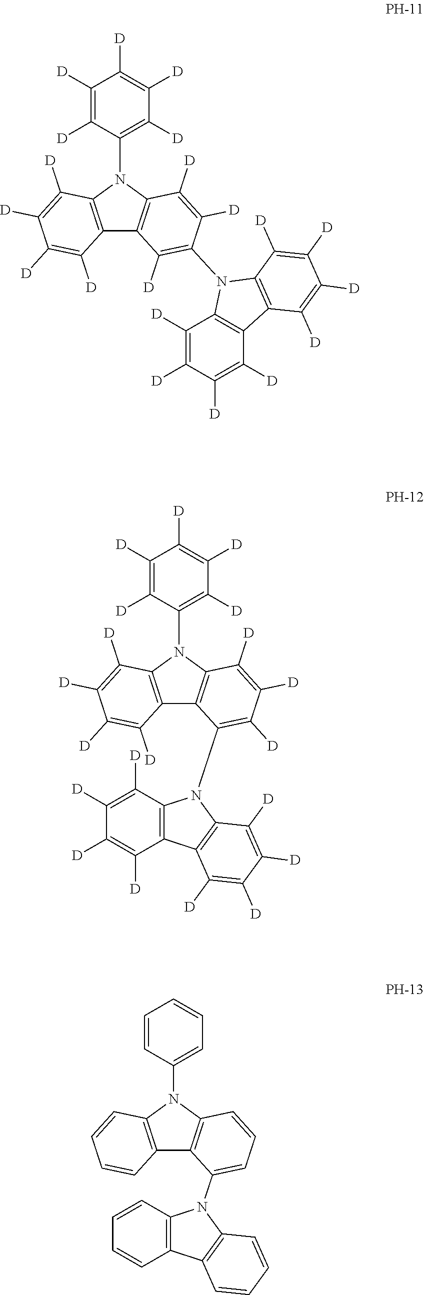 [SMILES: [2H]c1c([2H])c([2H])c(-n2c3c([2H])c([2H])c([2H])c([2H])c3c3c([2H])c(-n4c5c([2H])c([2H])c([2H])c([2H])c5c5c([2H])c([2H])c([2H])c([2H])c54)c([2H])c([2H])c32)c([2H])c1[2H] ; [2H]c1c([2H])c([2H])c(-n2c3c([2H])c([2H])c([2H])c([2H])c3c3c(-n4c5c([2H])c([2H])c([2H])c([2H])c5c5c([2H])c([2H])c([2H])c([2H])c54)c([2H])c([2H])c([2H])c32)c([2H])c1[2H] ; c1ccc(-n2c3ccccc3c3c(-n4c5ccccc5c5ccccc54)cccc32)cc1] 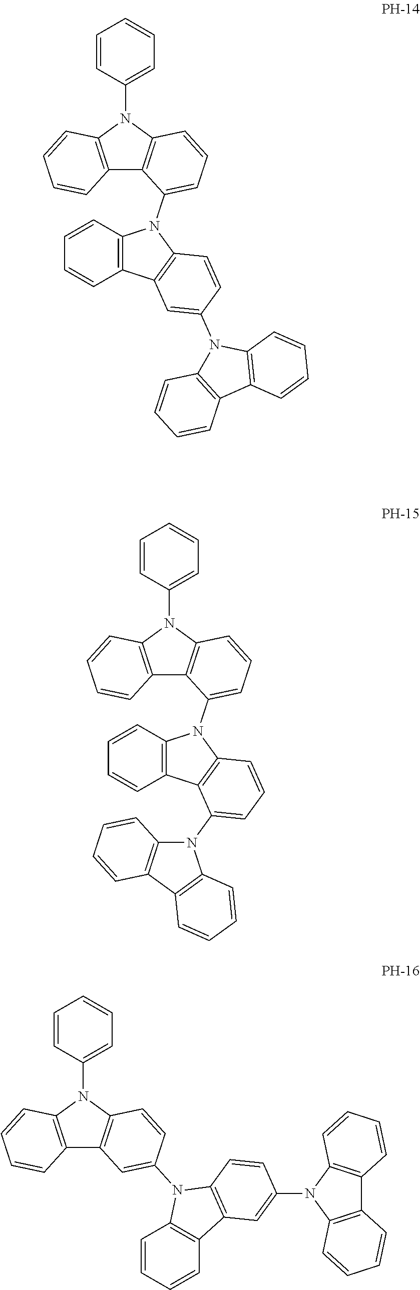 [SMILES: c1ccc(-n2c3ccccc3c3c(-n4c5ccccc5c5cc(-n6c7ccccc7c7ccccc76)ccc54)cccc32)cc1 ; c1ccc(-n2c3ccccc3c3c(-n4c5ccccc5c5c(-n6c7ccccc7c7ccccc76)cccc54)cccc32)cc1 ; c1ccc(-n2c3ccccc3c3cc(-n4c5ccccc5c5cc(-n6c7ccccc7c7ccccc76)ccc54)ccc32)cc1] 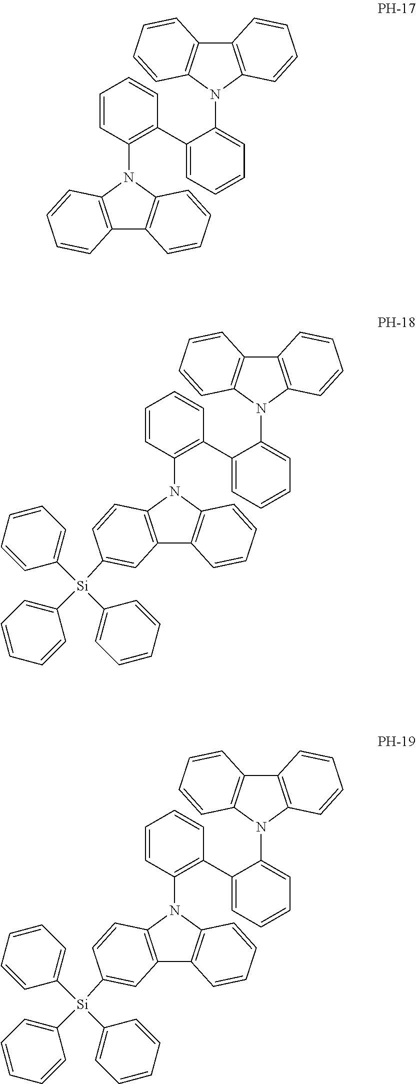 [SMILES: c1ccc(-n2c3ccccc3c3ccccc32)c(-c2ccccc2-n2c3ccccc3c3ccccc32)c1 ; c1ccc([Si](c2ccccc2)(c2ccccc2)c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3ccccc32)cc1] 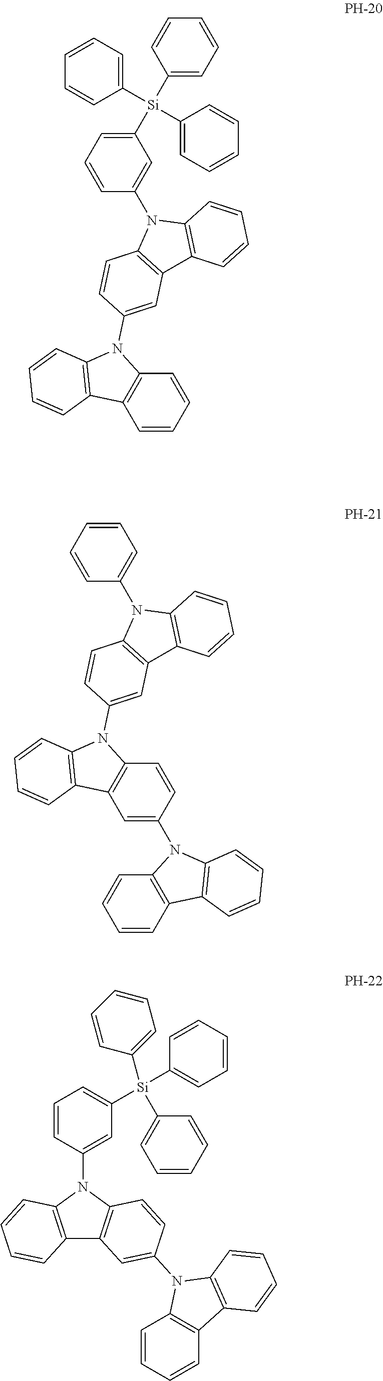 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc(-n2c3ccccc3c3cc(-n4c5ccccc5c5cc(-n6c7ccccc7c7ccccc76)ccc54)ccc32)cc1 ; c1ccc([Si](c2ccccc2)(c2ccccc2)c2cccc(-n3c4ccccc4c4cc(-n5c6ccccc6c6ccccc65)ccc43)c2)cc1] 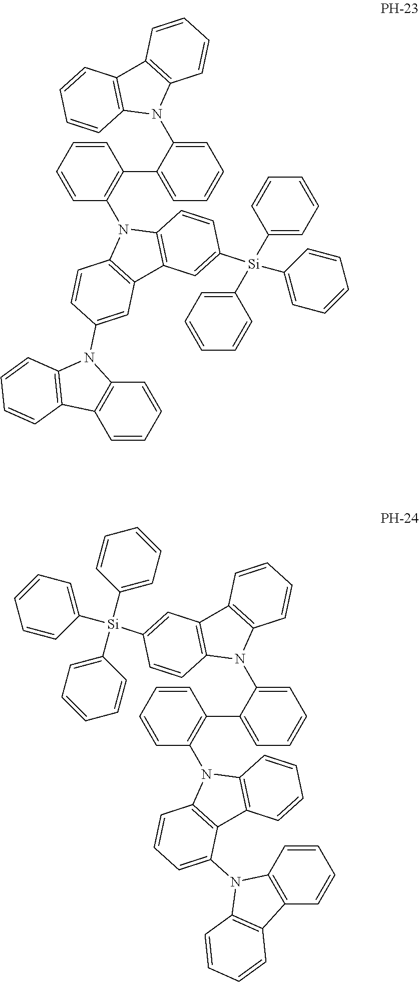 [SMILES: c1ccc([Si](c2ccccc2)(c2ccccc2)c2ccc3c(c2)c2cc(-n4c5ccccc5c5ccccc54)ccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccccc2-c2ccccc2-n2c3ccccc3c3c(-n4c5ccccc5c5ccccc54)cccc32)cc1] 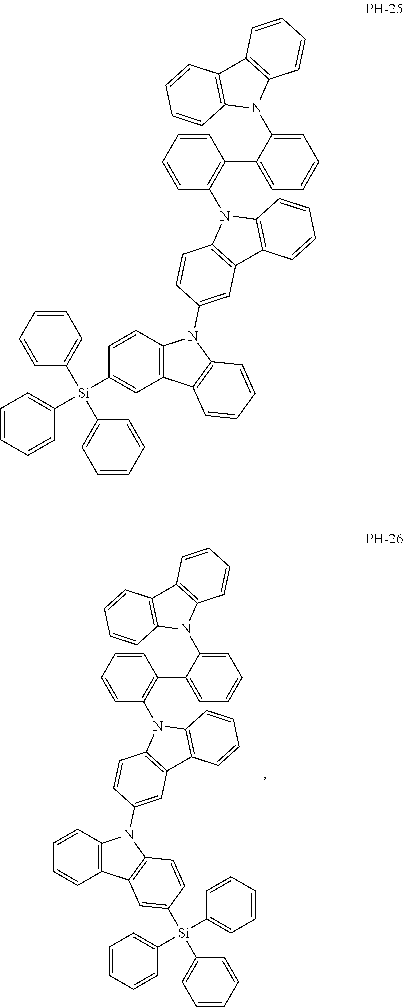 [SMILES: c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1 ; c1ccc([Si](c2ccccc2)(c2ccccc2)c2ccc3c(c2)c2ccccc2n3-c2ccc3c(c2)c2ccccc2n3-c2ccccc2-c2ccccc2-n2c3ccccc3c3ccccc32)cc1]
wherein the first n-type host is represented by Formula 3a: 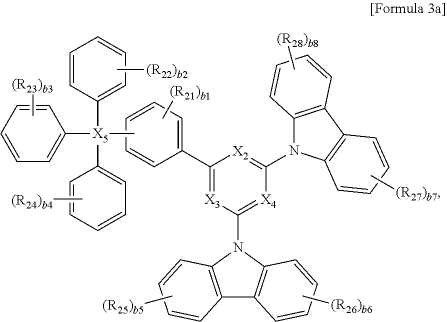
in the Formula 3a,
the definitions of b1 to b4 and R₂₁ to R₂₄ are same as those in Formula 3,
each of b5, b6, b7 and b8 is independently an integer of 0 to 4,
when b5 is 2 or more, two or more R₂₅ can be same or different, when b6 is 2 or more, two or more R₂₆ can be same or different, when b7 is 2 or more, two or more R₂₇ can be same or different, when b8 is 2 or more, two or more R₂₈ can be same or different, and
R₂₅, R₂₆, R₂₇ and R₂₈ is independently selected from the group consisting of deuterium, halogen, cyano, a substituted or unsubstituted C1 to C20 alkyl group, a substituted or unsubstituted C1 to C20 alkoxy group, a substituted or unsubstituted C3 to C30 cycloalkyl group, a substituted or unsubstituted C1 to C20 alkylamino group, a substituted or unsubstituted C6 to C30 aryloxy group, a substituted or unsubstituted C2 to C20 alkenyl group, a substituted or unsubstituted C2 to C20 alkynyl group, a substituted or unsubstituted C6 to C30 arylamino group, a substituted or unsubstituted C6 to C30 aryl group and a substituted or unsubstituted C3 to C30 heteroaryl group, or, optionally, adjacent two of R₂₅, R₂₆, R₂₇ and R₂₈ are combined to form a ring,
wherein the second n-type host is represented by Formula 6:

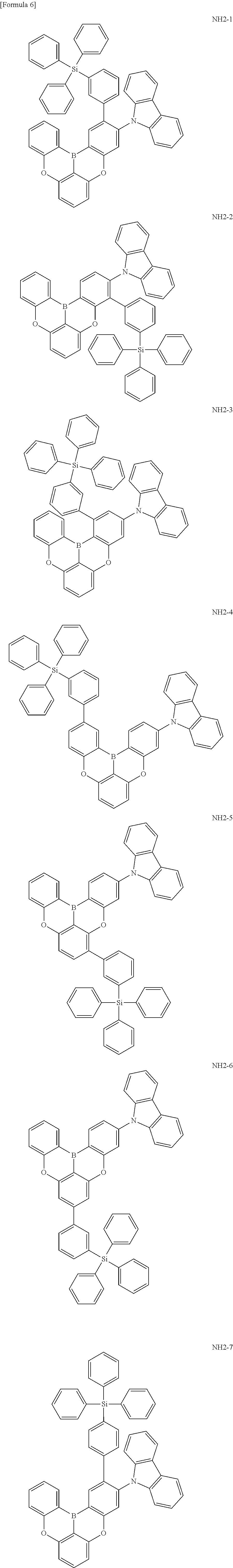

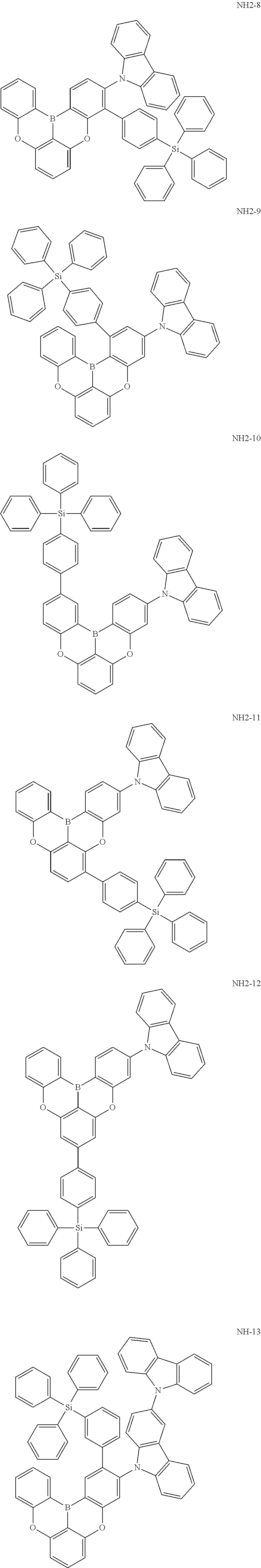

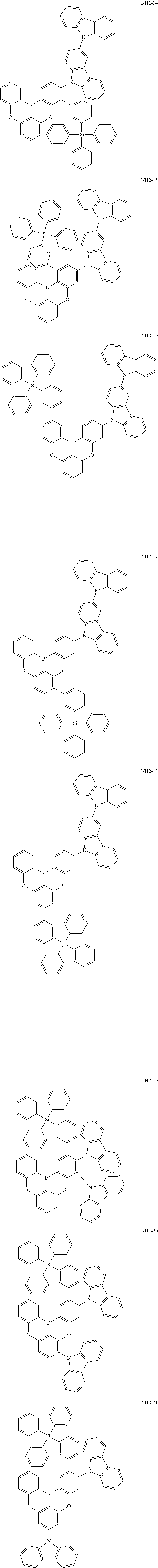

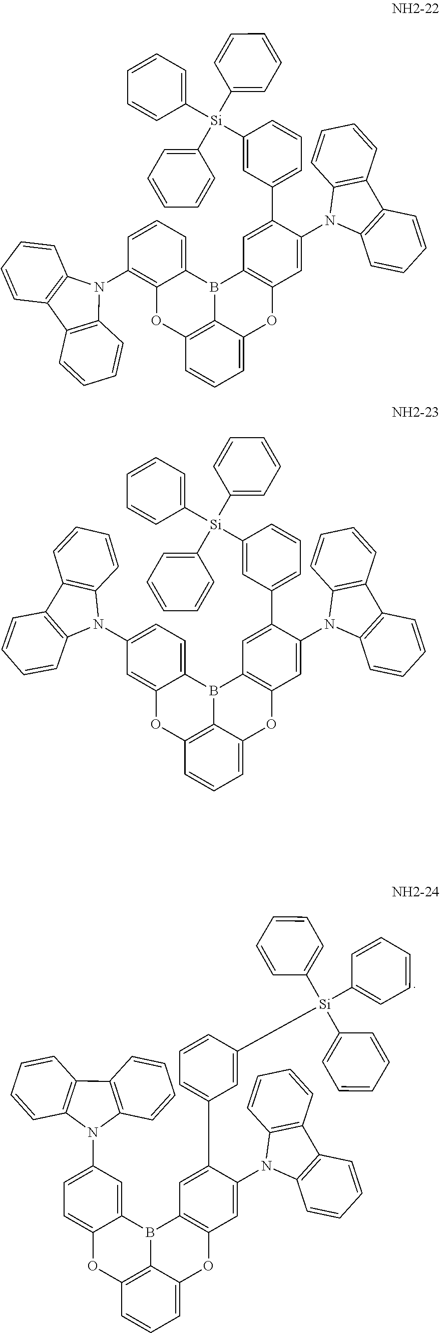 [SMILES: c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

15. The organic light emitting diode according to claim 11, wherein the first electrode is an anode, and the second electrode is a cathode, and the fourth blue emitting layer is positioned between the first electrode and the third blue emitting layer.

16. The organic light emitting diode according to claim 11, wherein a thickness of the third blue emitting layer is same as a thickness of the fourth blue emitting layer.

17. The organic light emitting diode according to claim 10, further comprising:
a third emitting part including a red emitting material layer and a green emitting material layer and positioned between the first and second emitting parts.

18. The organic light emitting diode according to claim 16, wherein the third emitting part further includes a yellow-green emitting material layer between the red and green emitting material layer.

19. The organic light emitting diode according to claim 1, wherein a difference between a lowest unoccupied molecular orbital (LUMO) energy level of the first p-type host and a LUMO energy level of the first n-type host is greater than 0.3 eV, and a difference between a highest occupied molecular orbital (HOMO) energy level of the first p-type host and a HOMO energy level of the first n-type host is greater than 0.3 eV.

20. The organic light emitting diode according to claim 1, wherein a difference between a singlet energy level of the second n-type host and a triplet energy level of the second n-type host is smaller than 0.3 eV, and
wherein a lowest unoccupied molecular orbital (LUMO) energy level of the second n-type host is smaller than a LUMO energy level of the second p-type host and is equal to or greater than a LUMO energy level of the second phosphorescent dopant.
